(19) United States
(12) Patent Application Publication
(10) Pub. No.: US 2006/0214169 A1
(43) Pub. Date: Sep. 28, 2006

(54) Active Matrix Display Backplane

(75) Inventor: Phillip Funkhouser, Dunwoody, GA (US)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: VirtualBLUE, LLC, Atlanta, GA (US)

(21) Appl. No.: 11/382,840

(22) Filed: May 11, 2006

Related U.S. Application Data
(63) Continuation-in-part of application No. 10/916,212, filed on Aug. 11, 2004.
(60) Provisional application No. 60/680,386, filed on May 11, 2005.
(60) Provisional application No. 60/494,237, filed on Aug. 11, 2003.
(60) Provisional application No. 60/501,483, filed on Sep. 9, 2003.
(60) Provisional application No. 60/504,133, filed on Sep. 19, 2003.
(60) Provisional application No. 60/513,854, filed on Oct. 23, 2003.
(60) Provisional application No. 60/573,534, filed on May 21, 2004.

(51) Int. Cl. H01L 29/76

(52) U.S. Cl. 257/66

(57) ABSTRACT

A matrix display driver comprises a flexible substrate, a gate line arranged linearly along one surface of the substrate, a source line arranged perpendicularly to the gate line but on the opposed surface of the substrate, the relative overlap of the gate line and source line defining a display switch, which further includes a pixel electrode, a drain electrically connected to the pixel electrode, a semiconductor disposed between the source line and the drain, and a channel gate, the channel gate electrically connected to the gate line by a via defined through the substrate, the channel gate being electrically insulated from the semiconductor by a dielectric, and wherein, when the display switch is actuated, current flows to the drain and the pixel electrode is energized. In an alternative embodiment, the source lines and gate lines are disposed in parallel on the same surface of the substrate.

### CROSS-REFERENCE TO RELATED APPLICATIONS

This application claims the benefit of and priority to U.S. Provisional Pat. Application No. 60/680,386 filed May 11, 2005, an is a continuation-in-part of U.S. patent application Ser. No. 10/916,212 filed Aug. 11, 2004, which claims the benefit of and priority to U.S. Provisional Pat. Application Nos. 60/494,237 filed Aug. 11, 2003, 60/501,483 filed Sep. 9, 2003, 60/504,133 filed Sep. 19, 2003, 60/513,854 filed Oct. 23, 2003, and 60/573,534 filed May 21, 2004, all of which are incorporated herein by reference.

### TECHNICAL FIELD OF THE INVENTION

The present invention relates to viewing devices and, more particularly, to an active matrix circuit capable of driving display images and text at very high resolution and with a flexible substrate.

### BACKGROUND OF THE INVENTION

Display manufacturers and research institutions have for many years been seeking to build displays that are increasingly larger, lighter, thinner, and capable of high resolution. Extreme competition within the marketplace continues to drive innovation in display design into the realm of building displays that are nearly as thin as paper. These same companies also are funding research with the goal of developing a bendable, flexible or even rollable display that could displace paper as the chosen medium in many applications—both in terms of cost and durability. Researchers have employed many new technologies and materials in search of solutions for the numerous issues faced in creating larger, thinner, and higher resolution displays.

Typically, the attributes of size, weight and resolutions counteract one another. For example, if you want a display that is thinner and lighter, it is typically not easily scalable to larger sizes. Or, if you want a display is larger, the resolution usually suffers. If your component materials are lightweight, such as organics on plastic, the electrical properties create issues with resistance at longer circuit lengths, reducing the size of the display. Until recent years, manufacturers continued to rely on better manufacturing processes and techniques while using the same materials to try to achieve improvements in these three factors. These manufacturers funded research to discover new materials that could replace existing materials and at the same time maintain commercial viability. As researchers have continued to overcome technology challenges in the lab, they often run into different issues trying to implement their technology on the manufacturer's production floor—often incurring significant and unanticipated expense or complications.

Accordingly, display manufactures continue to pursue manufacturing improvements that increase production yields and lower manufacturing costs as the best method for gaining advantage over their competitors. These same manufacturers know that they must, at the same time, fund internal and external research to create further alternative technology pathways eventually to gain competitive advantage going forward.

Independent research institutions, such as universities, also play an important role through the often autonomous nature of their respective fields of study. These institutions often receive grants from government agencies while at the same time receiving grants from private firms. Dual funding of research institutions sometimes creates a dilemma for the researchers because they occasionally get trapped between finding requirements of public money, which serves the greater good, and private money which usually is associated with specific profit goals.

The combination of manufacturers seeking improvements to design based on efficiency and researcher's pursuit of new technology based on scientific principles presents a gap large enough for independent inventors to generate novel and innovative solutions that fill the gap between existing industry and science. Independent inventors sit in a unique situation of innovative necessity due to the lack of an existing position within either industry or science. As a result, the solutions created are often pioneering.

Under the present invention, current materials, techniques and processes are simultaneously challenged which spawn's a completely unique advancement and enables three normally dependent attributes of display manufacturing and design; size, weight and resolution to become virtually independent. Challenging materials, techniques and processes concurrently was a result of searching for a product partner after initial design work was done and not finding a commercially available product or even a planned product that met size, weight or resolution requirements with the timelines required by product development. The current invention was designed from the perspective of fitting within a specific need precedent to the considerations of applying existing techniques, materials and processes. The current invention was completed with the end goal as the starting point. This end goal was the development of a flexible or rollable display device.

The unique combination of materials, processes and techniques incorporated within the present invention allows for a lowered weight factor in the device. Accordingly, the present invention answers specific needs associated with a rollable, large format, light weight and high resolution display for a portable device, but also provides advantageous options to thin-screen viewing devices in all markets.

### SUMMARY OF THE INVENTION

The current invention provides a conformable, bendable, flexible or rollable active matrix display backplane thin-film device. In embodiments of the current invention, the matrix display is connected to drivers, controllers, capacitors and integrated circuits capable of creating images and text.

The current invention provides a rollable active matrix display backplane without the requirement of stacking circuit lines—as is typically found in existing art. This change in circuit design is accomplished by changing the orientation and position of the integrated circuits which drive the electricity to pixels electrodes. In one embodiment, the current invention provides for circuit drivers and controllers to be placed at opposite ends of the circuit's horizontal plane with source and gate lines running in parallel. In another embodiment, source and gate lines run perpendicularly to one another, but on opposed sides of the substrate. In several embodiments, the present invention places pixel electrodes on the opposite side of the substrate from the semiconductor, gate lines, source lines and drains.

The current invention provides a rollable or flexible active matrix display backplane in which source and gate lines never intersect or overlap, in a first embodiment, by running the lines in parallel or, in a second embodiment, by running them perpendicularly to one another but on different sides of the display substrate. Both of these embodiments remove the requirement for added dielectric materials as an insulator between layers of stacked lines, which is conventional. In the present invention a column and row pattern is constructed in which source and gate lines are placed on opposing sides of the substrate and the substrate itself is used as a natural dielectric. This configuration eliminates dielectric materials needed to separate the circuit lines. Dielectric materials in the existing art are used as a method for eliminating shorts at the overlays of intersecting circuit points. Typically, in existing active matrix circuit design, the circuit lines are stacked in a perpendicular orientation to one another on a horizaontal plane and separated by dialectric material to keep the points of intersection from shorting out. In the current invention, dialectric material is not used to insulate source and gate lines form each other because the lines do not intersect or overlap; thus, no electrical shoring points are created. In this present invention, dialectic material or oxide may be used as an insulator between the semiconductor and one or more components of the pixel switch (i.e., the gate, source, and drain) and between the components of the pixel switch itself. Dialectric material may also reside between the rows of circuits to provide an insulator therebetween. Further, dialectric material may also be used as masking material when depositing semiconductors or, more simply, as a mask for an organic semiconductor that is capable of being deposited by various methods, such as inkjet deposition or sputtering techniques to specific locations within the overall circuit design.

In one embodiment, the current invention provides a rollable active matrix display backplane where all circuit lines never intersect. This design allows for very easy scaling along horizontal and vertical axis of the display plane allowing for easy interconnection of edge circuits at either end of the display circuit and creating independence between pixel electrode size and circuit line/trace size. Such arrangement also allows for easily changing the aspect ratio of the finished display produced by increasing the length of the pattern to increase the number of pixels oriented horizontally or by adding to the number of rows in the circuit design to increase the number of pixels oriented vertically on the matrix plane. Additional circuit length and additional circuit rows can be added independently and/or cumulatively to achieve the desired effect in either overall display size or display resolution.

The circuit design allows for a display backplane approaching an unlimited width and/or height. In existing art, as the width of the display grows, the height of the display must also grow because of the row and column design. In existing art there is also additional circuit area required to connect to the active matrix pattern to the display drivers. In one embodiment, the display drivers connect to each end of the row only design without the need for additional edge circuit. Additional rows increase the height and/or the resolution of the display which is entirely independent of extending the length of the circuits. The length of the circuits can be continuously extended to distances such that the display can be created on a scale that is capable of covering an entire wall—similar to wall paper.

In existing art, pixel electrodes of the active matrix circuit design are also typically stacked to achieve high resolution as necessary. In one embodiment, a rollable active matrix display backplane is comprised of a flexible plastic substrate with the entire circuit resident on one plane of the substrate while still achieving a high resolution. In another embodiment, the flexible substrate has some components of the pixel switches resident on one plane or surface of the substrate and other components disposed on the other or opposed plane or surface of the substrate, which are connected through vias formed or created through the substrate.

### BRIEF DESCRIPTION OF THE DRAWINGS

FIG. 1 is a side perspective cut away view of a portable rollable active matrix digital display having protective layers associated therewith in one embodiment of the invention;

FIG. 2 is a side perspective cut away view of a rollable active matrix digital display having a microcapsule display layer and flexible active matrix driver layer and protective layers associated therewith in another embodiment of the invention;

FIG. 3 is a side cross-sectional perspective view of an active matrix flexible display driver layer showing the design for the addressable points of the active matrix flexible display driver layer in an embodiment of the invention;

FIG. 4 is a side perspective view of an active matrix flexible display driver layer and a display layer showing how the addressable points of the active matrix flexible display driver layer have rotated the particles within the display layer by changing the electrical polarity of those points either positively or negatively which rotate the display layer particles in an embodiment of the invention;

FIG. 5 is a logical block diagram of the driver and controller electronics used to create the visual image on the digital display in an embodiment of the invention;

FIG. 6 is a simple design model of one gate line circuit controller and one source line circuit controller attached to and showing a row only design of the active matrix circuit;

FIG. 7 is an electrical schematic of one gate line circuit controller and one source line circuit controller attached to and showing a row only design of the active matrix circuit including a subset of the pixel electrodes;

FIG. 8 is a cross-sectional circuit block diagram of a flexible active matrix driver layer of a first, row-only embodiment of the invention;

FIG. 9 is a block diagram showing the top view of a first circuit design of the active matrix driver layer of FIG. 8;

FIG. 10 is a block diagram showing the top view of the gate line circuits of the active matrix driver layer circuit design of FIG. 9:

FIG. 11 is a block diagram showing the top view of the source line circuit of the active matrix driver layer circuit design of FIG. 9;

FIG. 12 is a block diagram showing the top view of the drain line circuit of the active matrix driver layer circuit design of FIG. 9;

FIG. 13 is a block diagram showing the top view of the pixel electrodes of the active matrix driver layer circuit design of FIG. 9;

FIG. 14 is a block diagram showing the top view of the semiconductor/TFT array of the active matrix driver layer circuit design of FIG. 9;

FIG. 15 is a block diagram showing the top view of a second circuit design of the active matrix driver layer of FIG. 8;

FIG. 16 is a block diagram showing the top view of the gate line circuit of the active matrix driver layer circuit of FIG. 15;

FIG. 17 is a bock diagram showing the top view of the source line circuit of the active matrix driver layer circuit design of FIG. 15;

FIG. 18 is a block diagram showing the top view of the drain line circuit of the active matrix driver layer circuit design of FIG. 15;

FIG. 19 is a block diagram showing the top view of the pixel electrodes of the active matrix driver layer circuit design of FIG. 15;

FIG. 20 is a block diagram showing the top view of the semiconductor/TFT array of the active matrix driver layer circuit design of FIG. 15;

FIG. 21 is a block diagram showing the top view of a third circuit design of the active matrix driver layer of FIG. 9;

FIG. 22 is a block diagram showing the top view of the gate line circuit of the active matrix driver layer circuit design of FIG. 21;

FIG. 23 is a block diagram showing the top view of the source line circuit of the active matrix driver layer circuit design of FIG. 21;

FIG. 24 is a block diagram showing the top view of the drain line circuit of the active matrix driver layer circuit design of FIG. 21;

FIG. 25 is a block diagram showing the top view of the pixel electrodes of the active matrix driver layer circuit design of FIG. 21;

FIG. 26 is a block diagram showing the top view of the semiconductor/TFT array of the active matrix driver layer circuit design of FIG. 21;

FIG. 27 is a block diagram showing the top view of a fourth circuit design of the active matrix driver layer of FIG. 8;

FIG. 28 is a block diagram showing the top view of the gate line circuit of the active matrix driver layer circuit design of FIG. 27;

FIG. 29 is a block diagram showing the top view of the source line circuit of the active matrix driver layer circuit design of FIG. 27;

FIG. 30 is a block diagram showing the top view of the drain line circuit of the active matrix driver layer circuit design of FIG. 27;

FIG. 31 is a block diagram showing the top view of the pixel electrodes of the active matrix driver layer circuit design of FIG. 27;

FIG. 32 is a block diagram showing the top view of the semiconductor/TFT array of the active matrix driver layer circuit design of FIG. 27;

FIG. 33 is a cross-sectional circuit block diagram of a flexible active matrix driver layer of a second, row-only embodiment of the invention;

FIG. 34 is a cross-sectional circuit block diagram of a flexible active matrix driver layer of a third, row-only embodiment of the invention;

FIG. 35 is a block diagram showing the top view of a first circuit design of the active matrix driver layer of FIG. 33;

FIG. 36 is a block diagram showing the top view of the laser vias of the active matrix driver layer circuit design of FIG. 35;

FIG. 37 is a block diagram showing the top view of the gate line circuit of the active matrix driver layer circuit design of FIG. 35;

FIG. 38 is a block diagram showing the top view of the source line circuit of the active matrix driver layer circuit design of FIG. 35;

FIG. 39 is a block diagram showing the top view of the drain line circuit of the active matrix driver layer circuit design of FIG. 35;

FIG. 40 is a block diagram showing the top view of the pixel electrodes of the active matrix driver layer circuit design of FIG. 35;

FIG. 41 is a block diagram showing the top view of the semiconductor/TFT array of the active matrix driver layer circuit design of FIG. 35;

FIG. 42 is a block diagram showing the top view of a first circuit design of the active matrix driver layer of FIG. 34;

FIG. 43 is a block diagram showing the top view of the laser vias of the active matrix driver layer circuit design of FIG. 42;

FIG. 44 is a block diagram showing the top view of the gate line circuit of the active matrix driver layer circuit design of FIG. 42;

FIG. 45 is a block diagram showing the top view of the source line circuit of the active matrix driver layer circuit design of FIG. 42;

FIG. 46 is a block diagram showing the top view of the drain line circuit of the active matrix driver layer circuit design of FIG. 42;

FIG. 47 is a block diagram showing the top view of the pixel electrodes of the active matrix driver layer circuit design of FIG. 42;

FIG. 48 is a block diagram showing the top view of the semiconductor/TFT array of the active matrix driver layer circuit design of FIG. 42;

FIG. 49 is a block diagram showing the top view of a second circuit design of the active matrix driver layer of FIG. 33;

FIG. 50 is a block diagram showing the top view of the laser vias of the active matrix driver layer circuit design of FIG. 49;

FIG. 51 is a block diagram showing the top view of the gate line circuit of the active matrix driver layer circuit design of FIG. 49;

FIG. 52 is a block diagram showing the top view of the source line circuit of the active matrix driver layer circuit design of FIG. 49;

FIG. 53 is a block diagram showing the top view of the drain line circuit of the active matrix driver layer circuit design of FIG. 49;

FIG. 54 is a block diagram showing the top view of the pixel electrodes of the active matrix driver layer circuit design of FIG. 49;

FIG. 55 is a block diagram showing the top view of the semiconductor/TFT array of the active matrix driver layer circuit design of FIG. 49;

FIG. 56 is a block diagram showing the top view of a second circuit design of the active matrix driver layer of FIG. 34;

FIG. 57 is a block diagram showing the top view of the laser vias of the active matrix driver layer circuit design of FIG. 56;

FIG. 58 is a block diagram showing the top view of the gate line circuit of the active matrix driver layer circuit design of FIG. 56;

FIG. 59 is a block diagram showing the top view of the source line circuit of the active matrix driver layer circuit design of FIG. 56;

FIG. 60 is a block diagram showing the top view of the drain line circuit of the active matrix driver layer circuit design of FIG. 56;

FIG. 61 is a block diagram showing the top view of the pixel electrodes of the active matrix driver layer circuit design of FIG. 56;

FIG. 62 is a block diagram showing the top view of the semiconductor/TFT array of the active matrix driver layer circuit design of FIG. 56;

FIG. 63 is a block diagram showing the top view of a third circuit design of the active matrix driver layer of FIG. 34;

FIG. 64 is a block diagram showing the top view of the laser vias of the active matrix driver layer circuit design of FIG. 63;

FIG. 65 is a block diagram showing the top view of the gate line circuit of the active matrix driver layer circuit design of FIG. 63;

FIG. 66 is a block diagram showing the top view of the source line circuit of the active matrix driver layer circuit design in of FIG. 63;

FIG. 67 is a block diagram showing the top view of the drain line circuit of the active matrix driver layer circuit design of FIG. 63;

FIG. 68 is a block diagram showing the top view of the pixel electrodes of the active matrix driver layer circuit design of FIG. 63;

FIG. 69 is a block diagram showing the top view of the semiconductor/TFT array of the active matrix driver layer circuit design of FIG. 63;

FIG. 70 is a cross-sectional circuit block diagram of a flexible active matrix driver layer of a fourth, row and column embodiment of the invention;

FIG. 71 is a block diagram showing the top view of the circuit design of the active matrix driver layer of FIG. 70;

FIG. 72 is a block diagram showing the top view of the laser via and gate circuit lines of the active matrix driver layer circuit design of FIG. 70;

FIG. 73 is a cross-sectional circuit block diagram of a flexible active matrix driver layer of a fifth row and column embodiment of the invention;

FIG. 74 is a block diagram showing the top view of the circuit design of the active matrix driver layer of FIG. 73;

FIG. 75 is a block diagram showing the top view of the laser via and gate circuit lines of the active matrix driver layer circuit design of FIG. 73.

### DETAILED DESCRIPTION OF THE INVENTION

In the following description, numerous specific details may be set forth to provide a thorough understanding of the present invention. However, it will be obvious to those skilled in the art that the present invention may be practiced without such specific details.

In describing the preferred embodiment of the present invention, reference will be made herein to the drawings in which like numerals refer to like features of the invention. It will be appreciated that a particular element may be included in various figures, as the drawings provide a variety of views of the invention. Accordingly, where reference is made to one or more drawings in the subsequent description, it will be appreciated that such reference is merely illustrative, as the drawings and description should be taken in their entirety to fully appreciate the described aspects of the invention. Further, it will be appreciated that elements may appear in one or more drawings without a reference numeral.

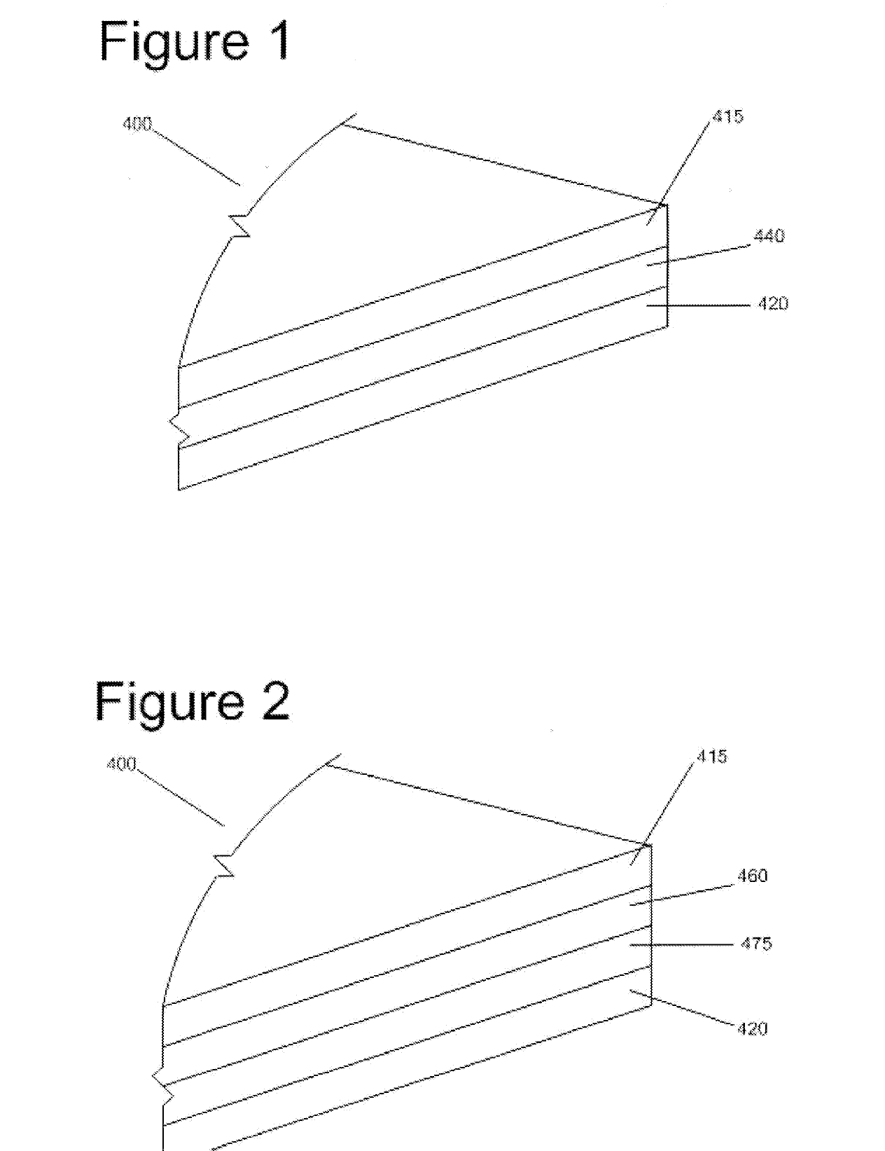

Referring first to FIG. 1, a rollable flexible digital display 400 uses a low power flexible microcapsule display layer 460 in some embodiments. The microcapsule display layer 460 is capable of displaying the last drawing or document displayed until it is necessary to switch to a different drawing or document.

Accordingly, the microcapsule layer 460 in conjunction with the upper transparent protective layer 415 and the flexible active matrix driver layer 475 is capable of generating drawings and documents displayed on the flexible microcapsule display layer 460 which are to be seen by the user.

The rollable flexible digital display assembly 400 comprises a flexible active matrix (OLED) RGB color display 440 or, in an alternative embodiment, a flexible microcapsule display layer 460 typically less than 1/10 millimeters in thickness. The rollable flexible digital display assembly 400 includes a transparent protective weather resistant upper layer 415, which is typically 3 to 4 mils thick, and includes adhesive 152 to bind to both the flexible active matrix (OLED) RGB color display 440 or in an alternative embodiment a flexible microcapsule display layer 460 and the protective weather resistant lower layer 420. The flexible active matrix (OLED) RGB color display 440 or, in an alternative embodiment, a flexible microcapsule display layer 460 includes a protective weather resistant lower layer 420 typically 3 to 4 mils thick including adhesive 152 oppositely disposed relative to the transparent weather resistant upper protective layer 415.

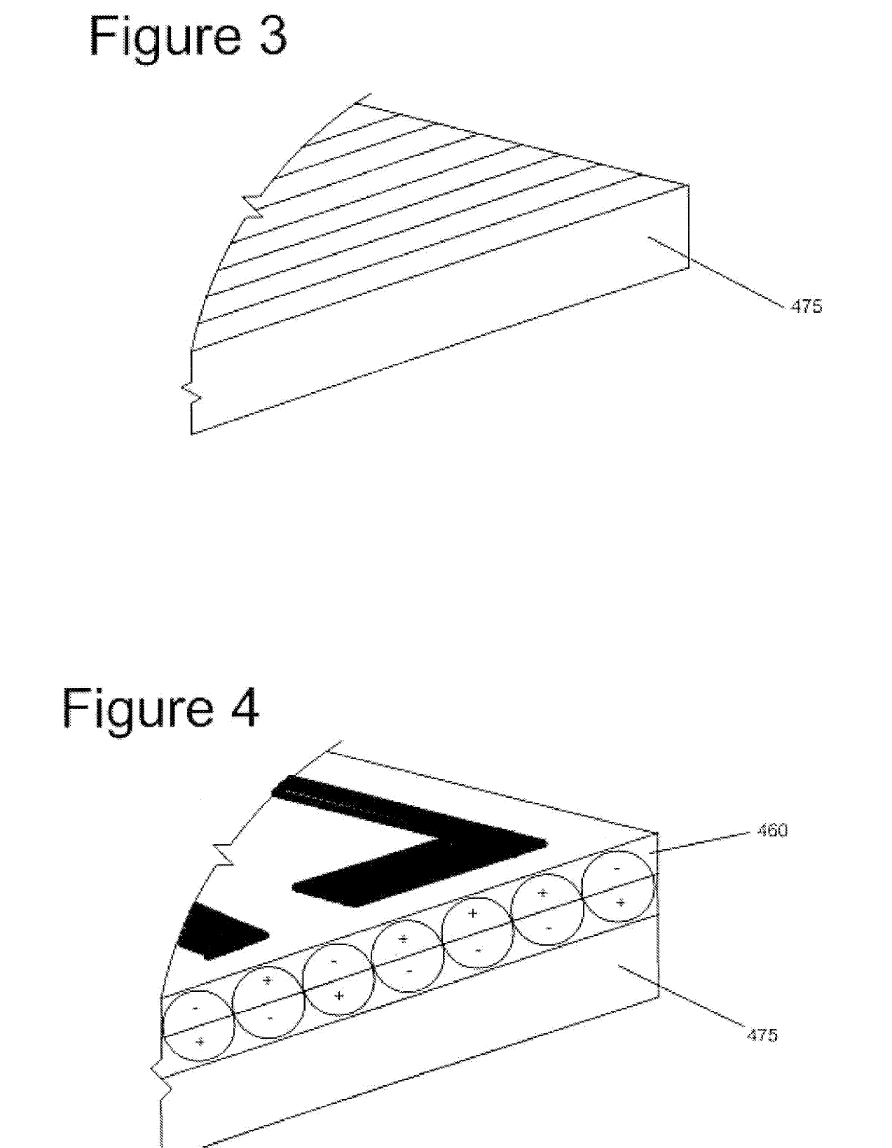

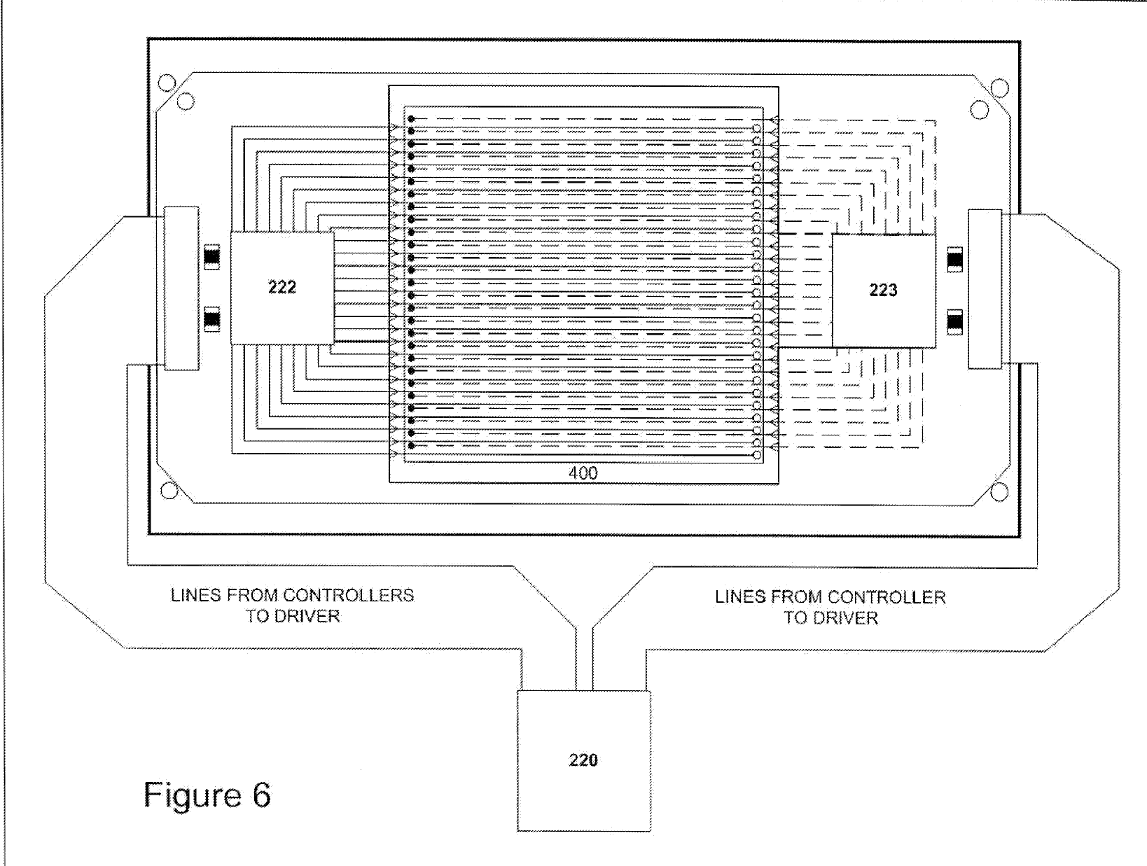

In yet another embodiment a flexible active matrix driver layer 475 is placed in between flexible microcapsule display layer 460 and the protective lower layer 420, as shown in FIG. 2. The flexible active matrix driver layer 475, as shown in FIGS. 3 and 4, comprises a flexible circuit board manufactured by companies, such as 3M, and produced with one metal or two metal circuits constructed on flexible polyimide or plastic substrates. For example, one layer polyimide substrate manufacturing is capable of one metal fine pitch circuitry to 35 μm (prototypes capable of 25 μm. These one metal polyimide circuits are available and currently manufactured by 3M and sold under the brand name Microflex™. The fine pitch circuits are organized in an active matrix parallel grid type design with all pixel electrodes addressable by the display controllers 220 (as shown in FIG. 6). The display controller 220 is capable of sending an electric current to a specific coordinate or set of many coordinates concurrently, which electrically interact (i) with the particles within the flexible microcapsule display layer 460, which is adhered to the flexible active matrix display driver layer 475, or (ii) directly to the pixels of the flexible active matrix (OLED) RGB color display 440. Once charged by flexible active matrix display driver layer 475, those electrically charged particles within the flexible microcapsule display layer 460 or the pixels of the flexible active matrix (OLED) RGB color display 440 are capable of generating an image, text, pictures and diagrams as shown in FIG. 4.

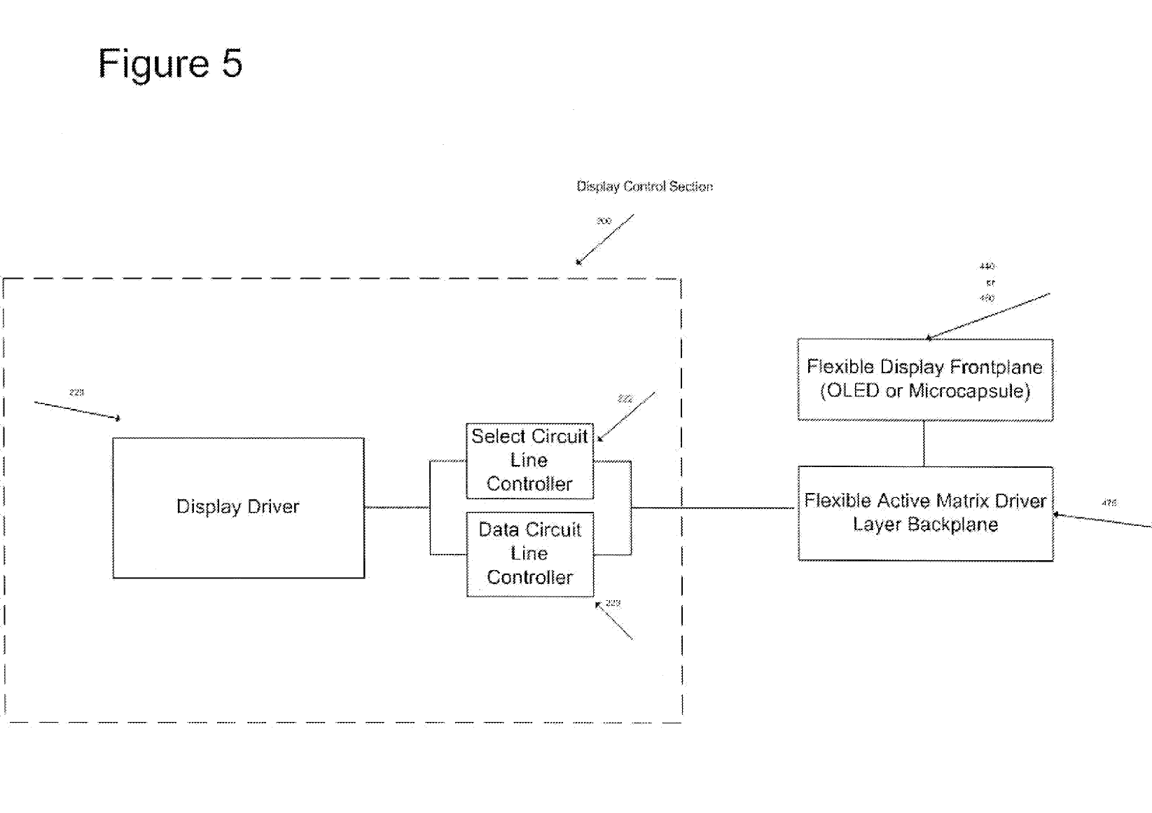

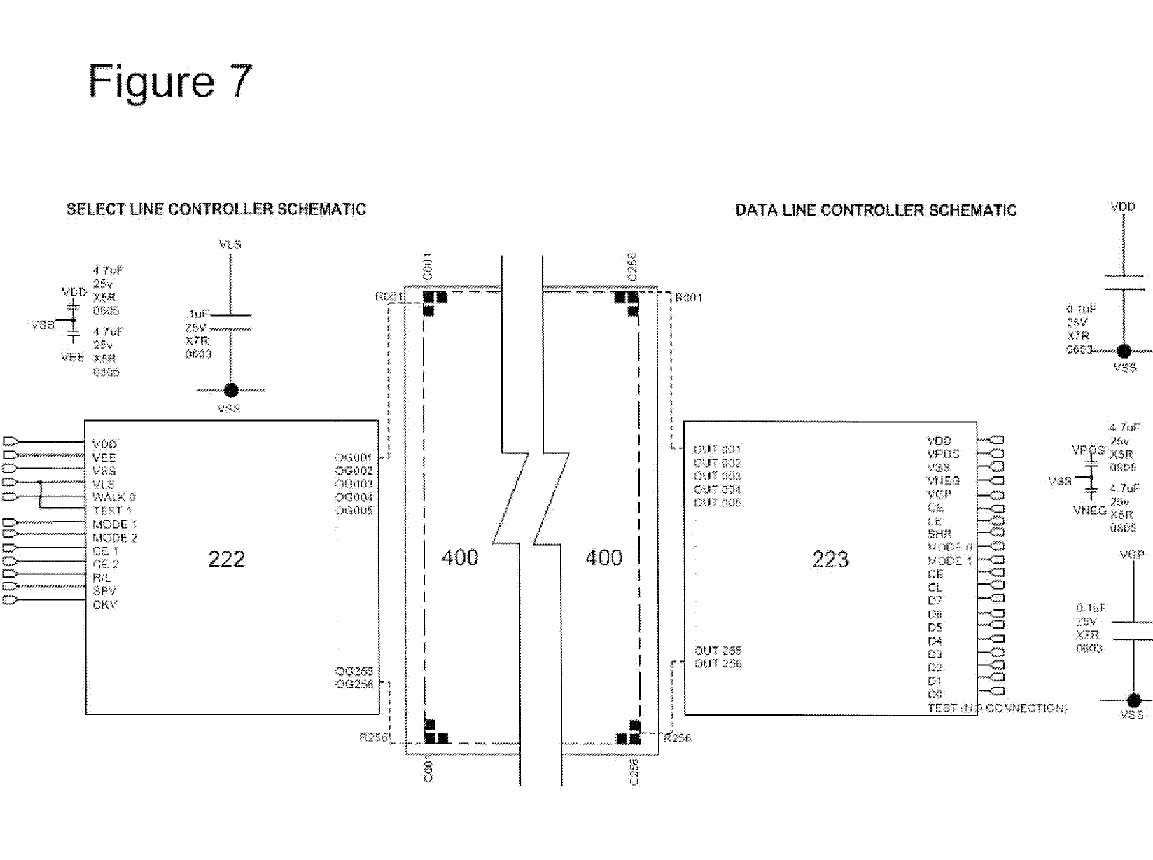

Referring to FIGS. 5-7, in a preferred embodiment, the display control section 200 includes a display driver clip 220, a gate circuit controller 222, a source circuit controller 223 connected to the active matrix driver backplane layer 475, which electrically drives a separate microcapsule display layer 460 or other alternative technology, such as an OLED display layer 440. Preferably, the active matrix driver backplane layer 475 and the microcapsule display layer 460 or OLED display layer 440 are laminated or otherwise combined to create the flexible display assembly 400.

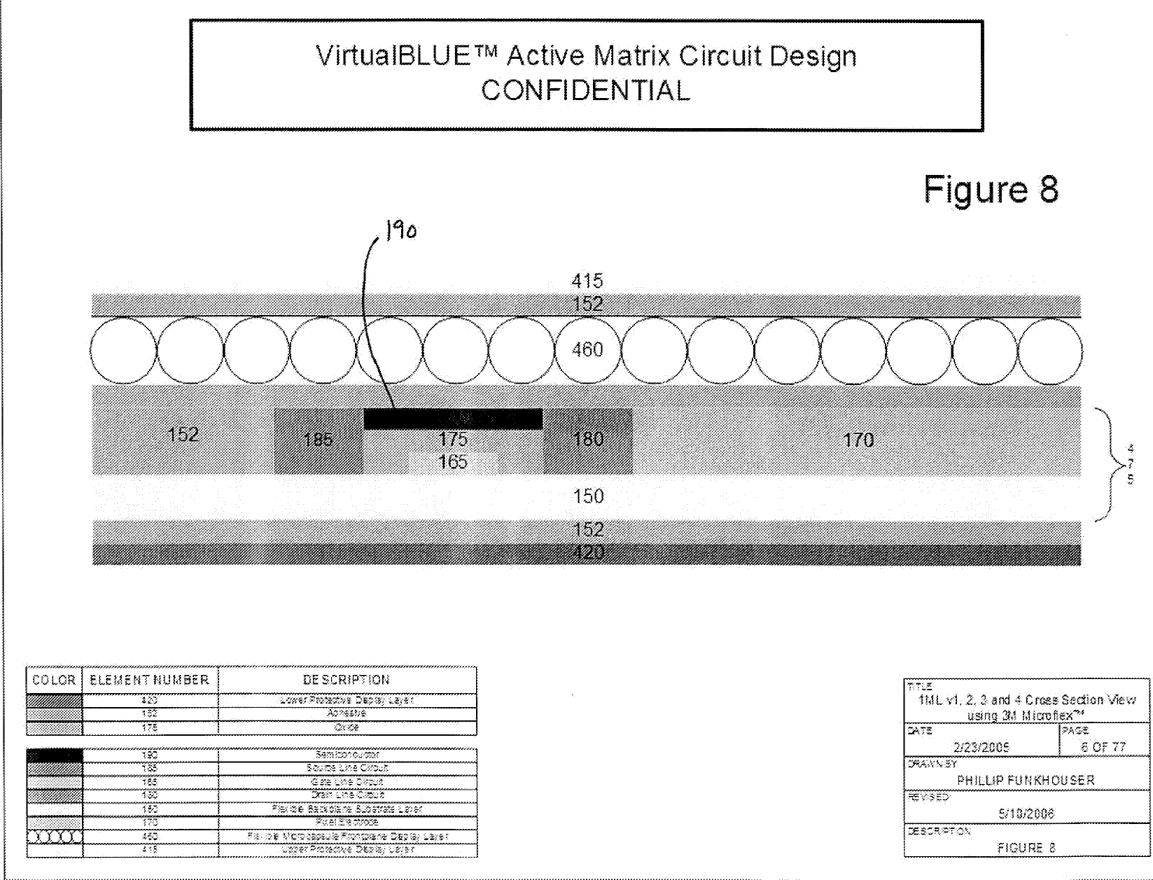

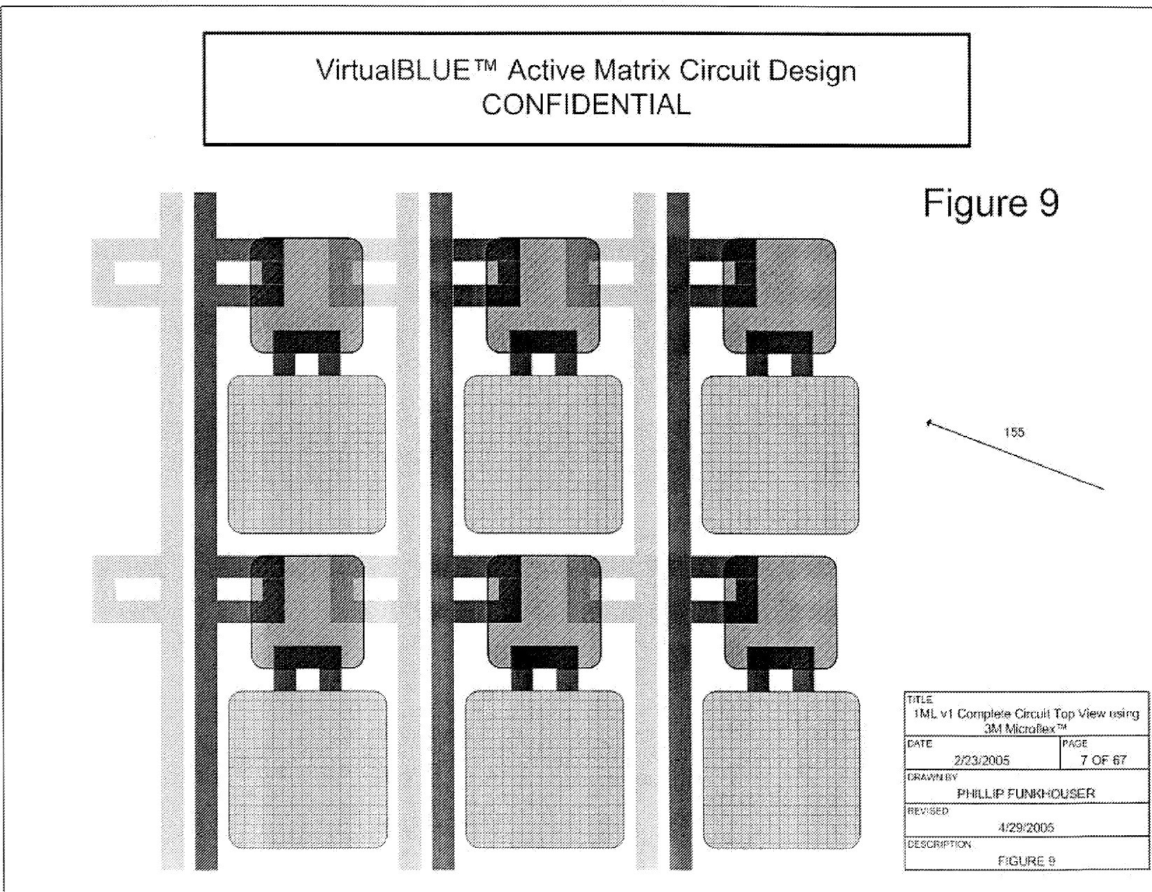

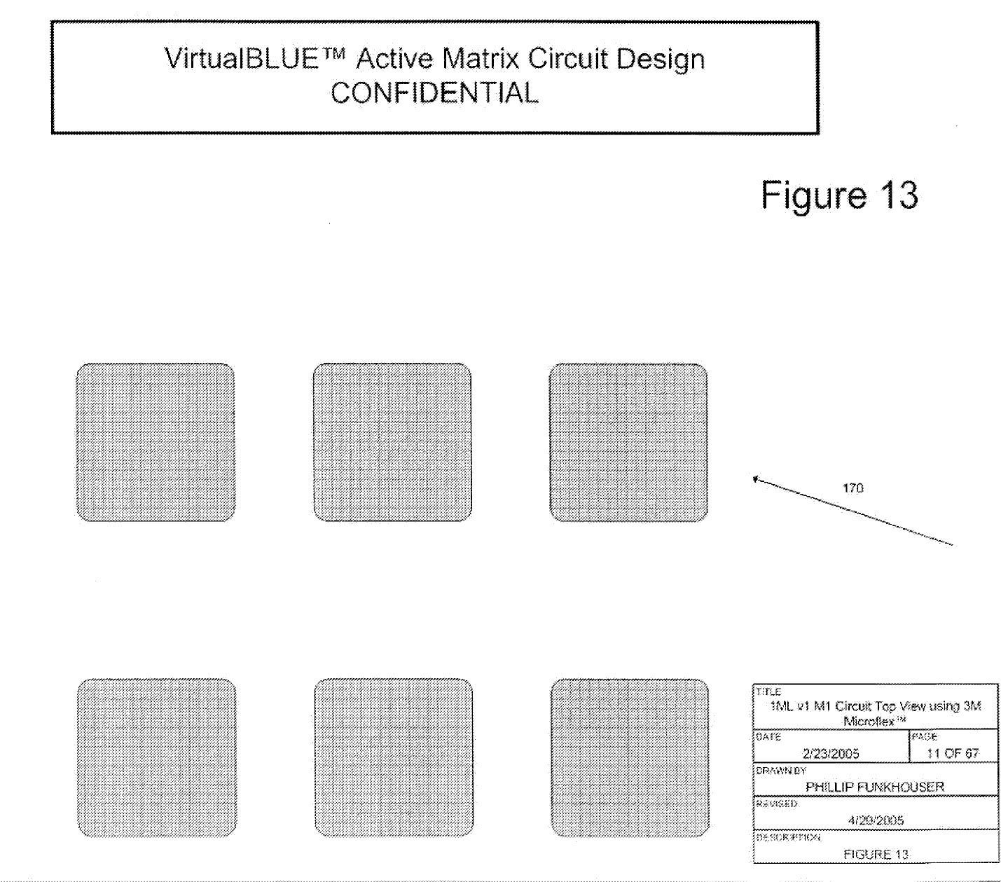

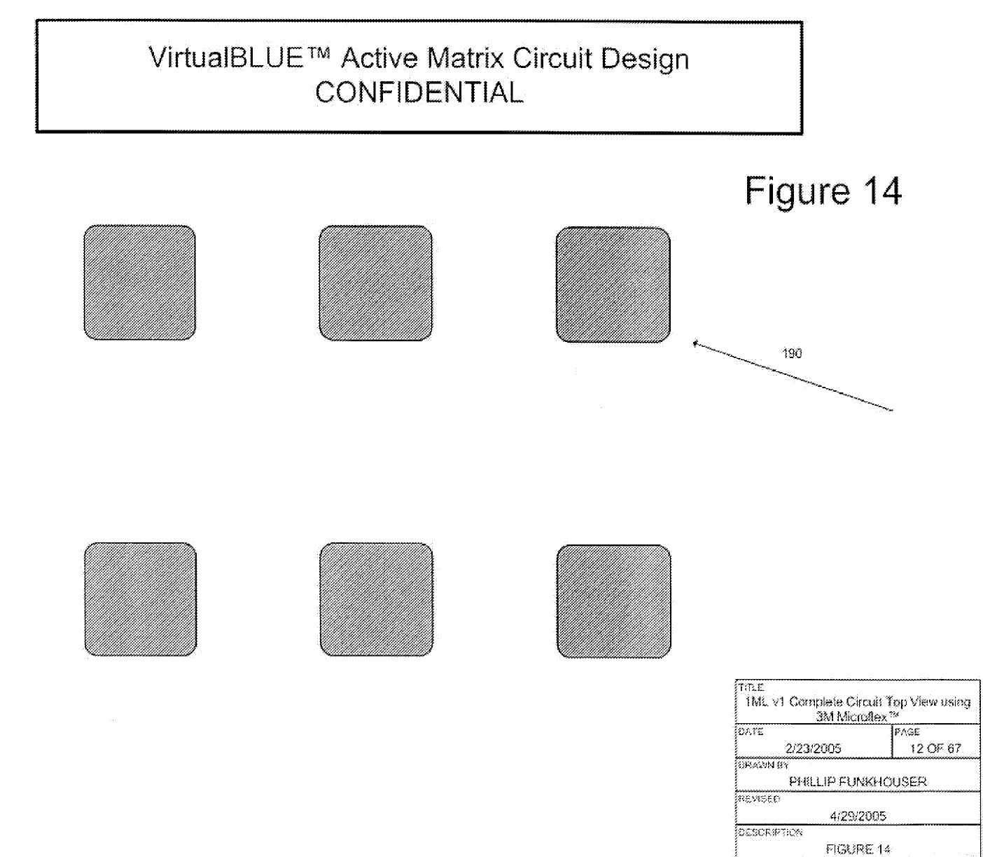

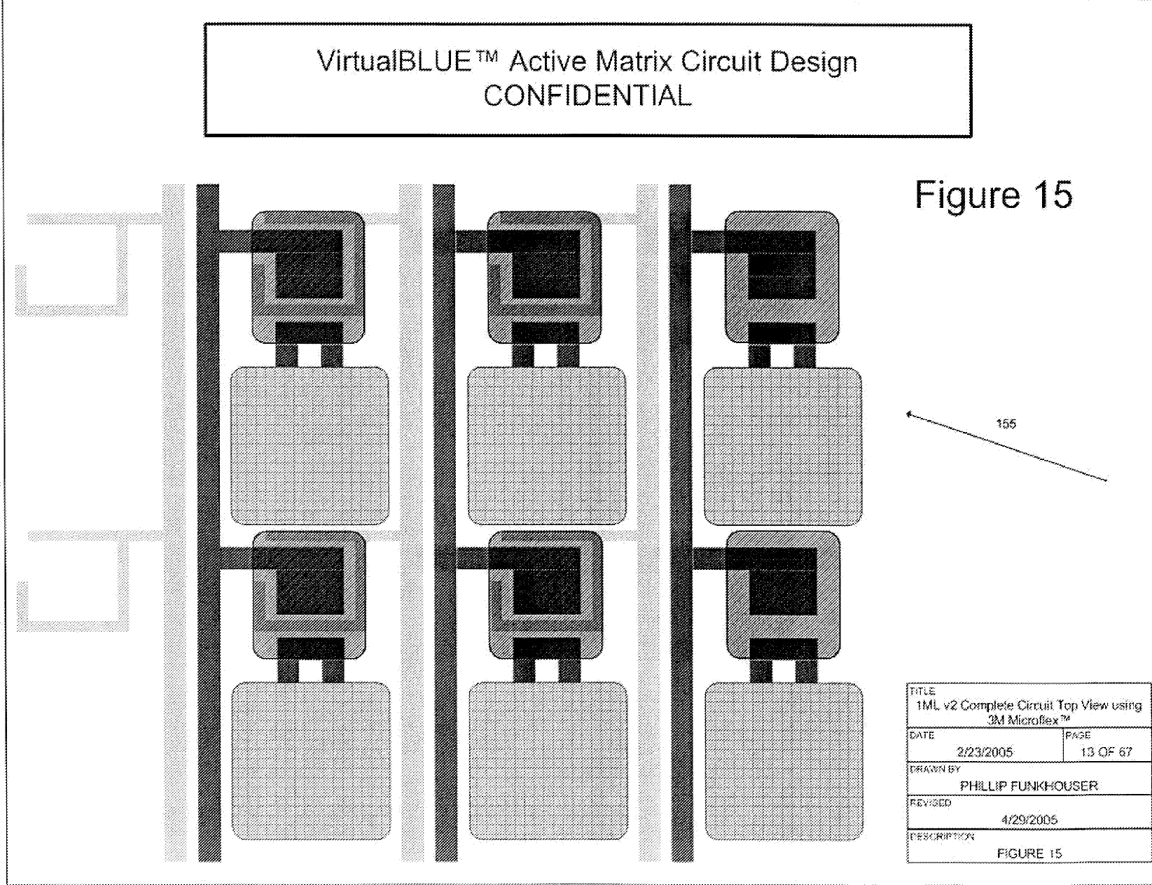

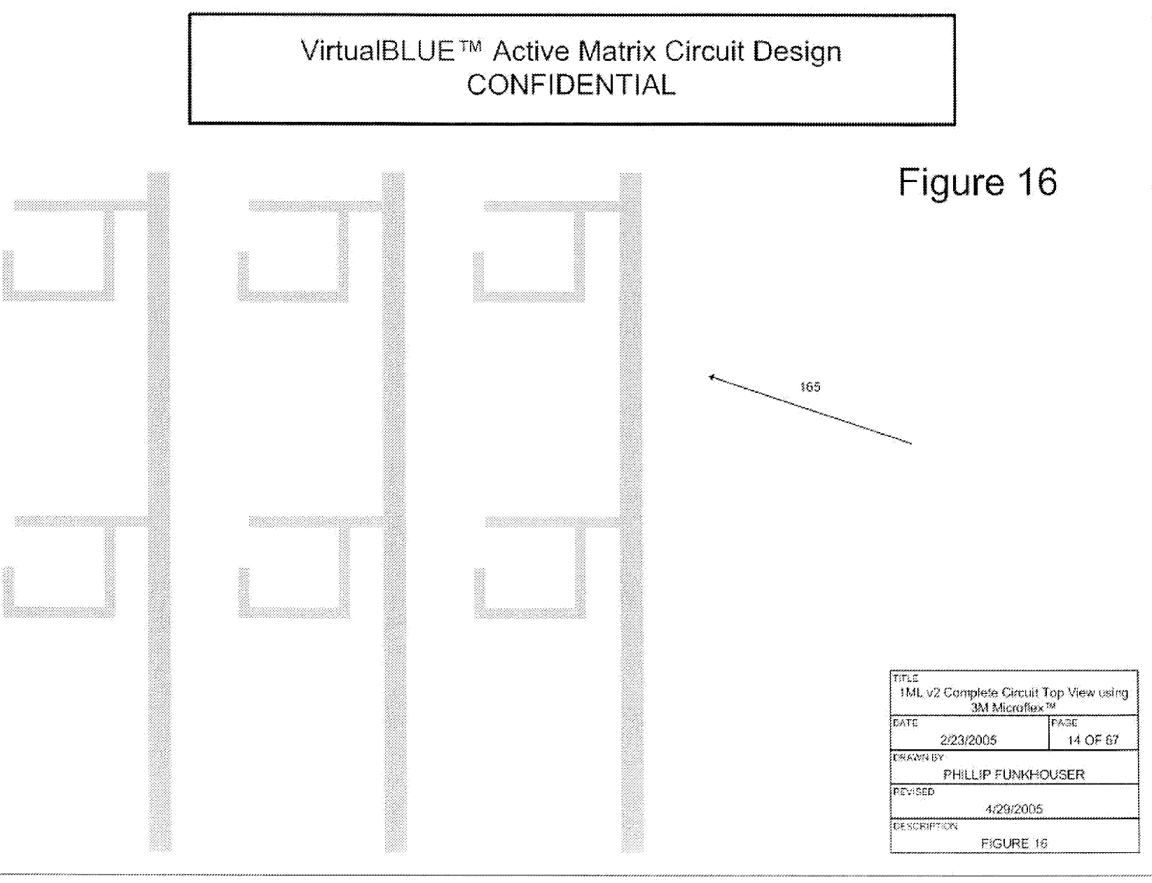

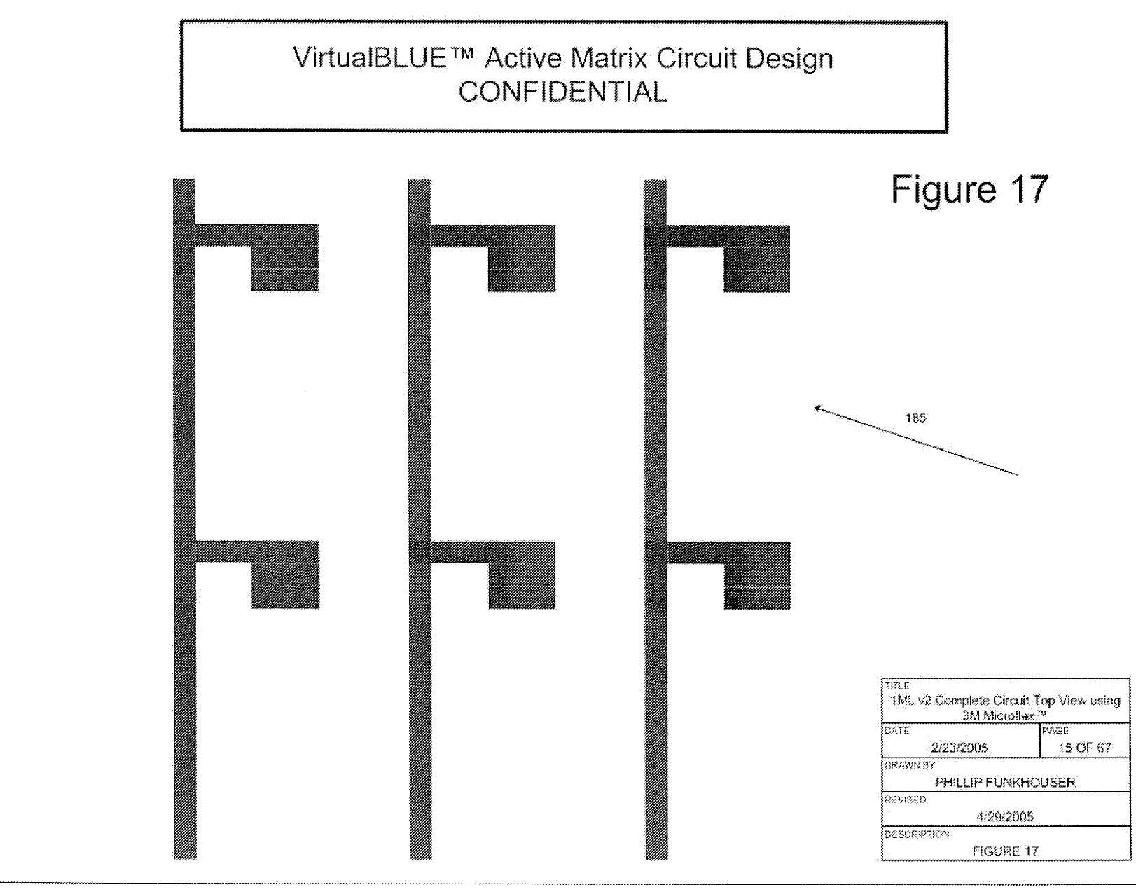

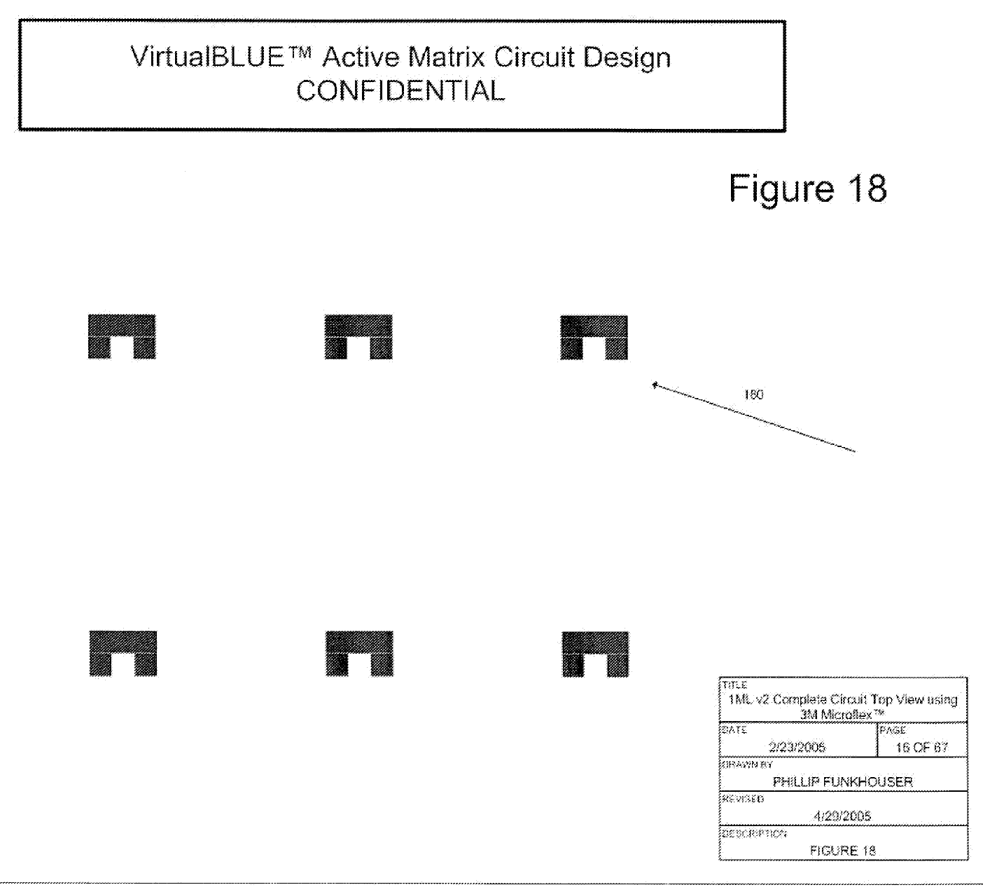

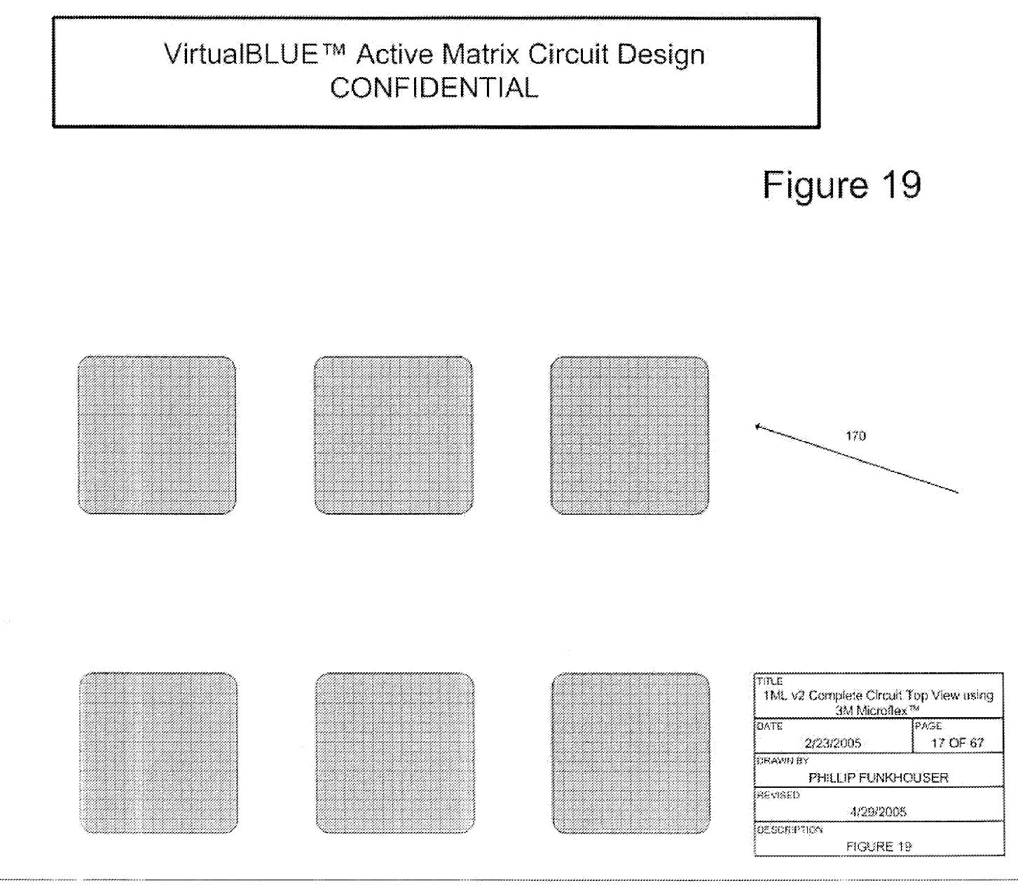

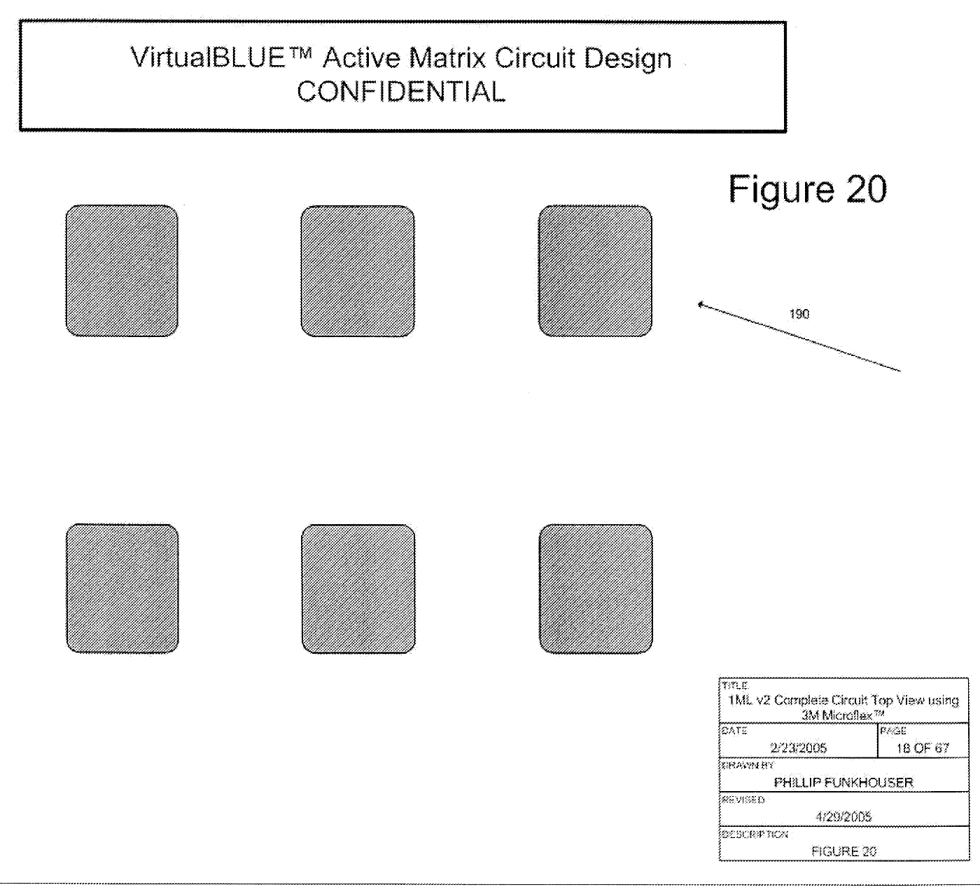

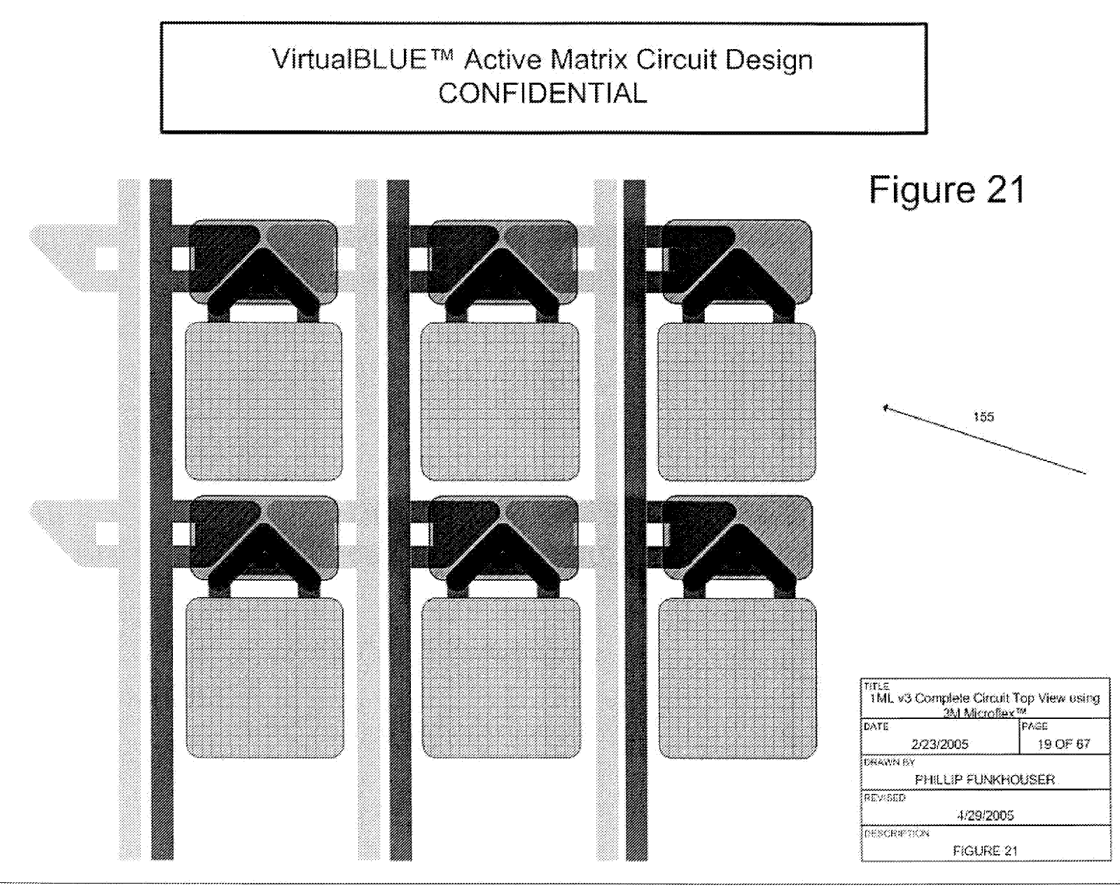

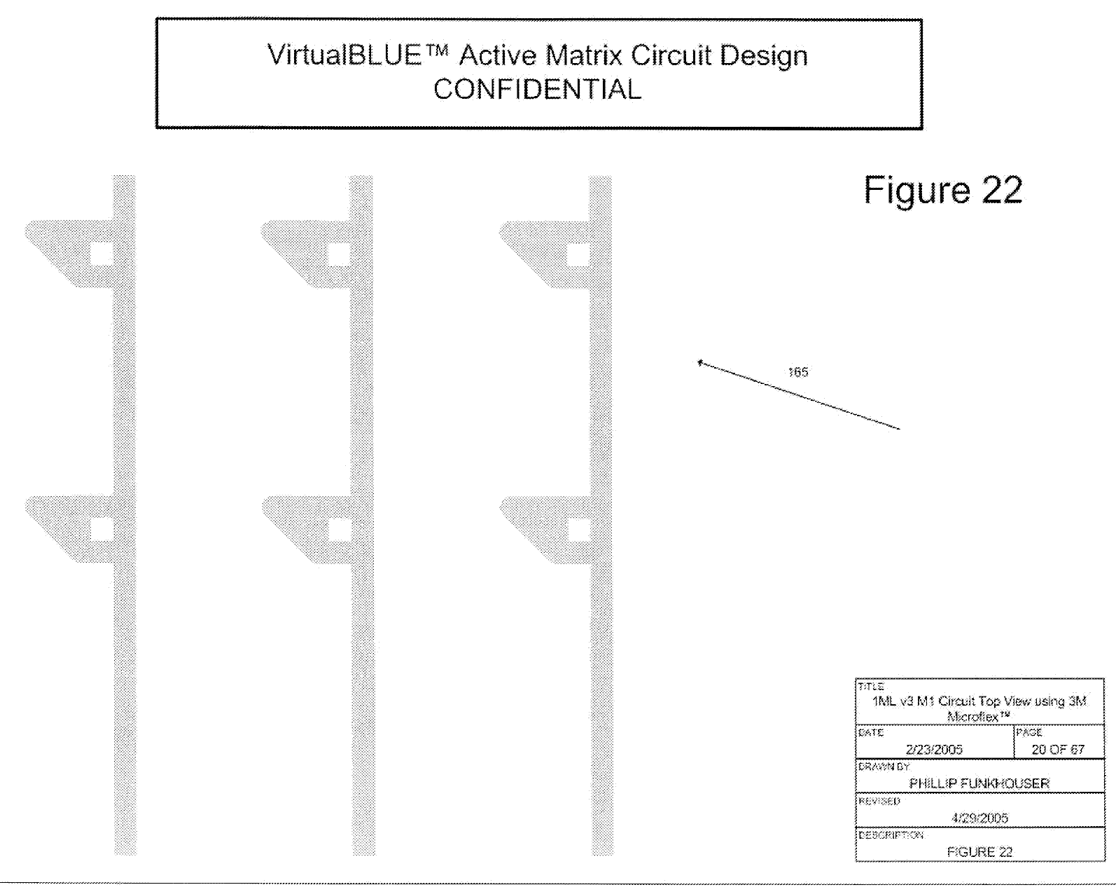

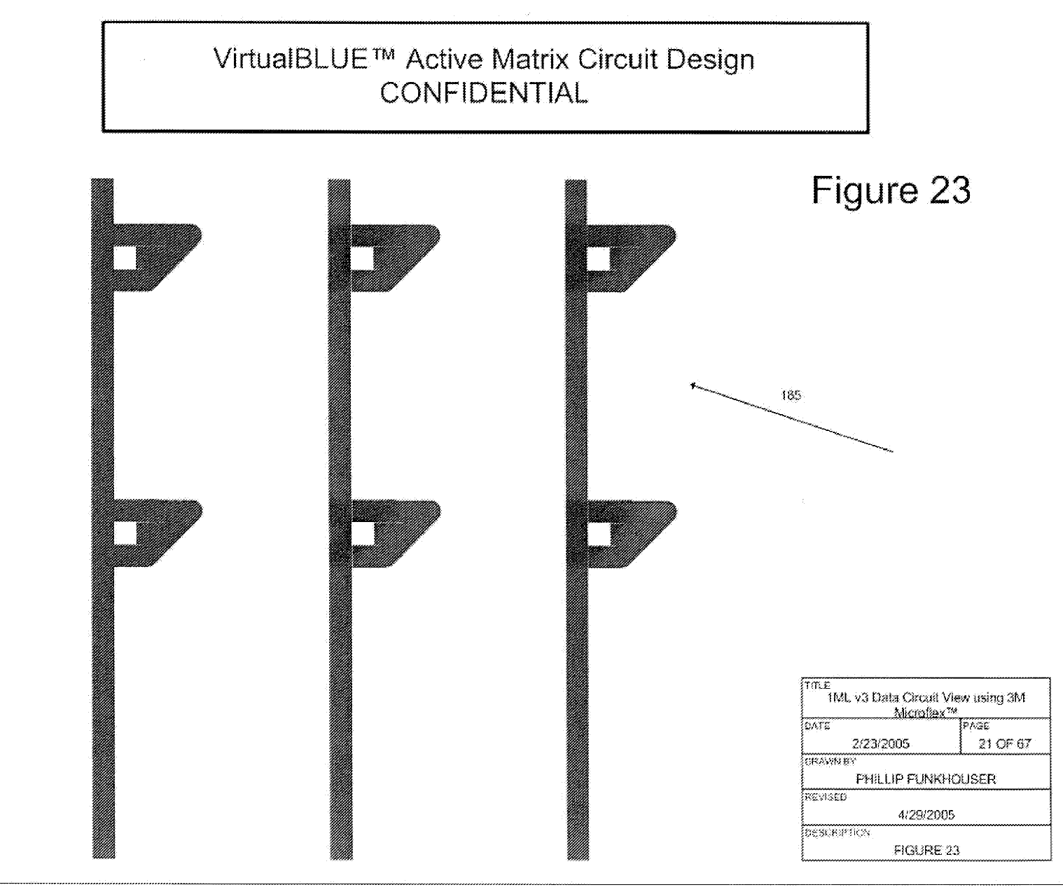

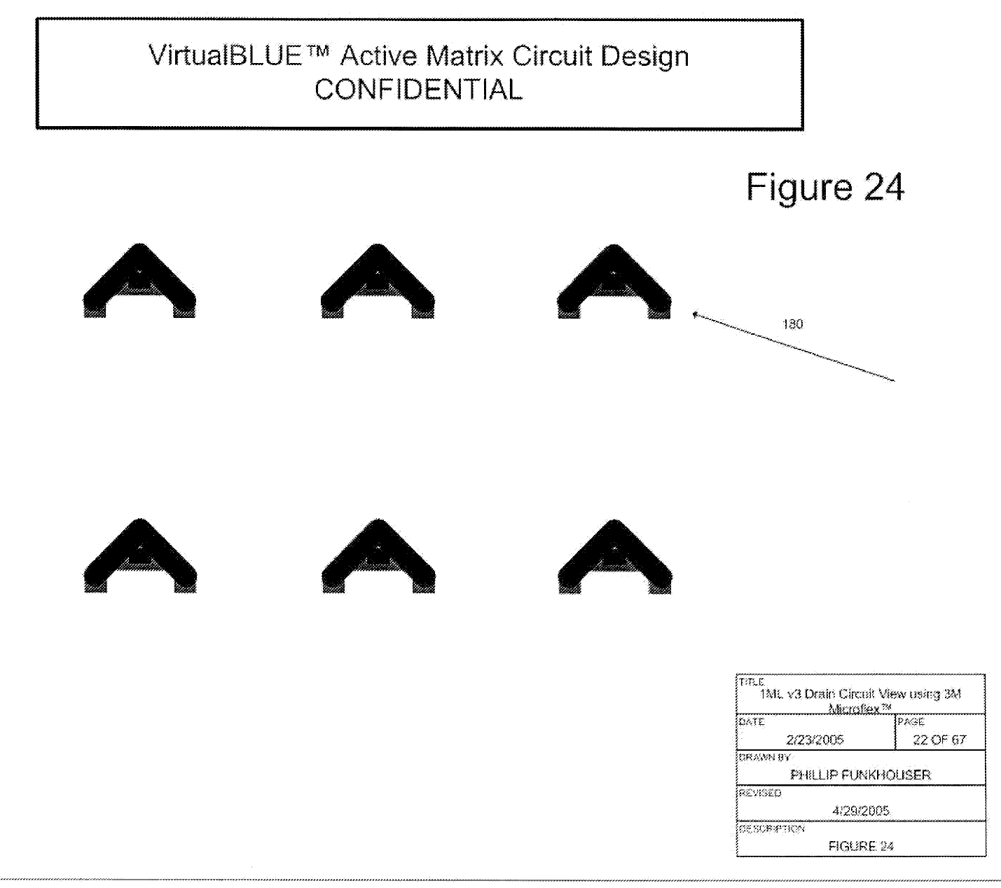

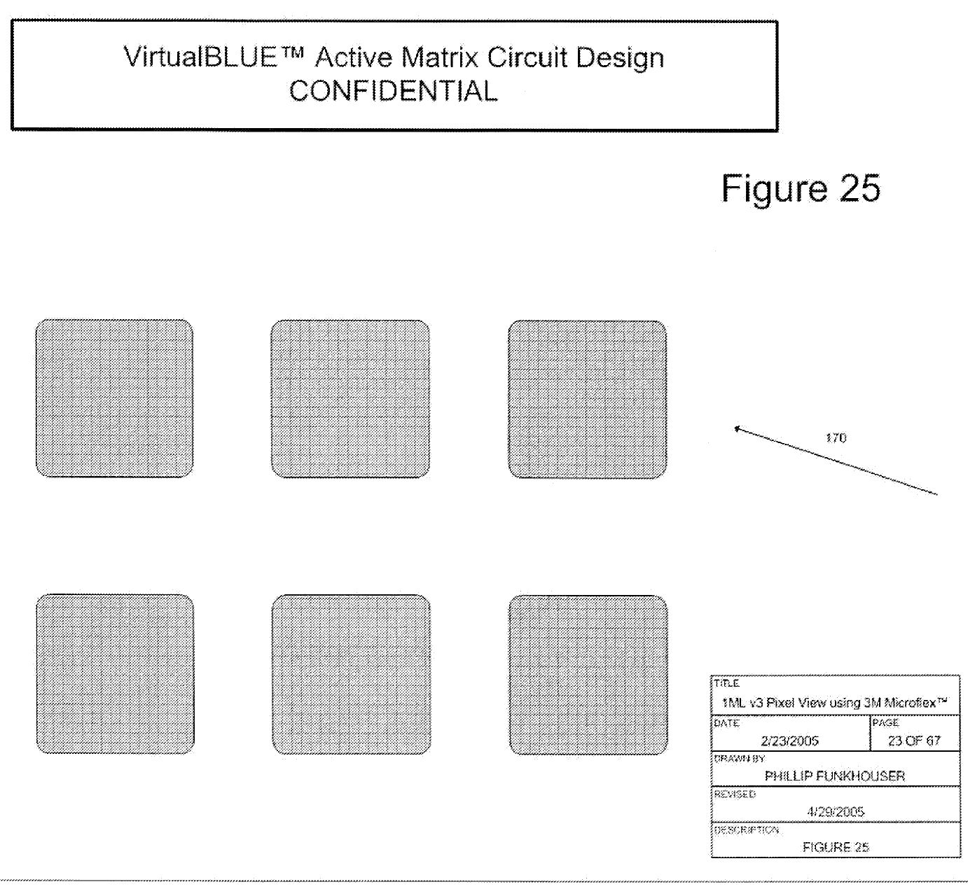

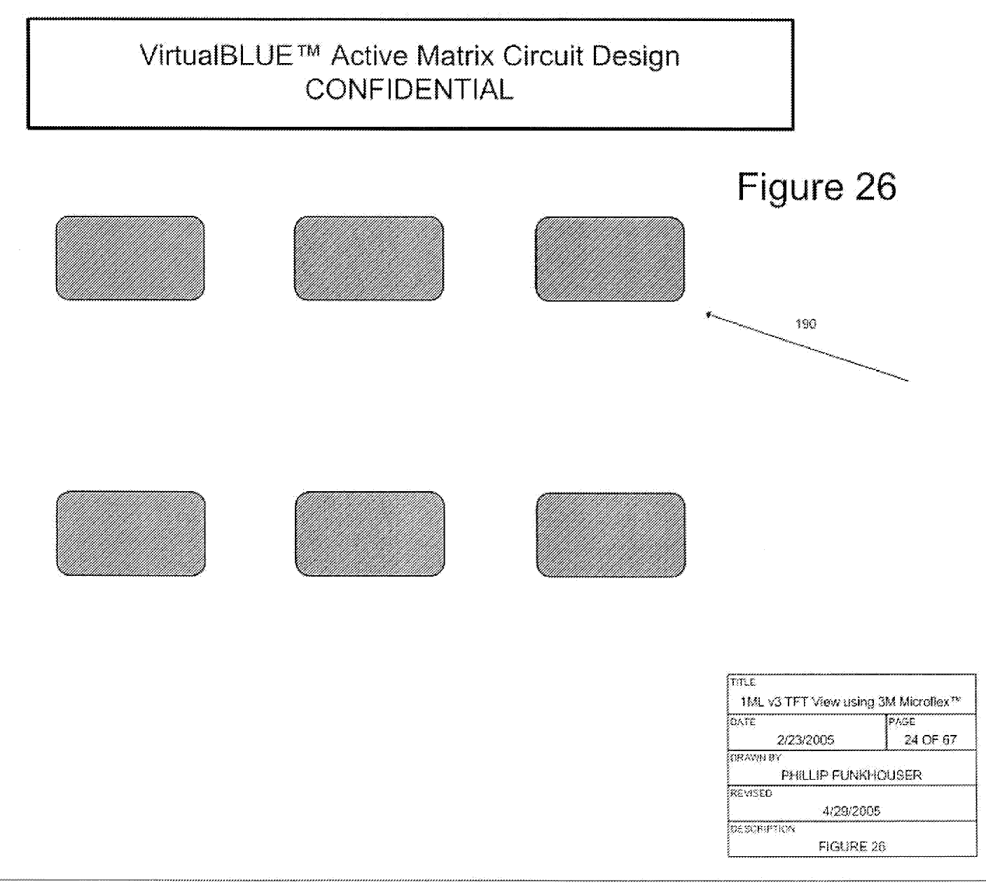

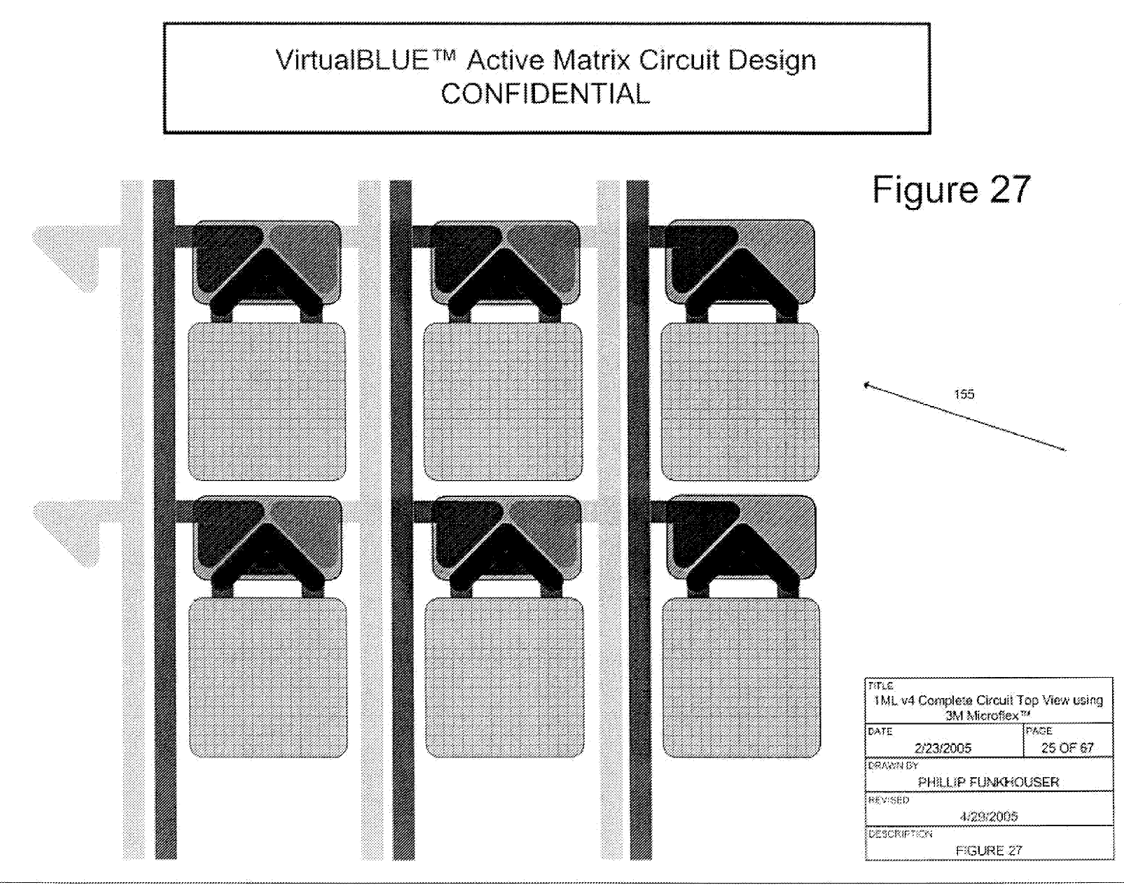

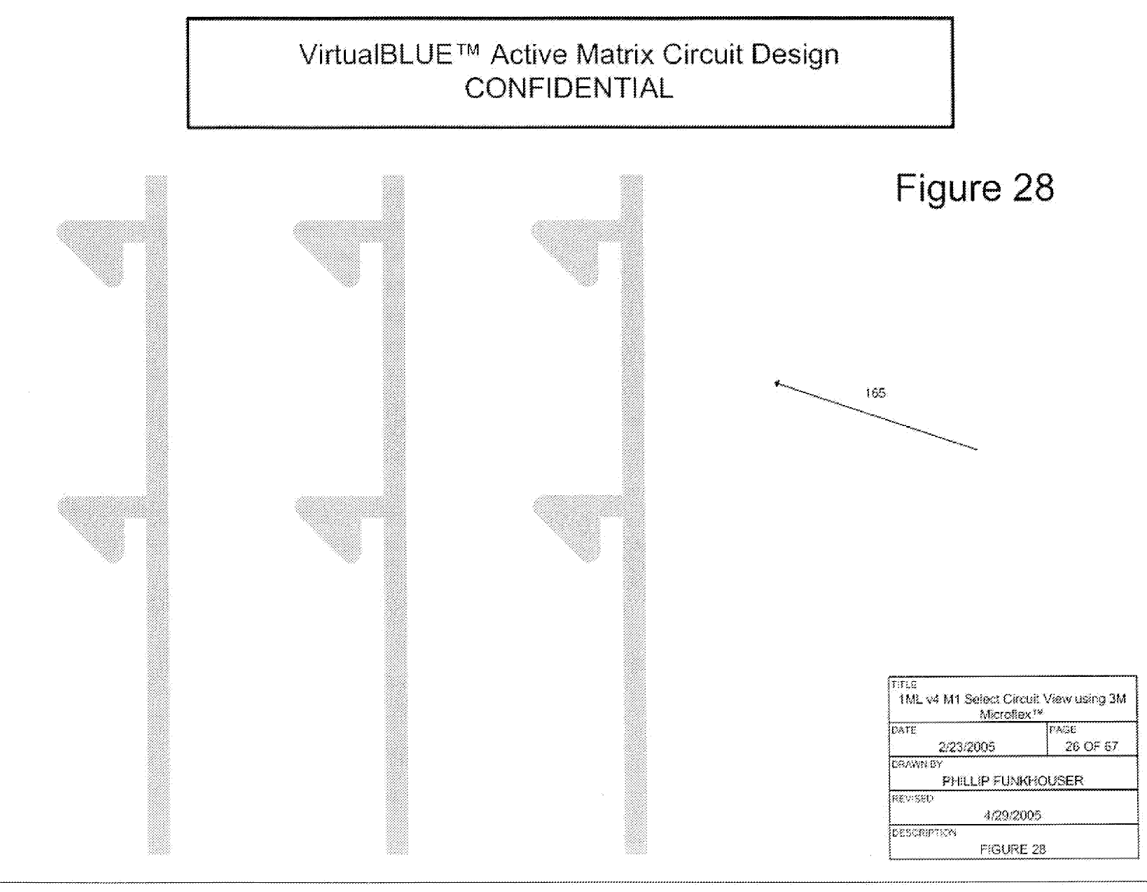

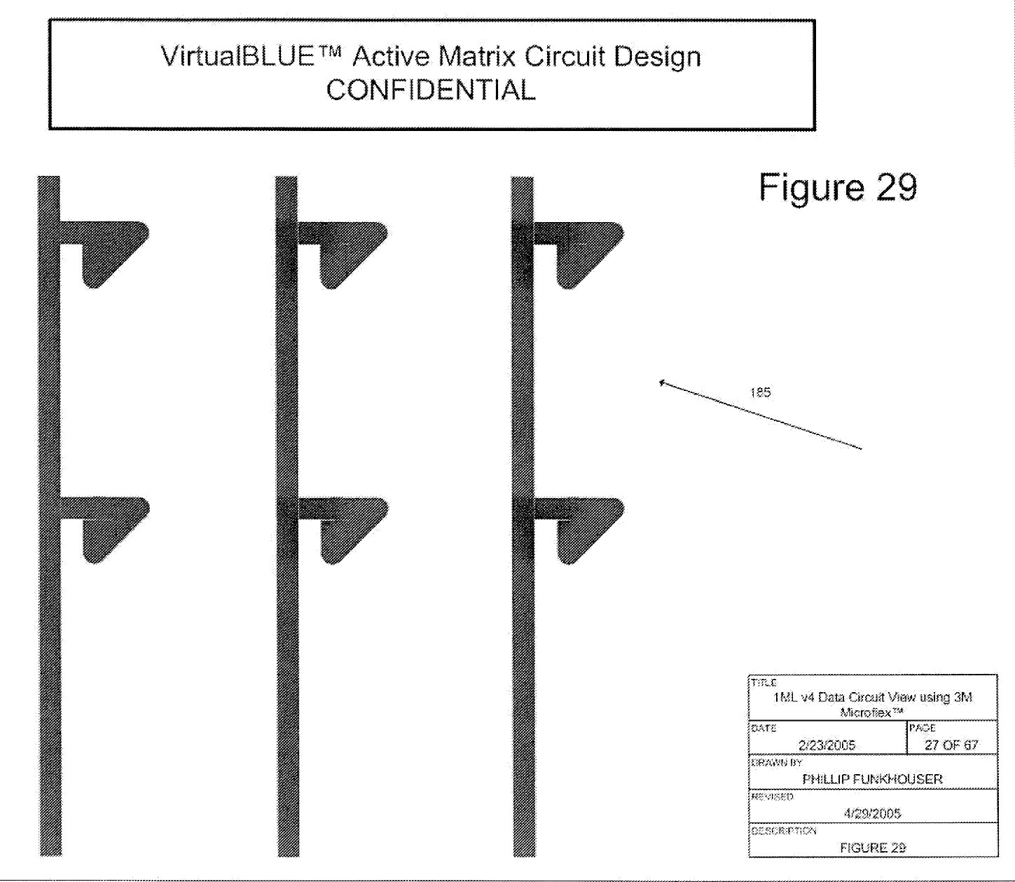

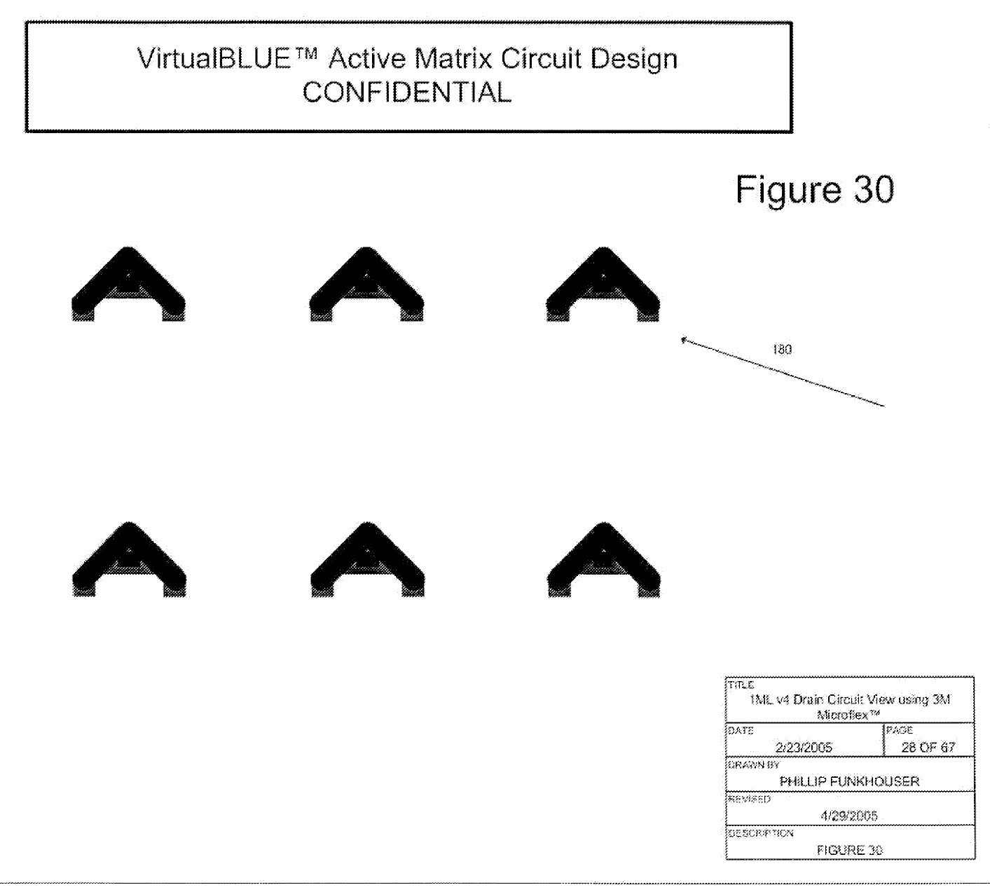

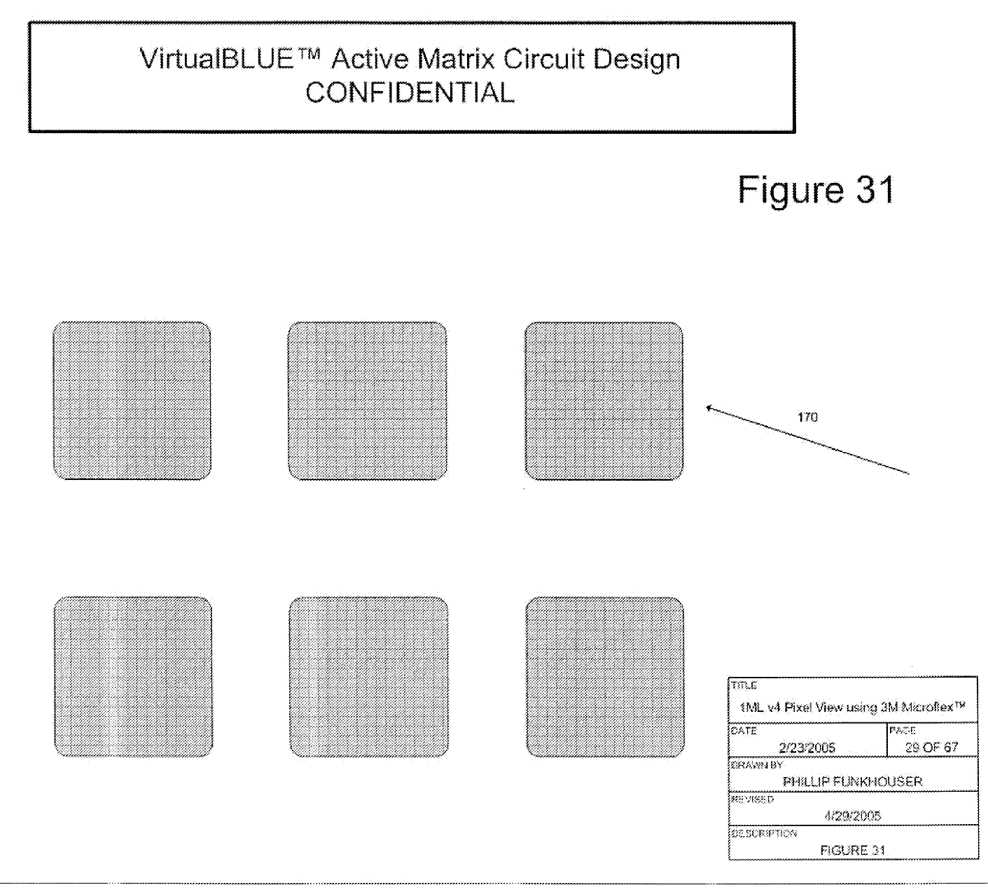

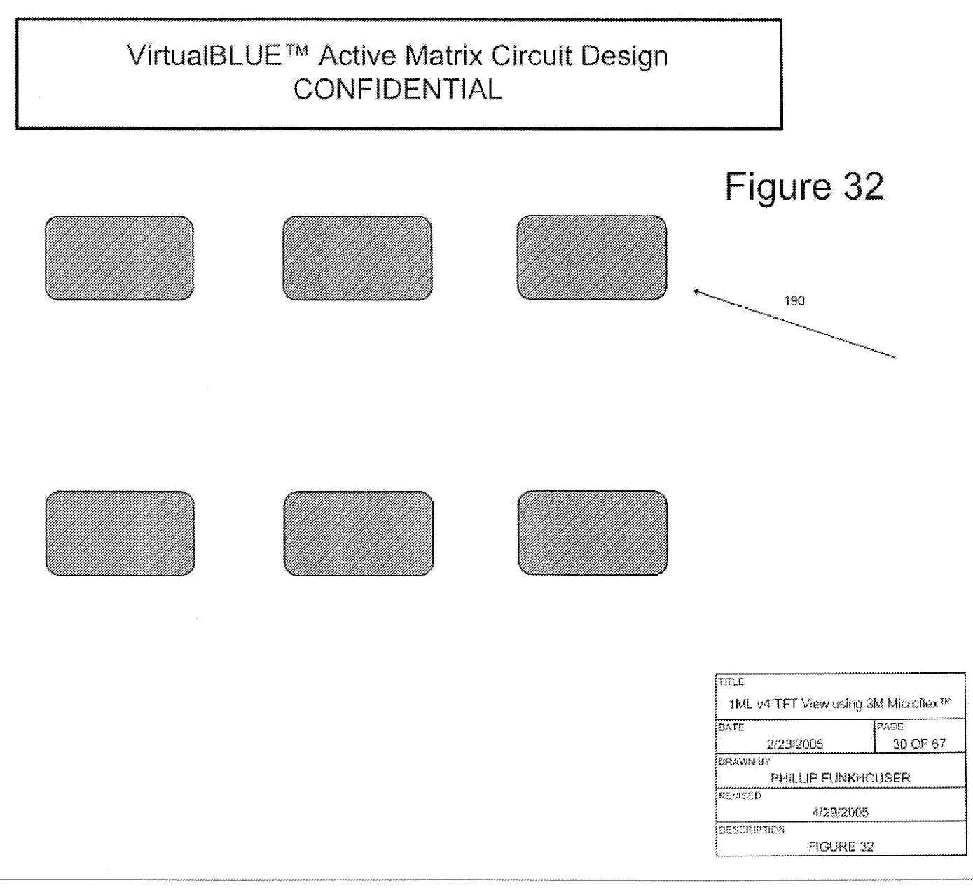

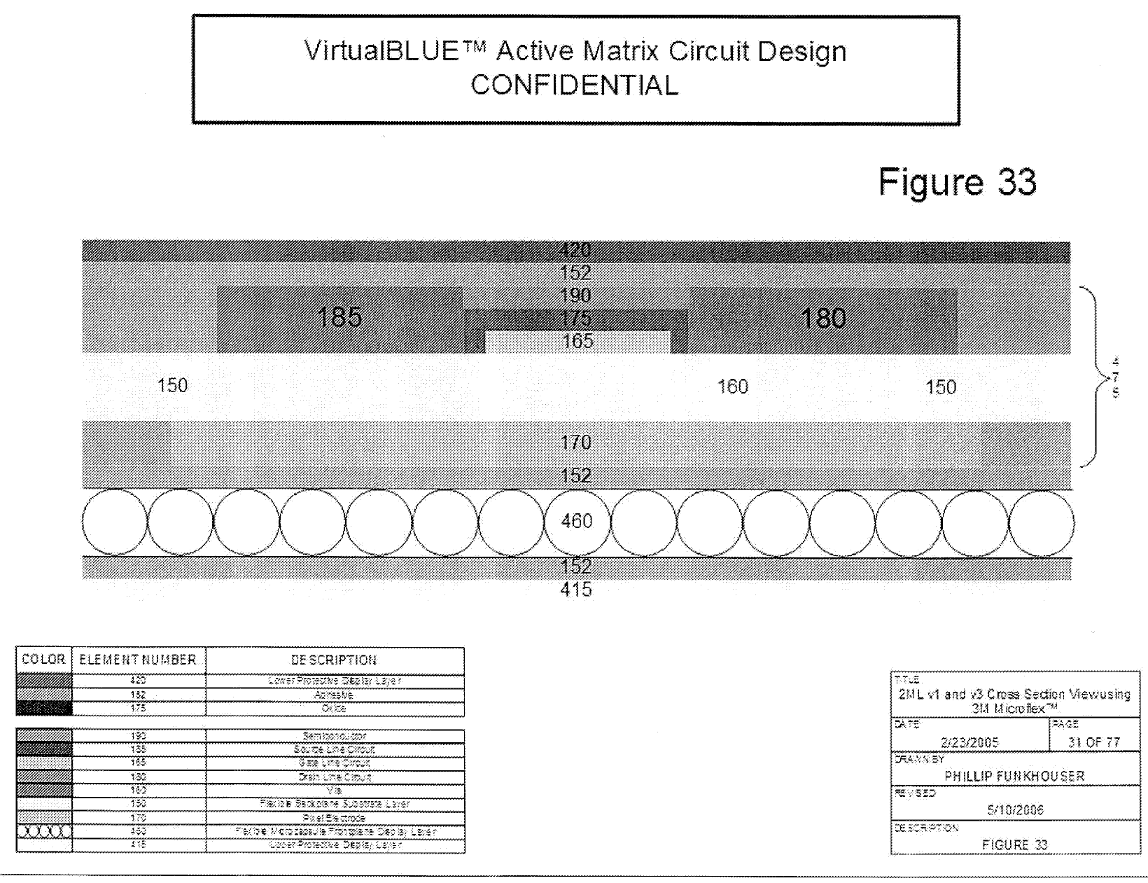

FIG. 8 illustrates a first embodiment of a flexible active matrix driver layer 475 in a row-only configuration. FIGS. 9-14 illustrate a top view of a first circuit design 155 associated with the flexible active matrix driver layer 475 of FIG. 8, FIGS. 15-20 illustrate a top view of a second circuit design 155, FIGS. 21-26 illustrate a top view of a third circuit design 155, and FIGS. 27-32 illustrate a top view of a fourth circuit design 155. As shown in FIGS. 8-32, the circuit assembly 155 is placed on a flexible substrate 150. In this embodiment, pixel electrode 170 is located on the same surface of flexible substrate 150 with respect to the circuit assembly 155. The circuit assembly 155 includes gate line 165, dielectric 175, drain 180, source line 185, and semiconductor 190.

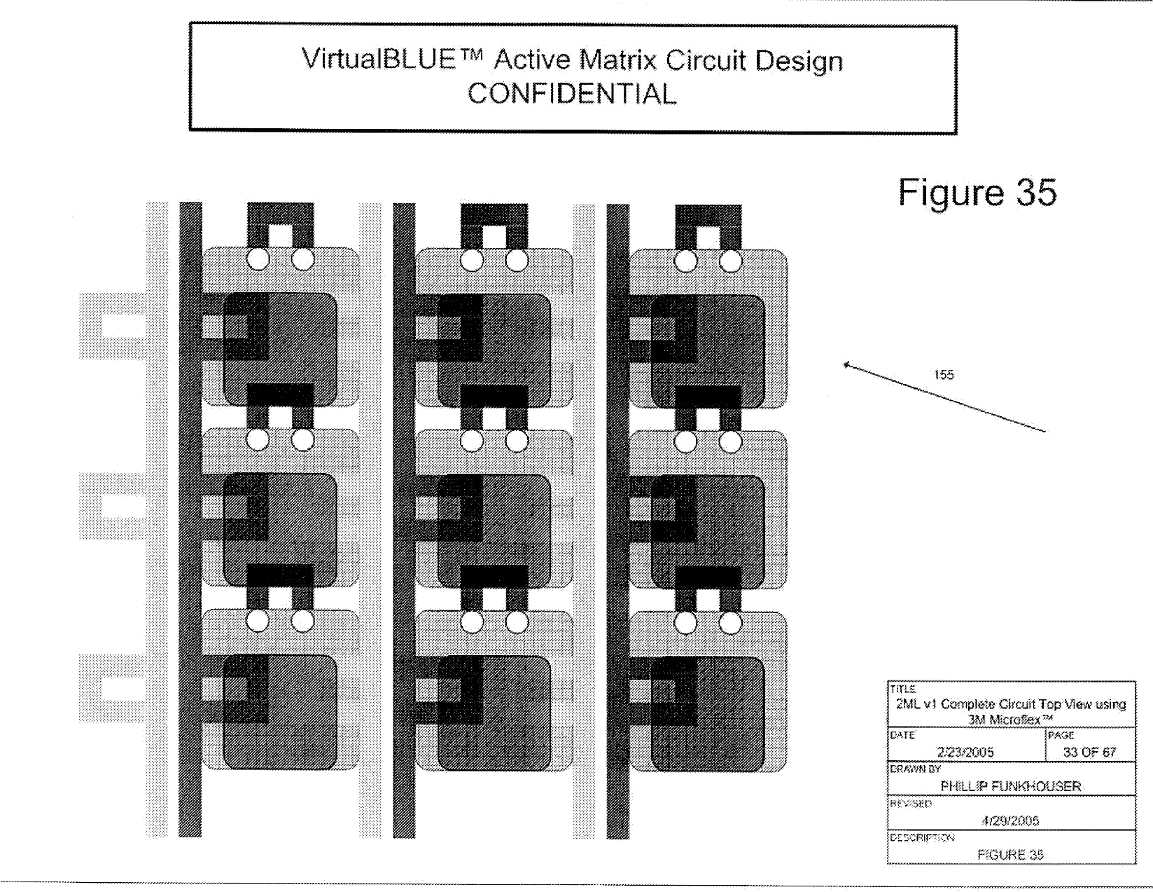

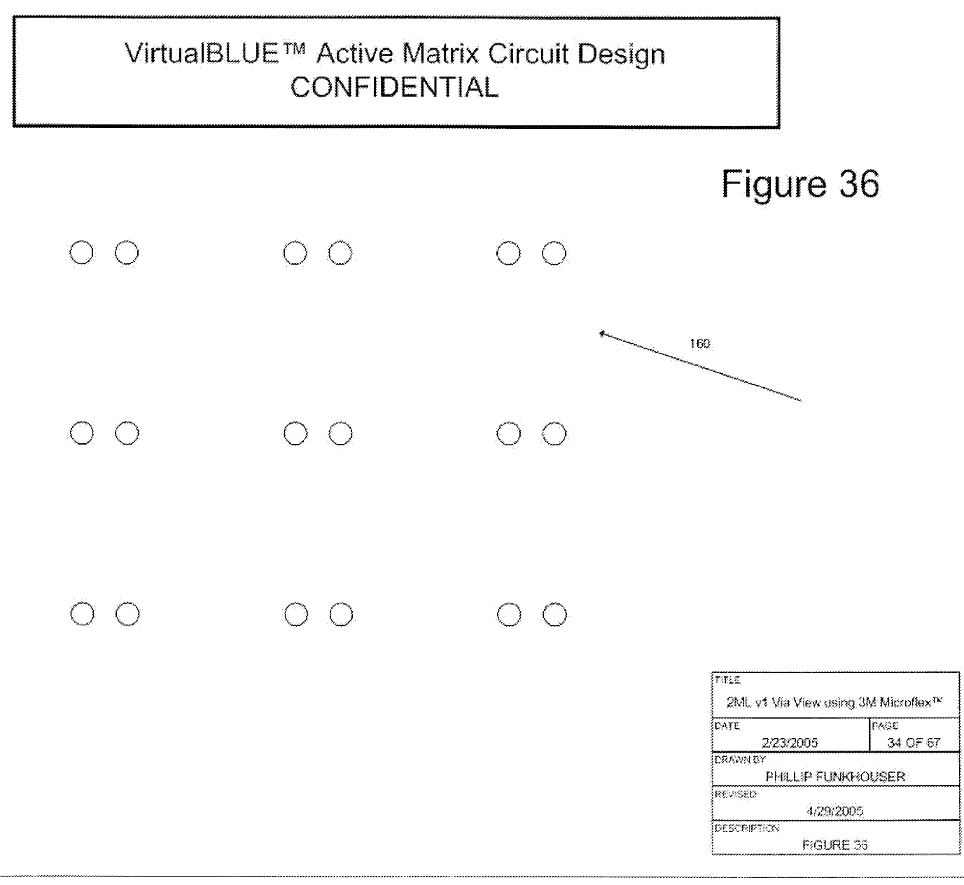

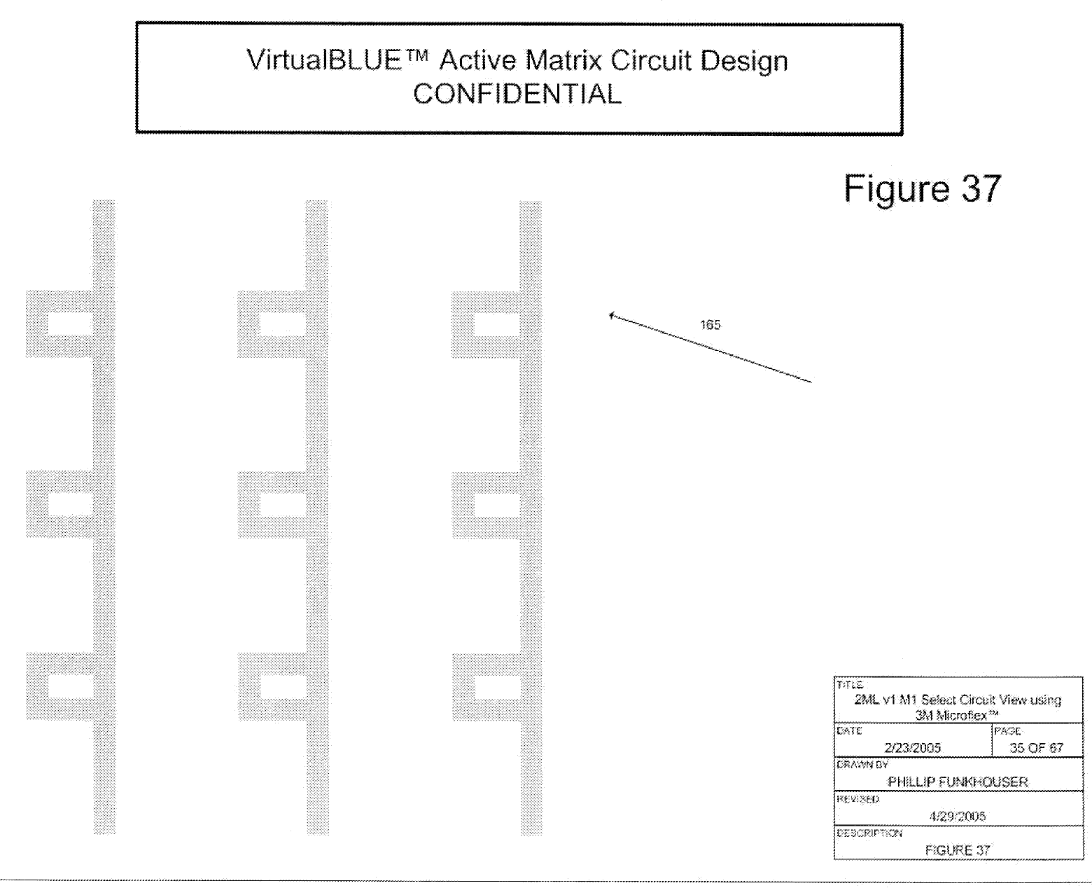

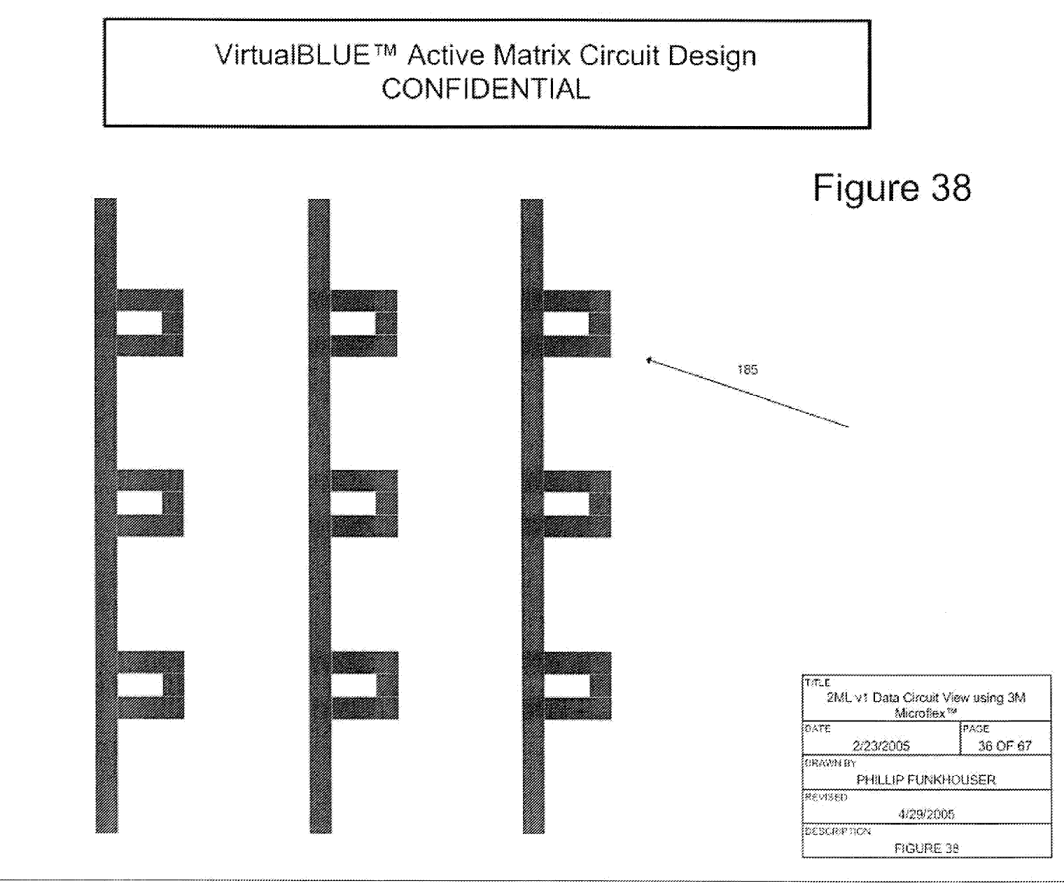

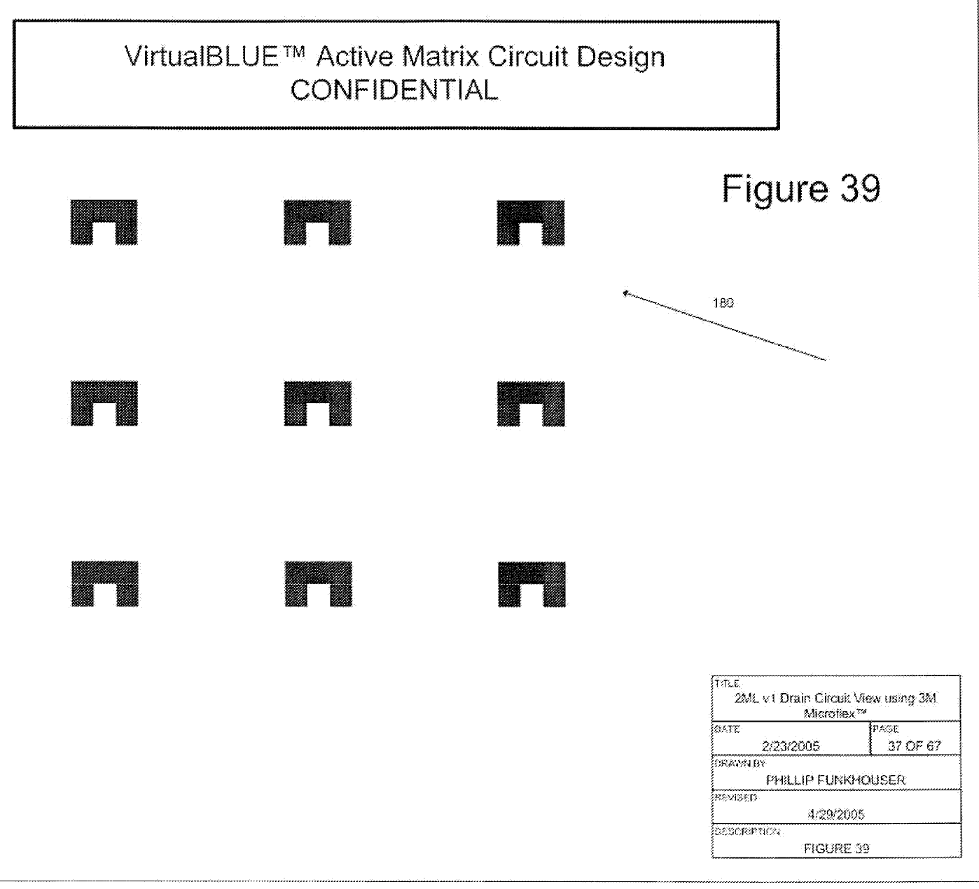

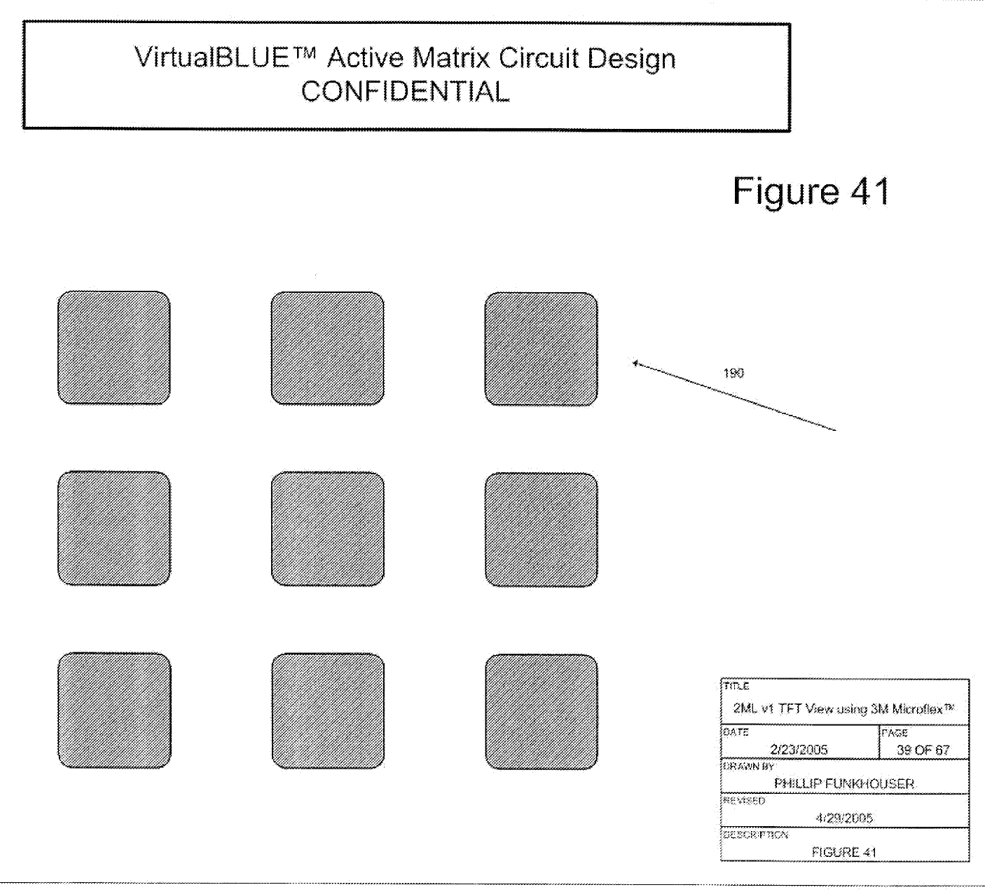

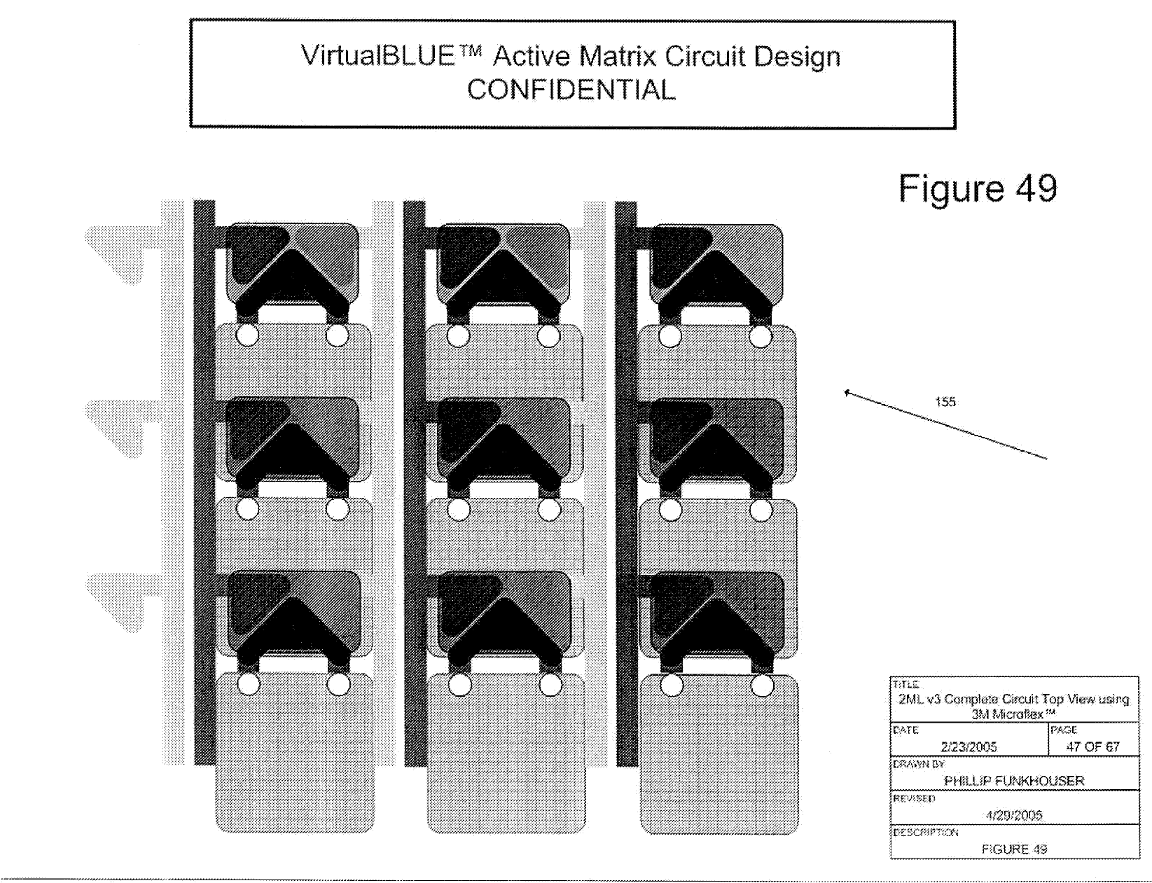

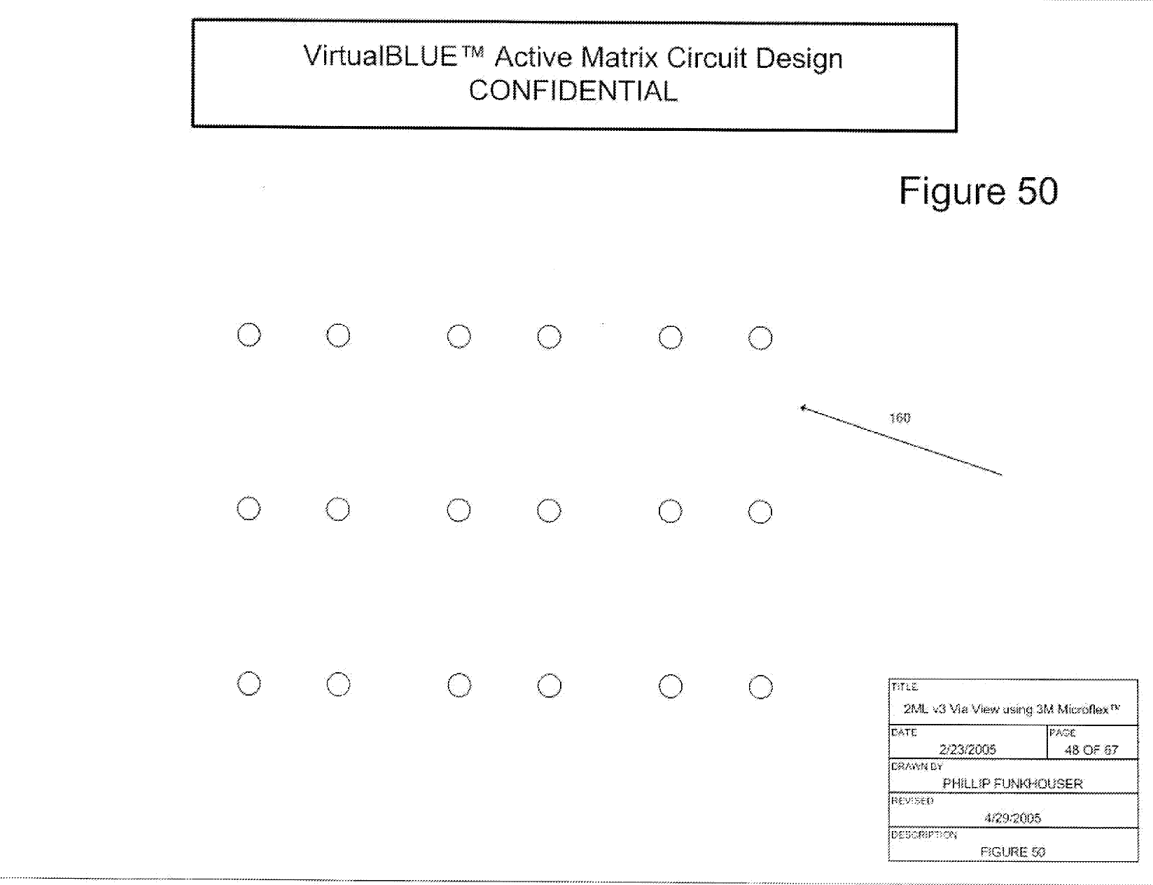

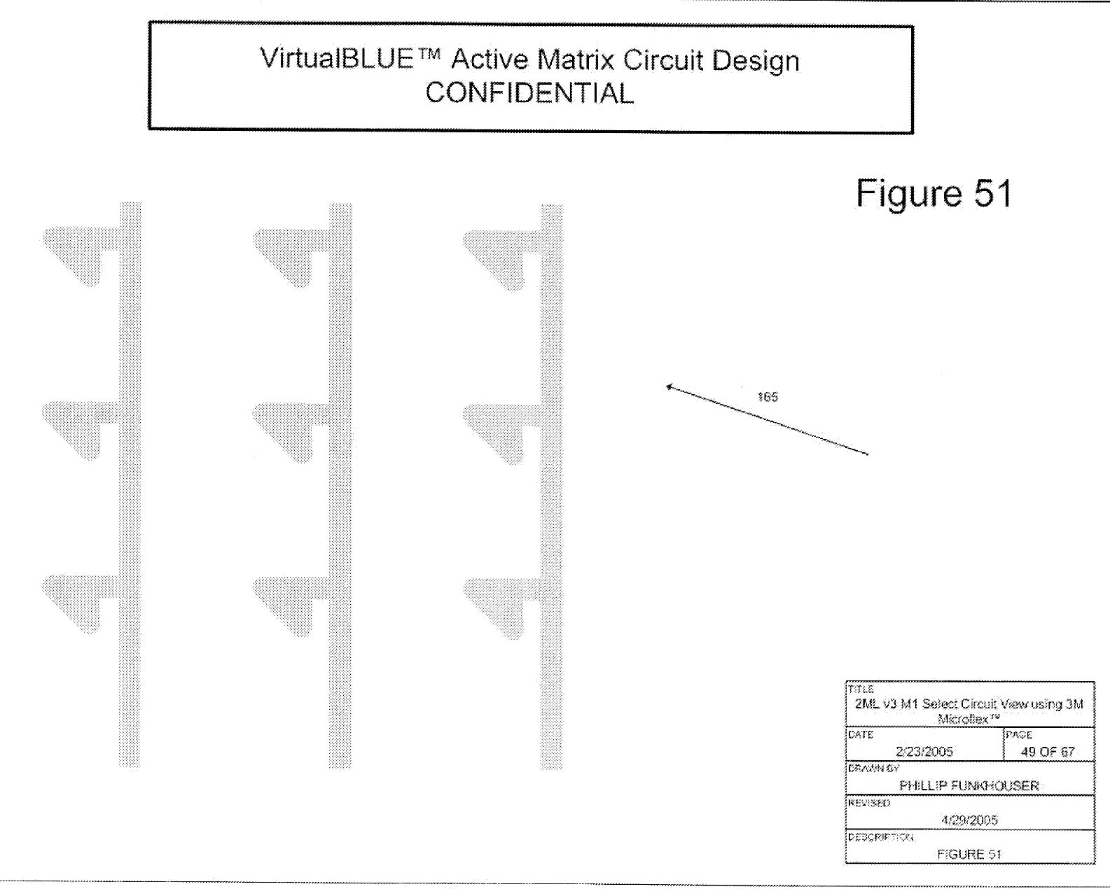

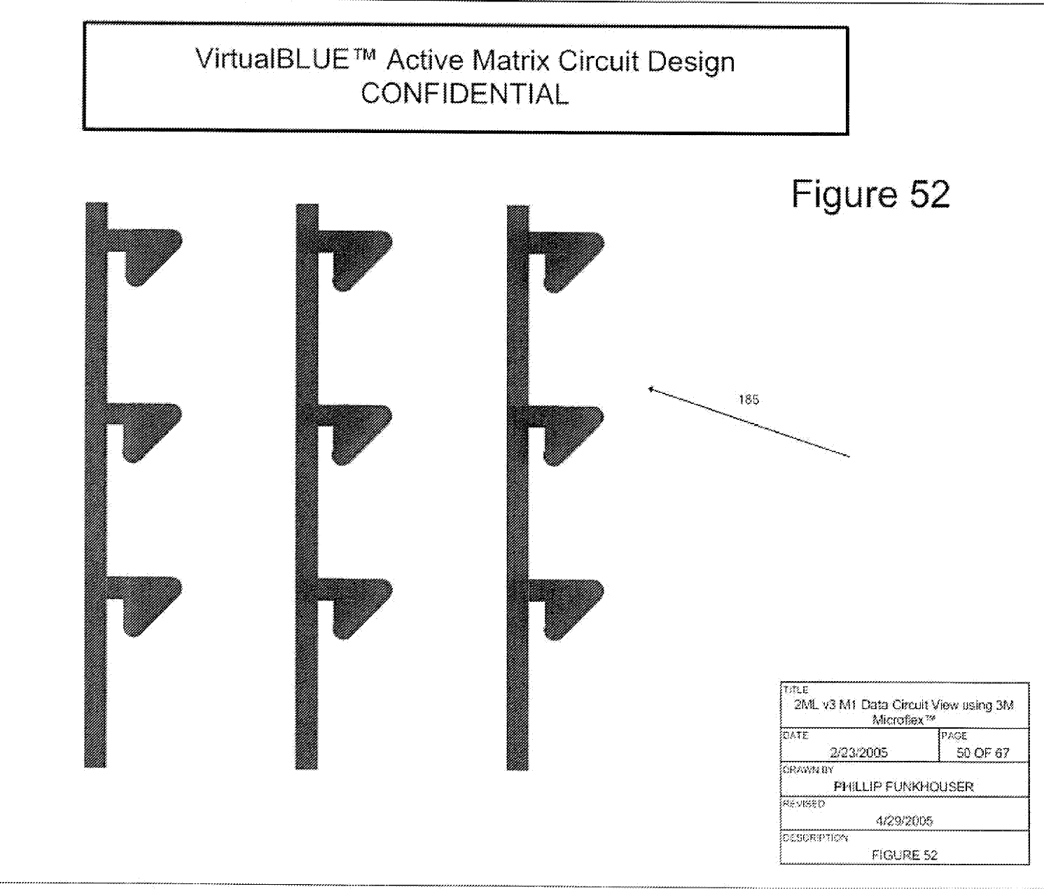

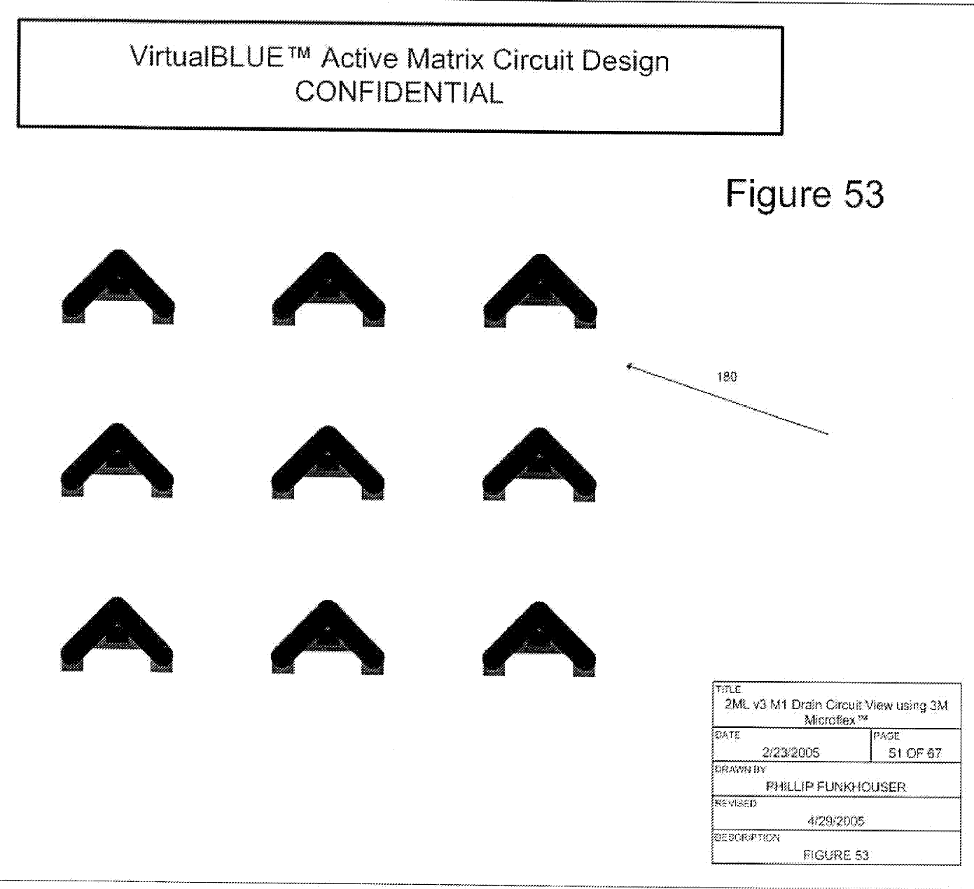

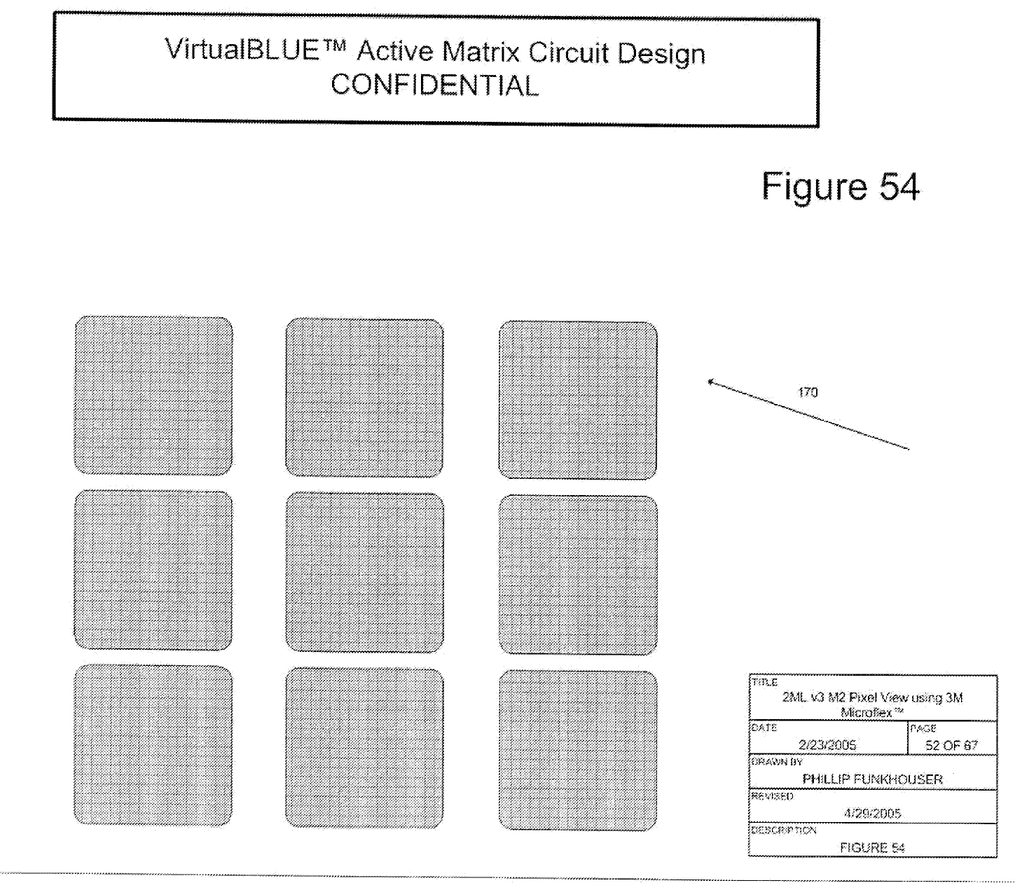

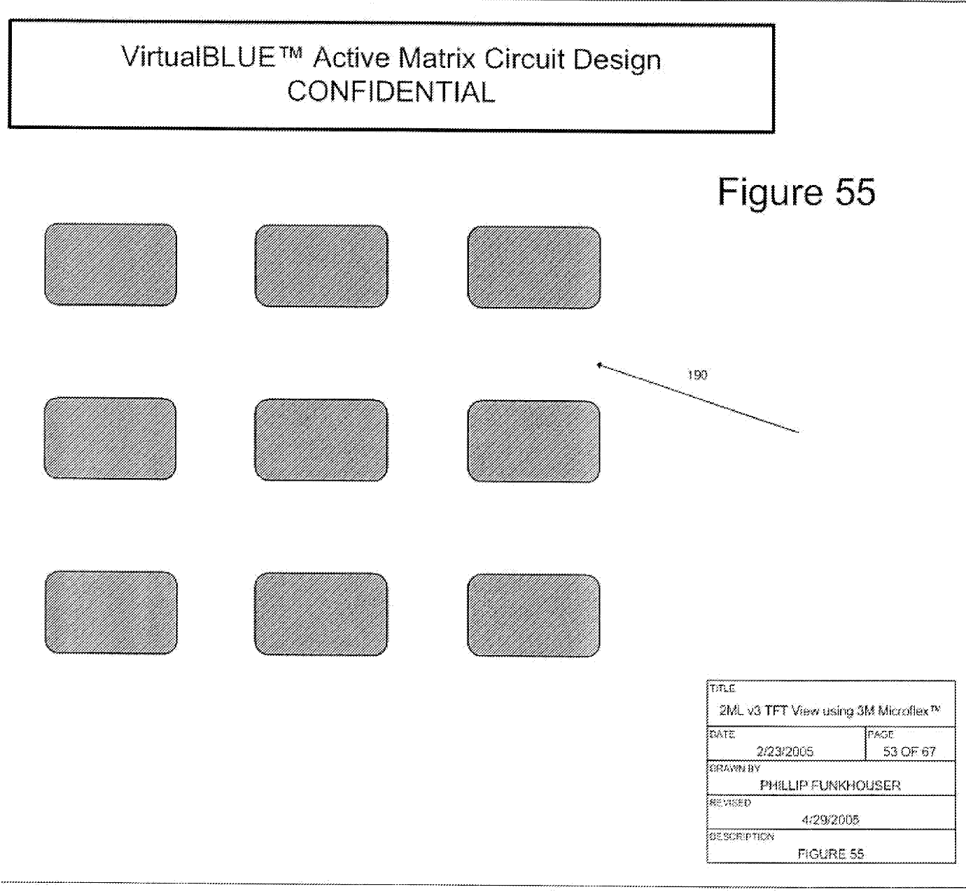

FIG. 33 illustrates a second embodiment of a flexible active matrix driver layer 475 in a row-only configuration. FIGS. 35-41 illustrate a top view of a first circuit design 155 associated with the flexible active matrix driver layer 475 of FIG. 33 and FIGS. 49-55 illustrate a top view of a second circuit design 155 associated with the flexible active matrix driver layer 475 of FIG. 33.

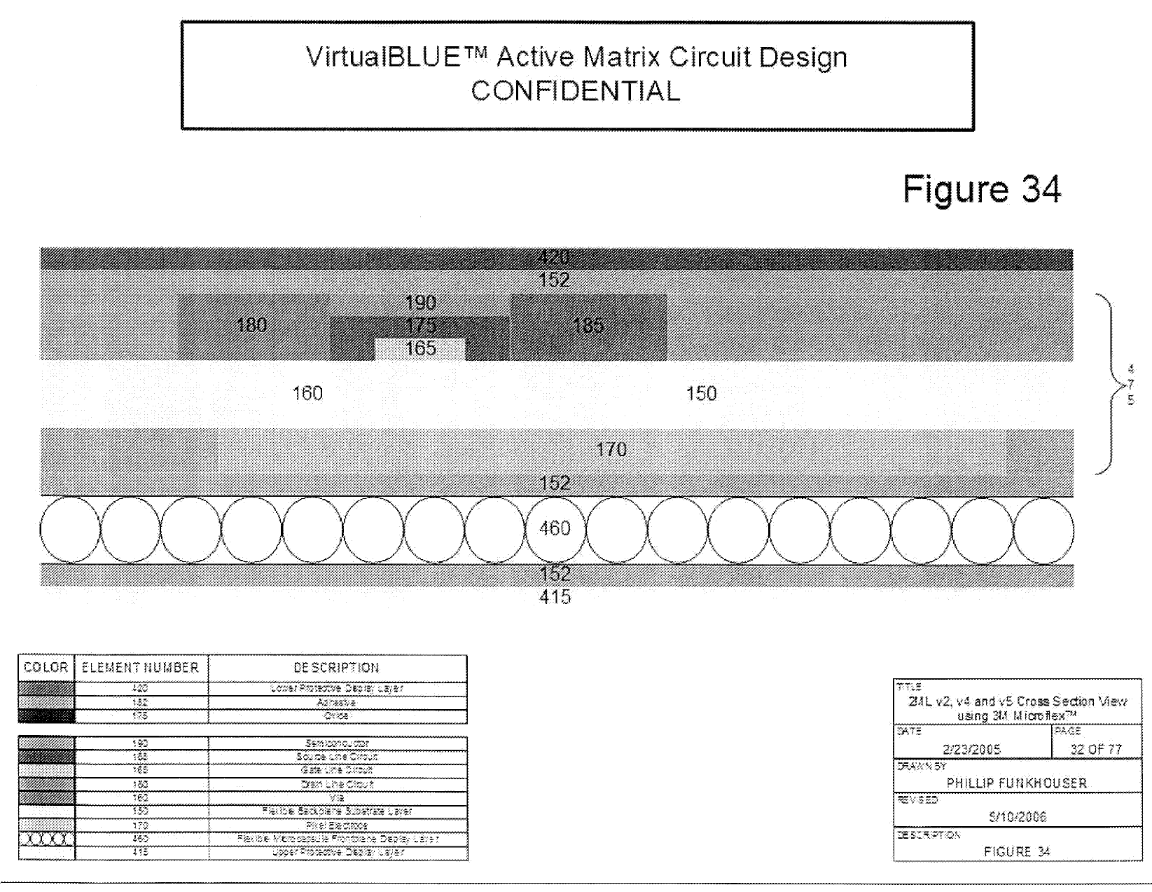

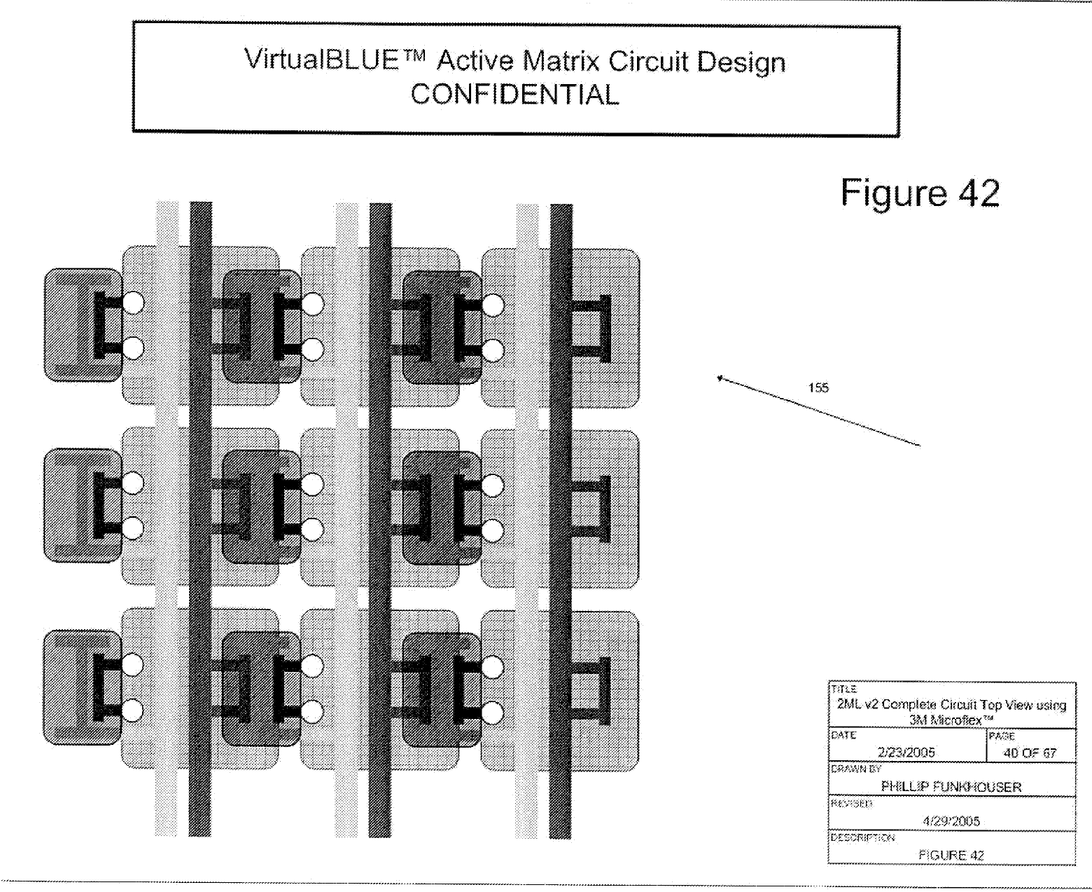

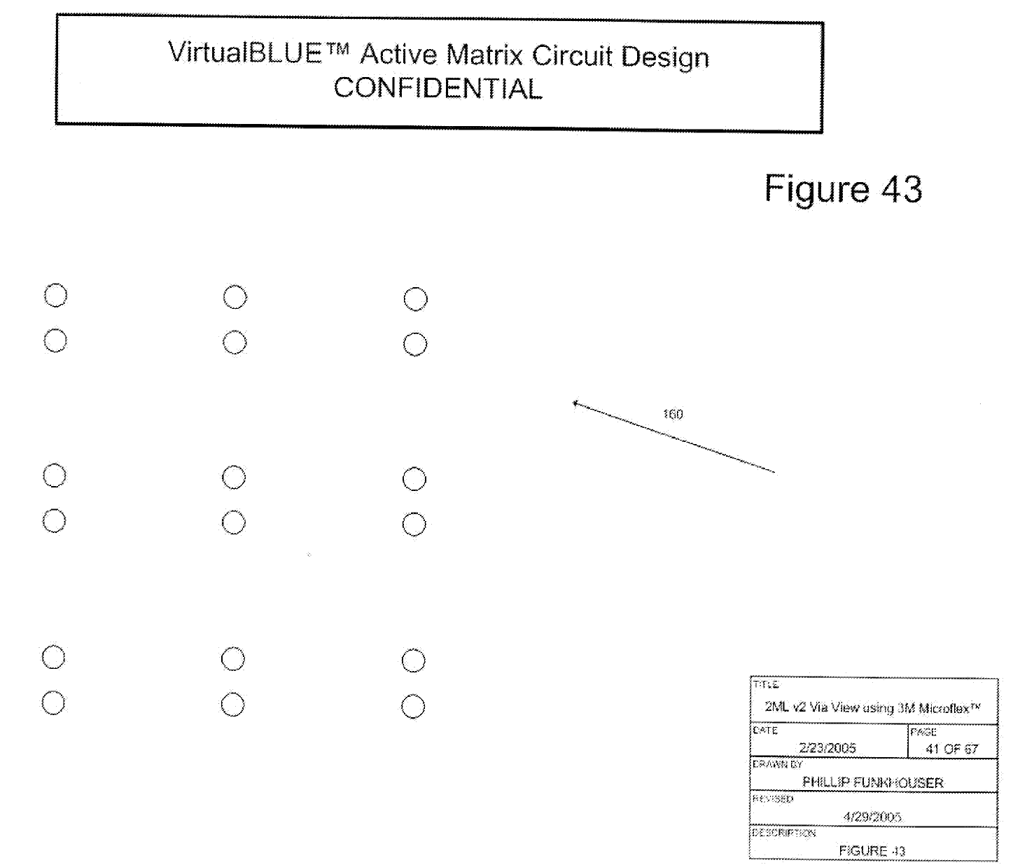

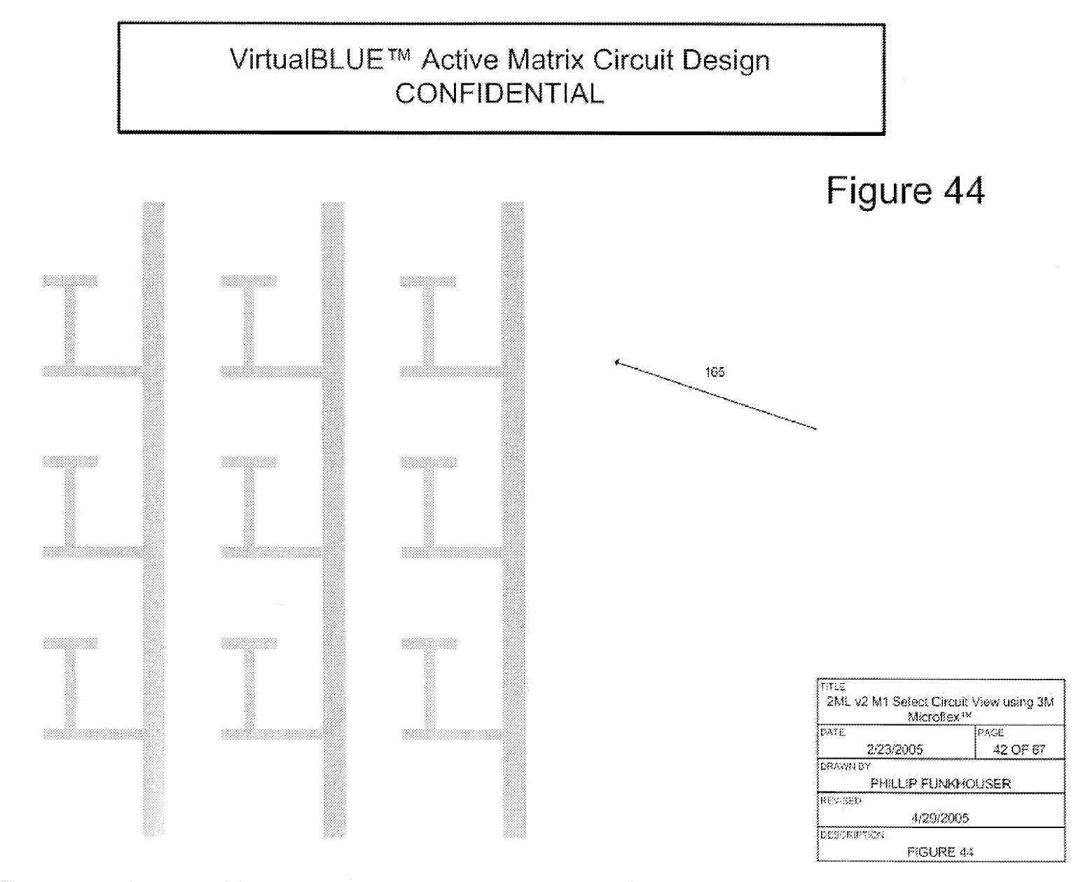

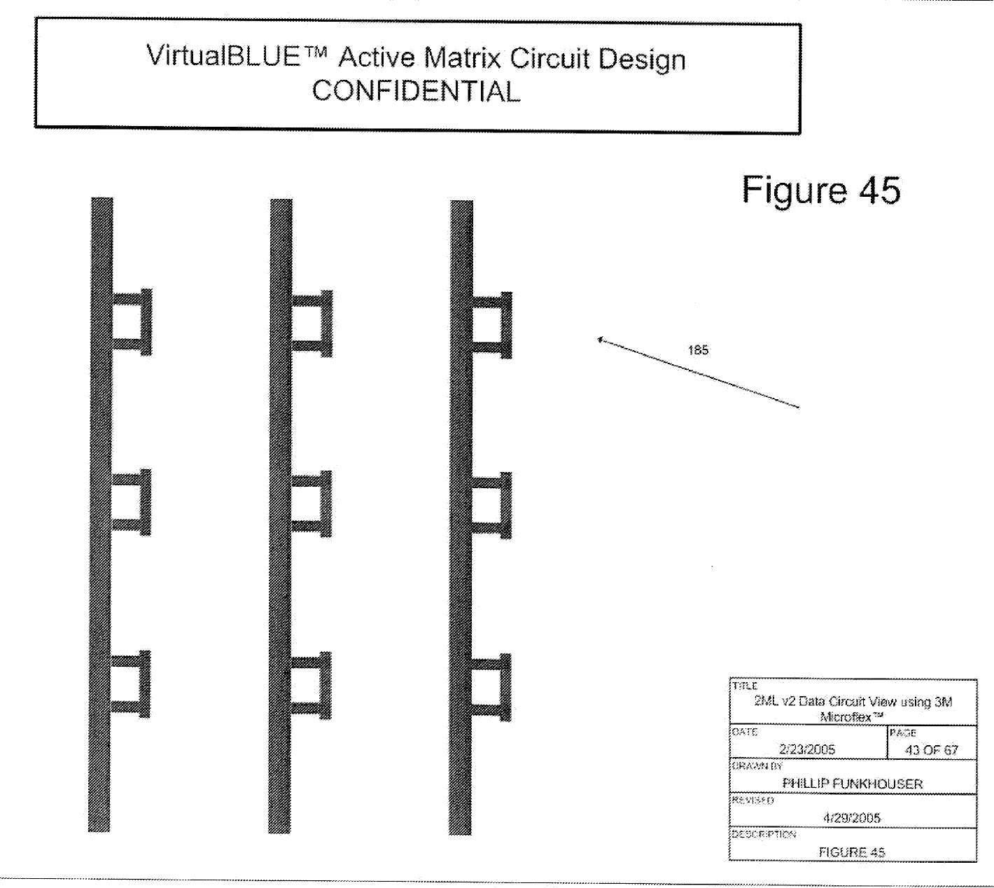

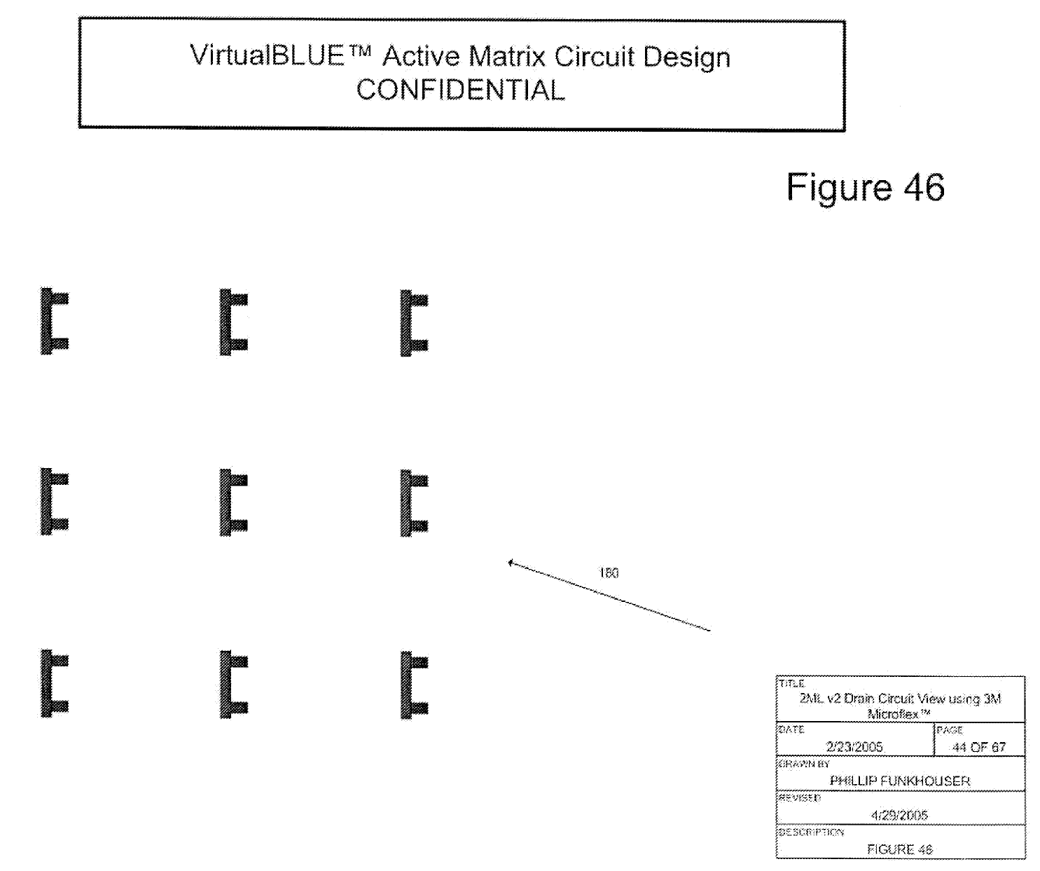

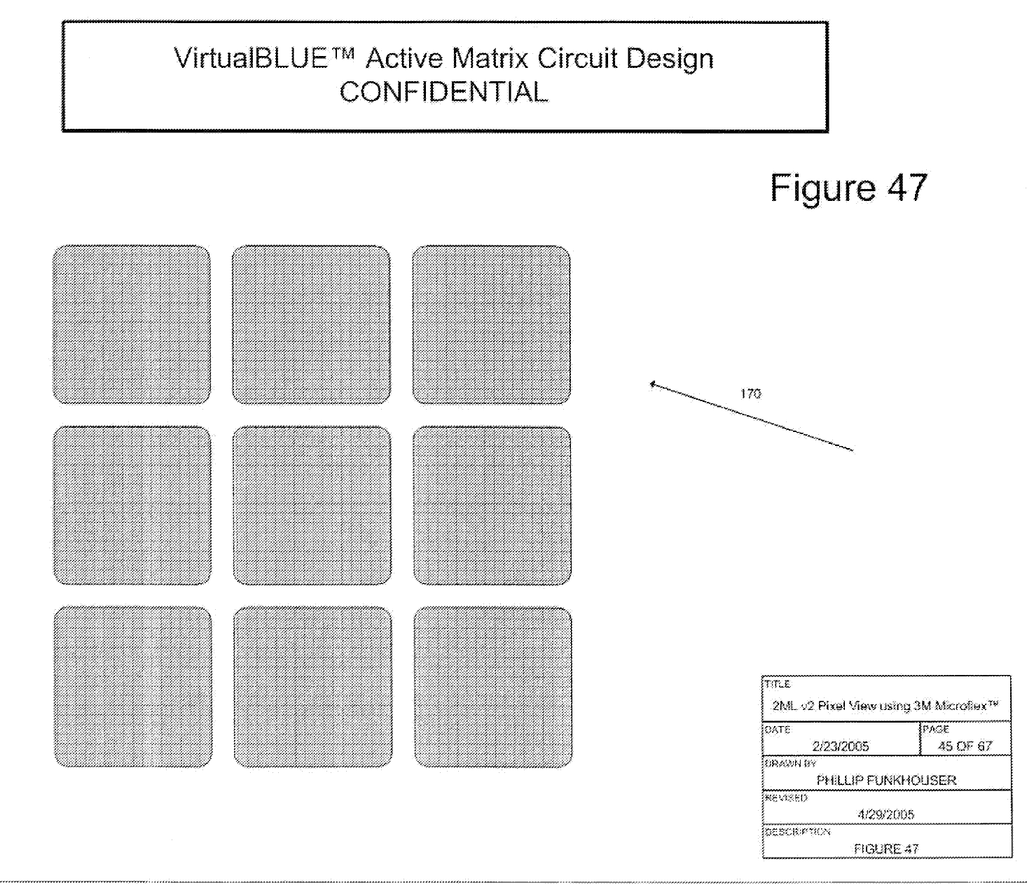

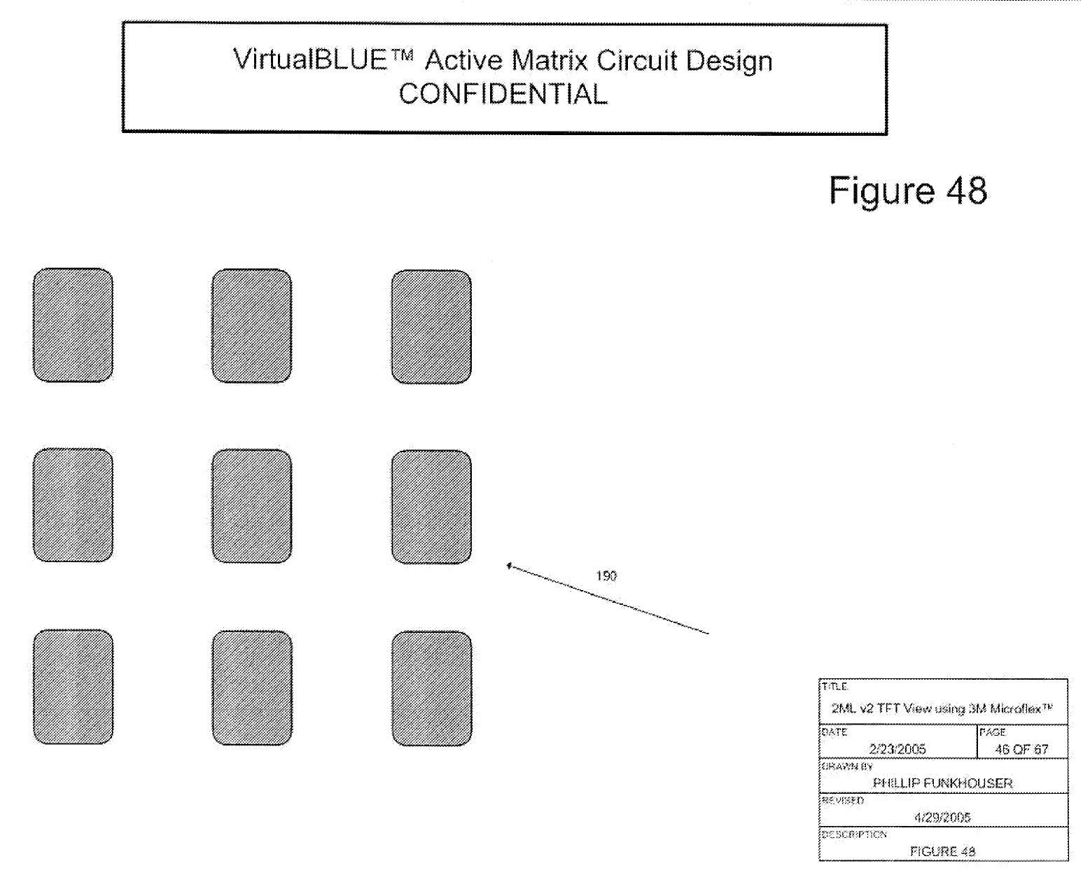

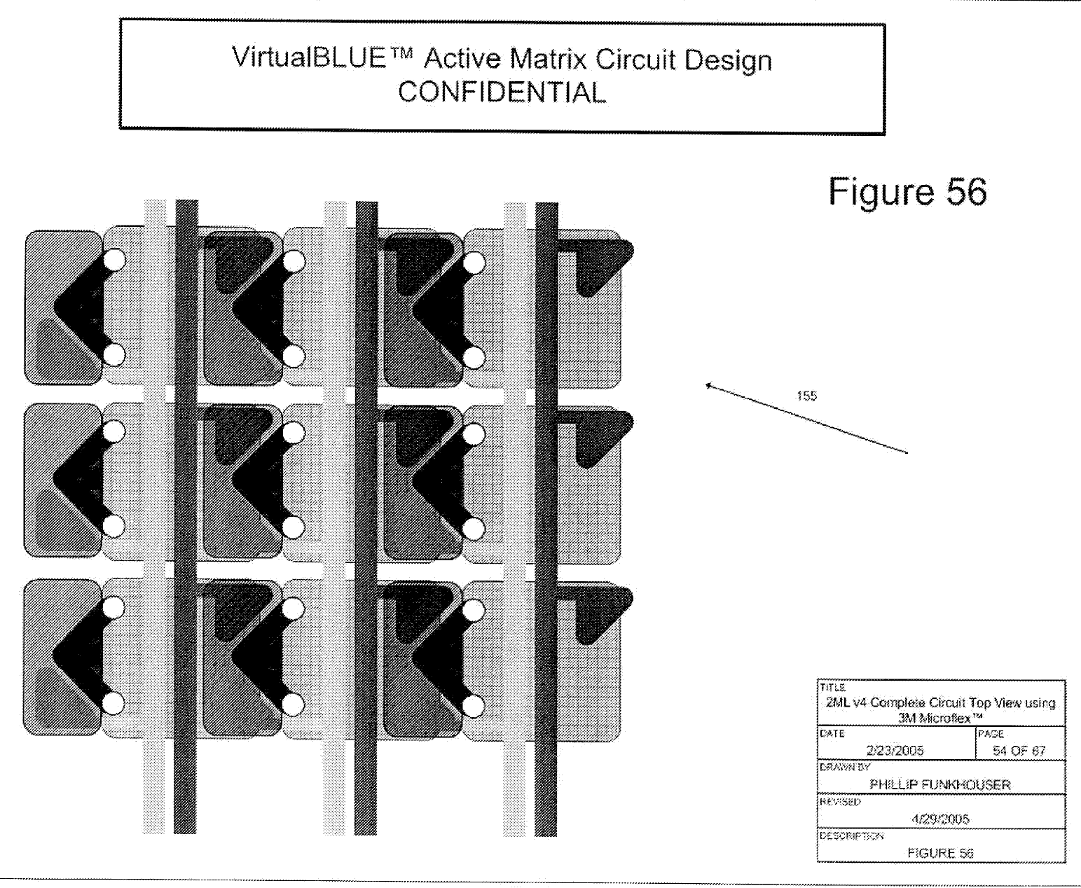

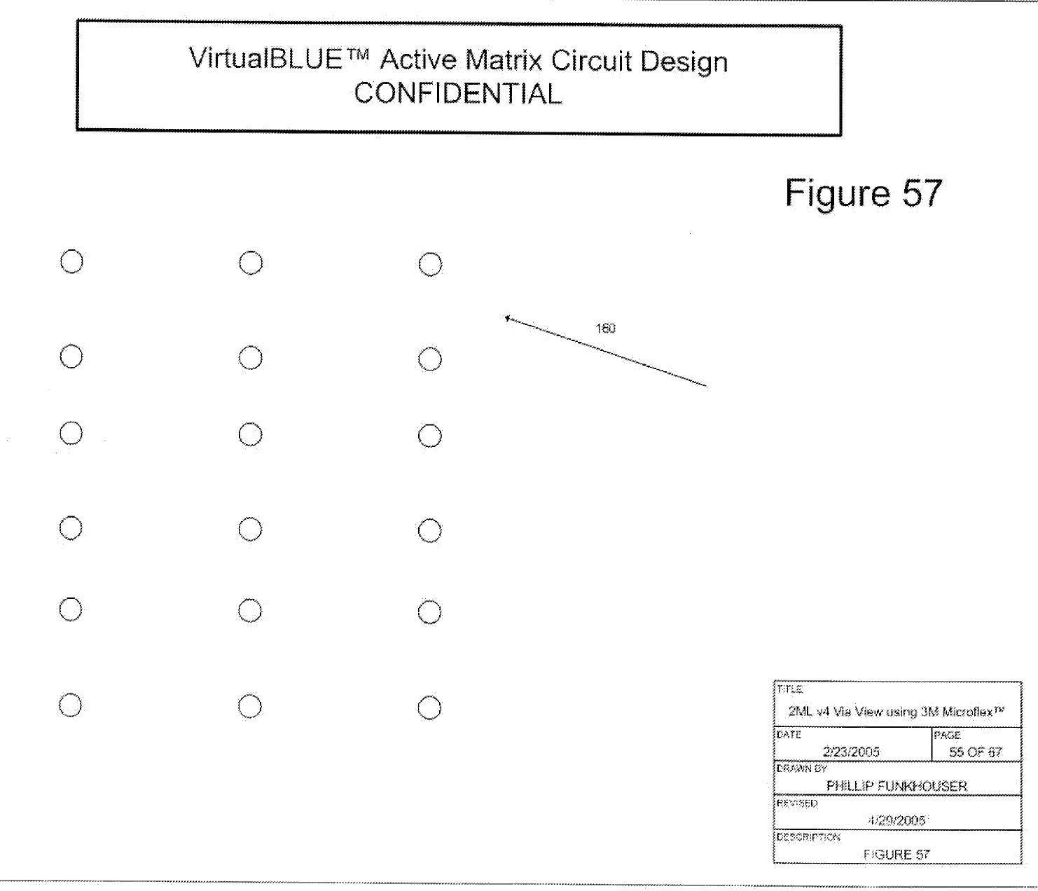

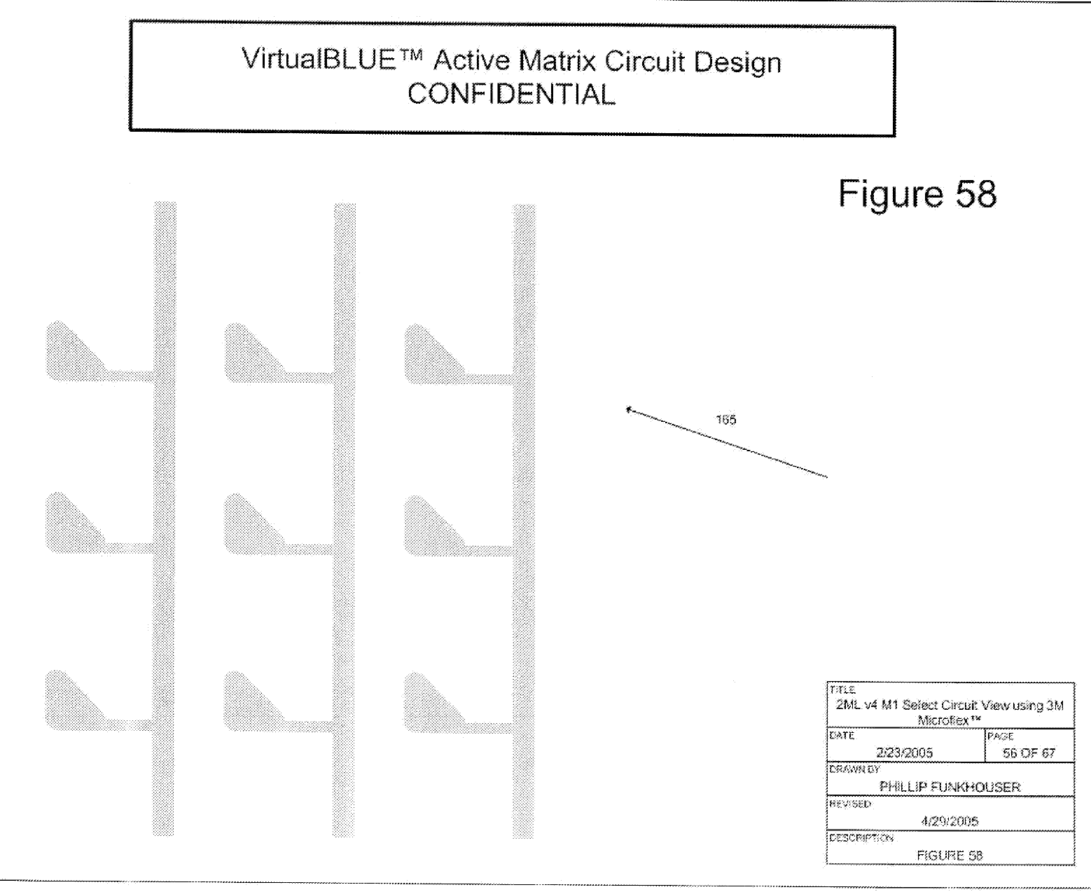

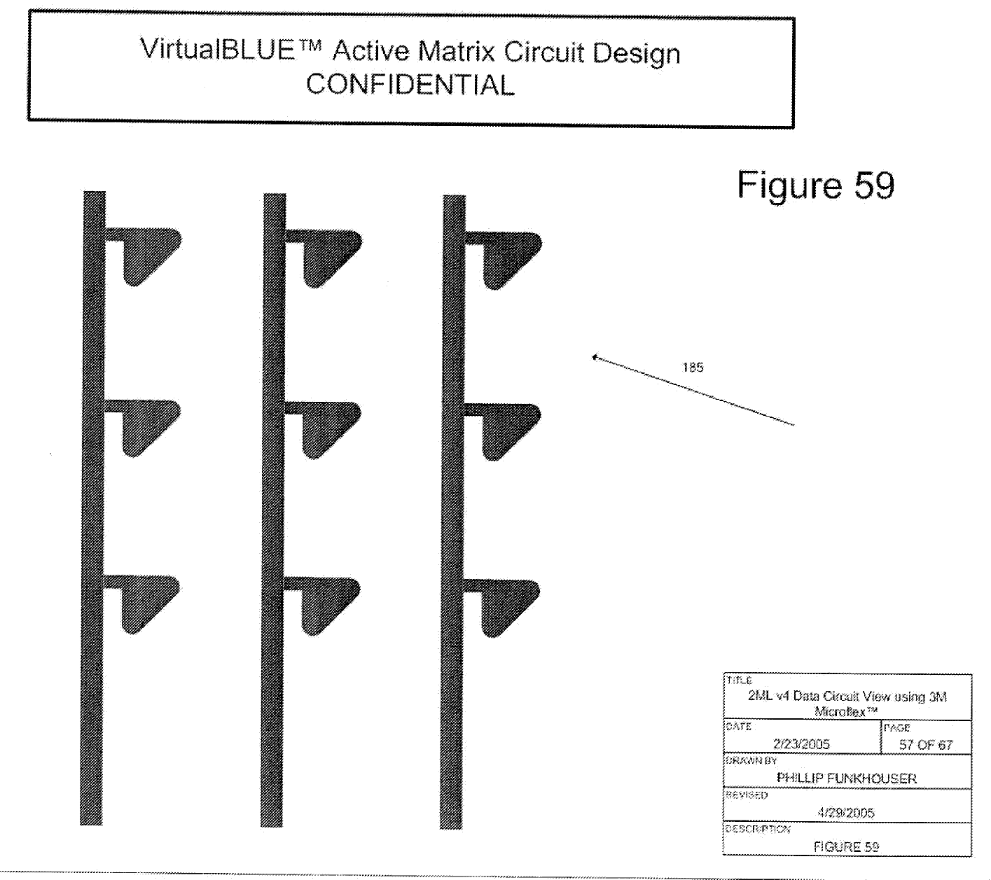

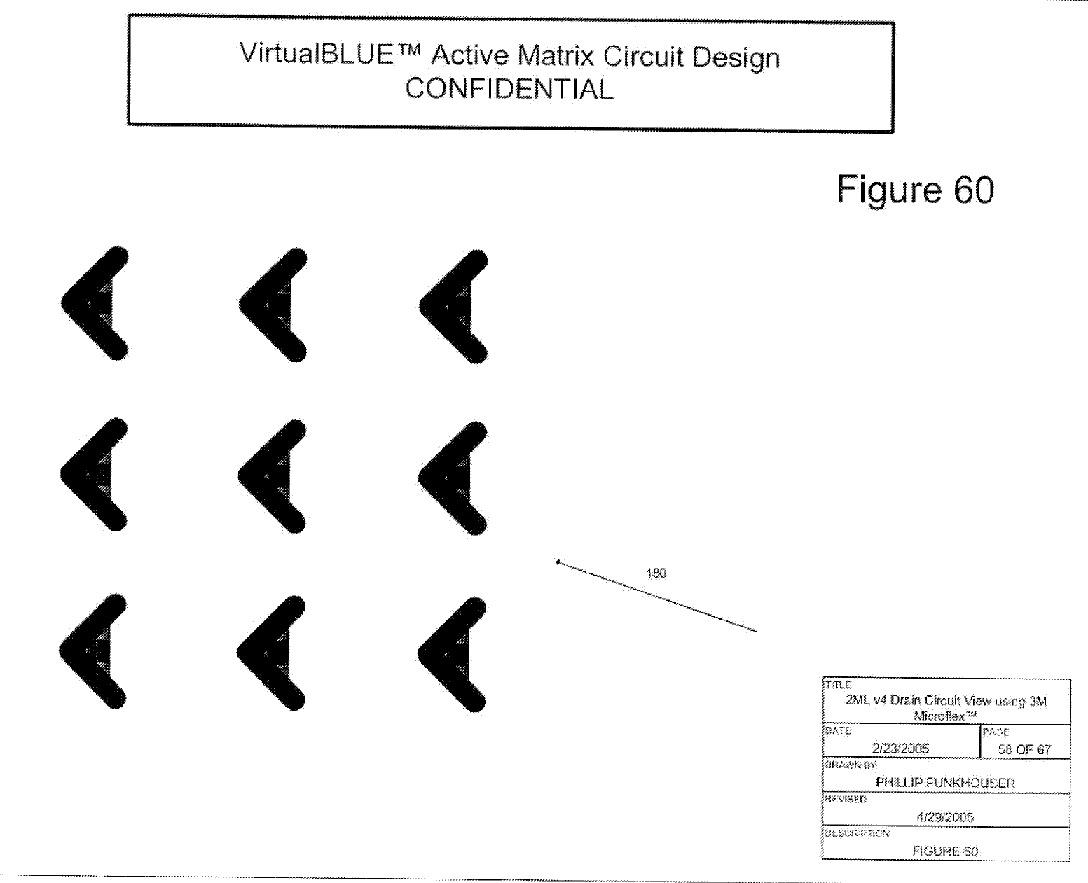

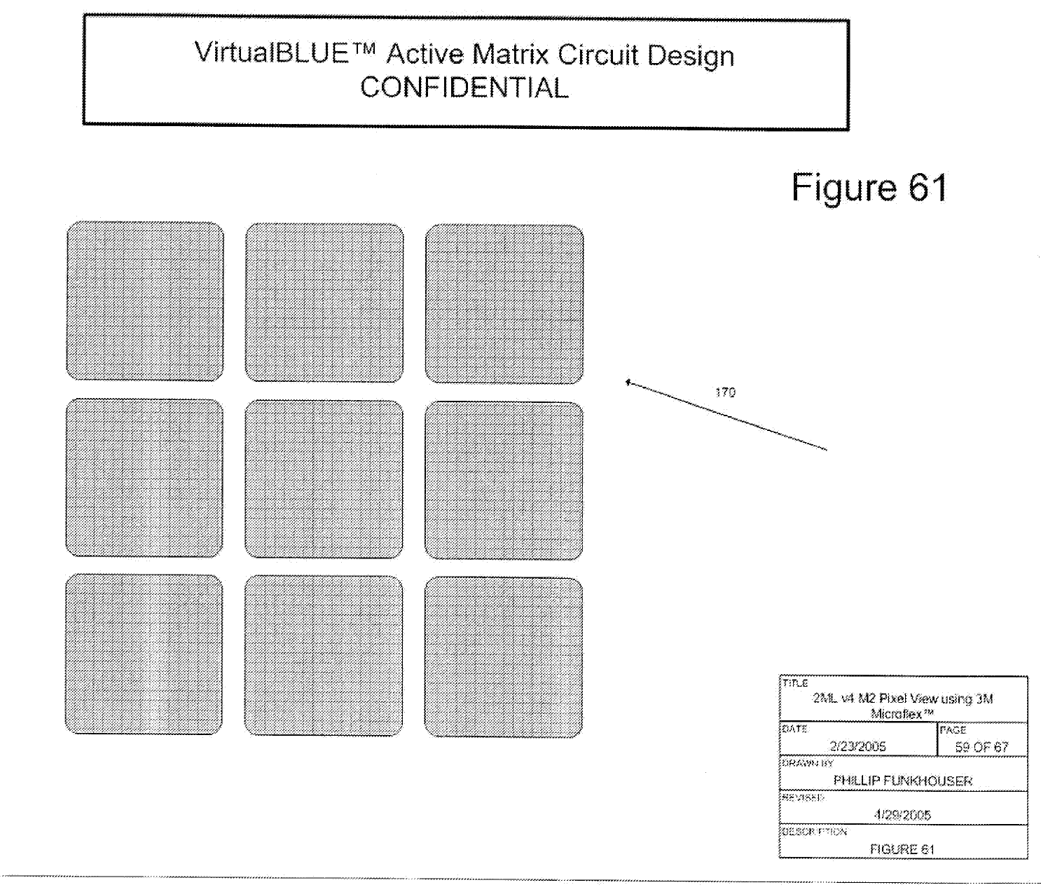

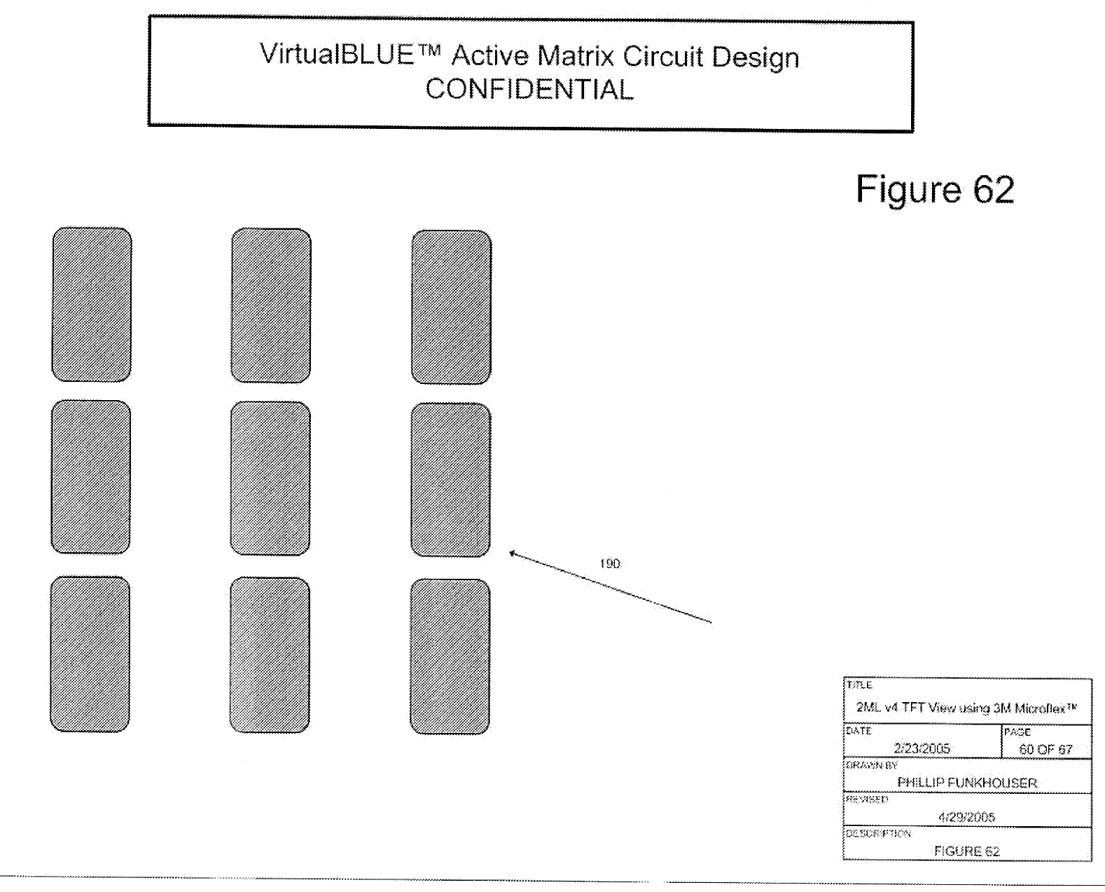

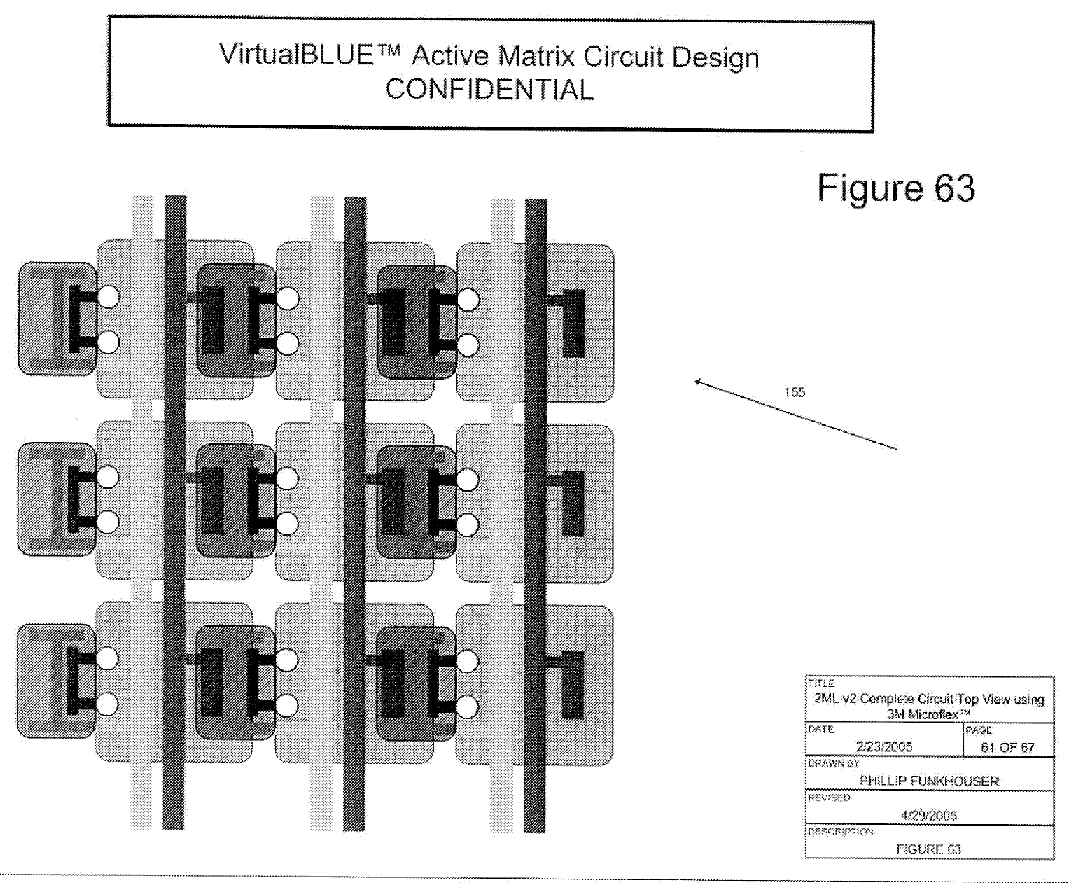

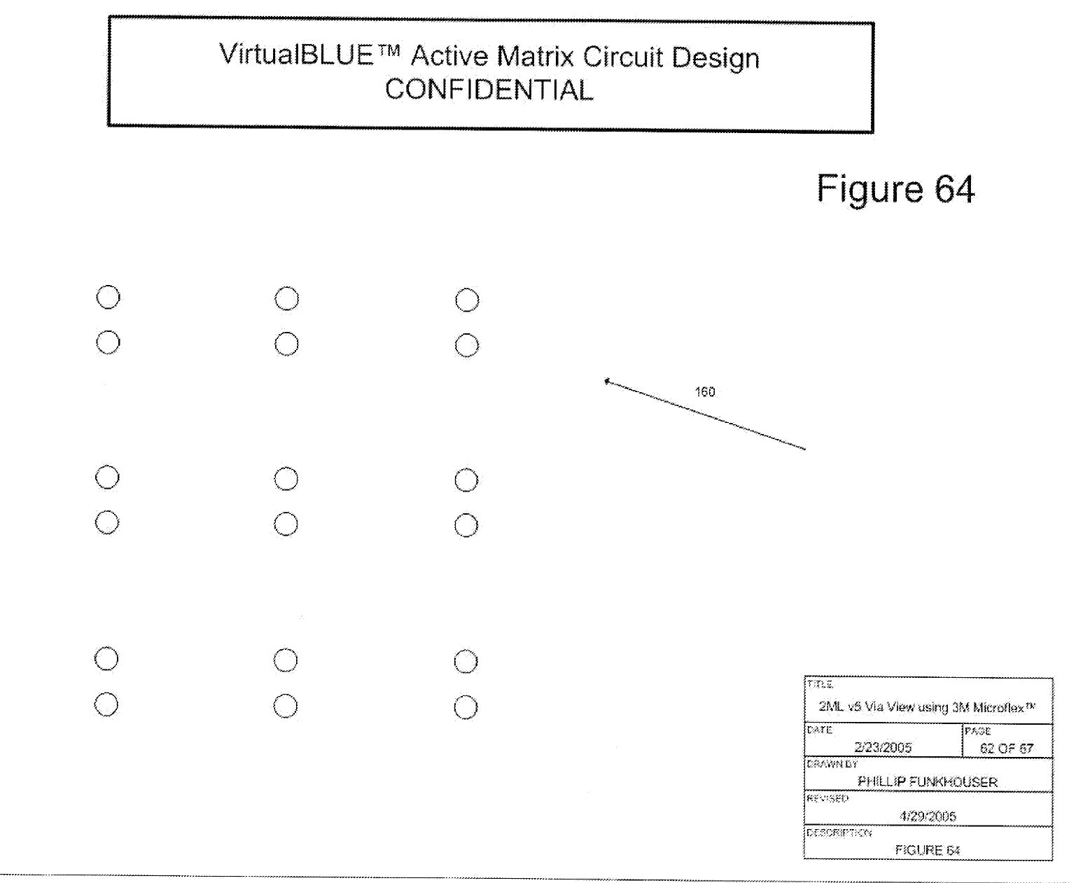

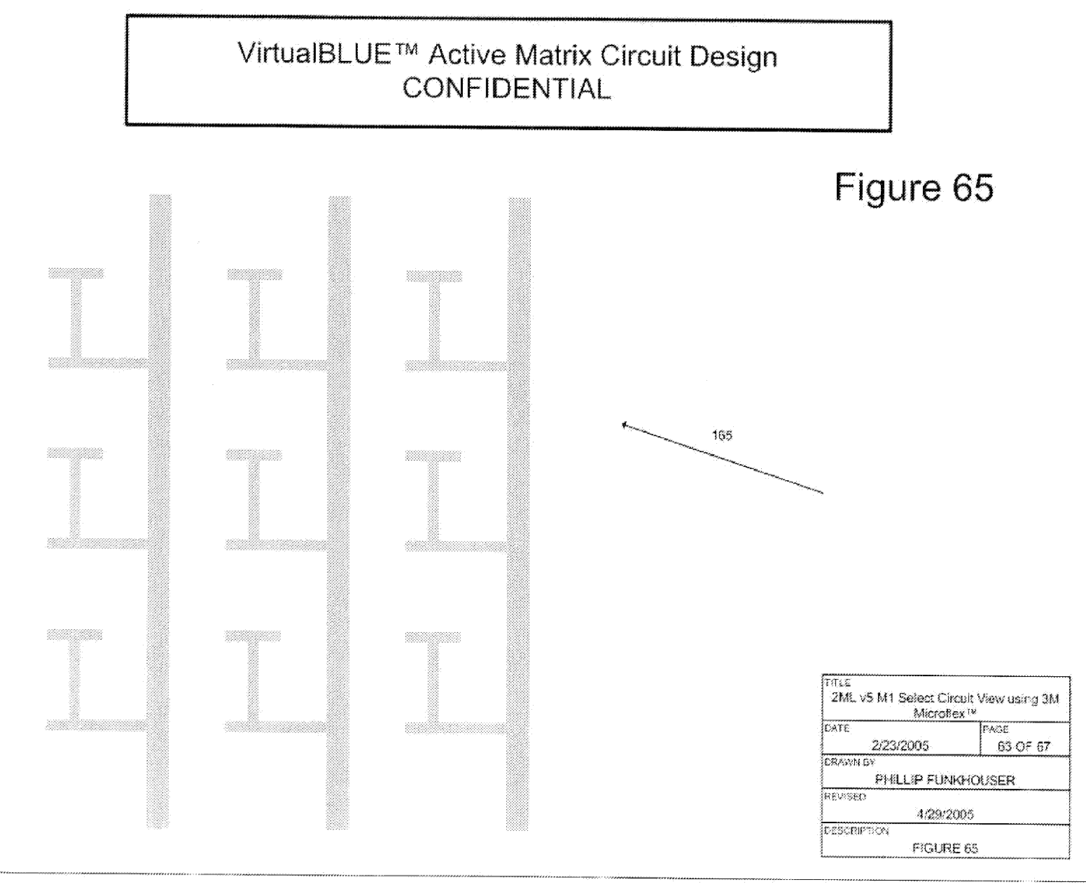

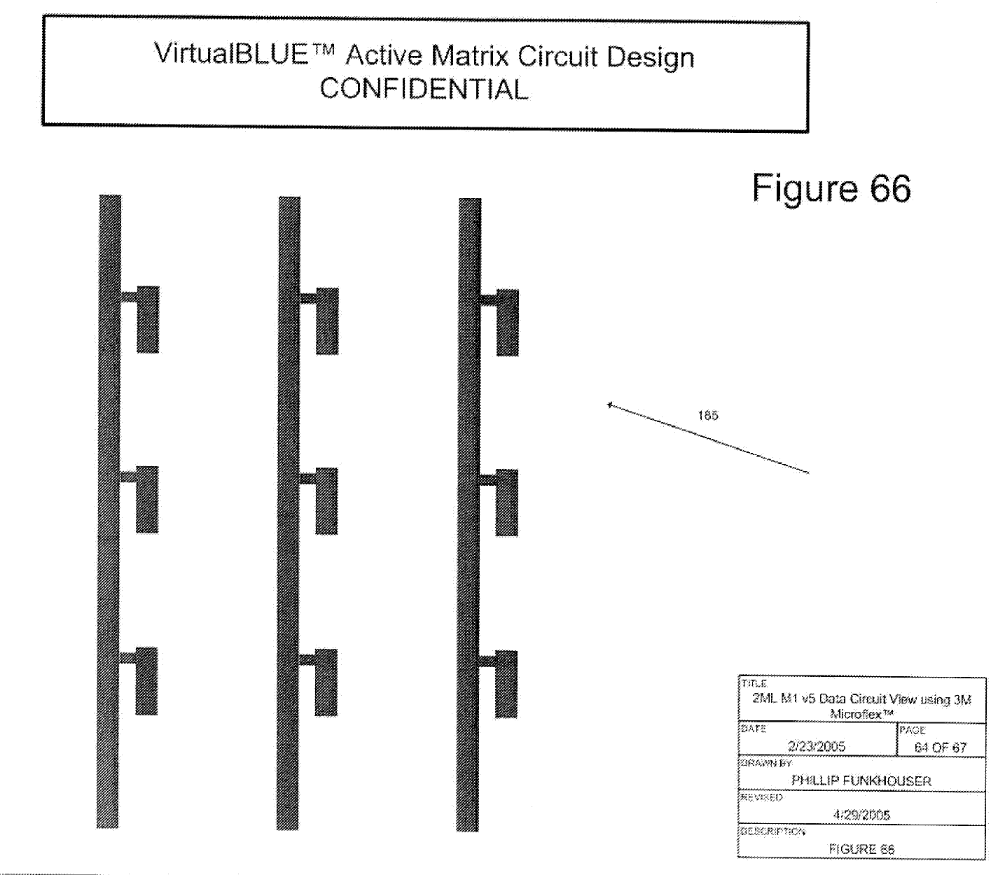

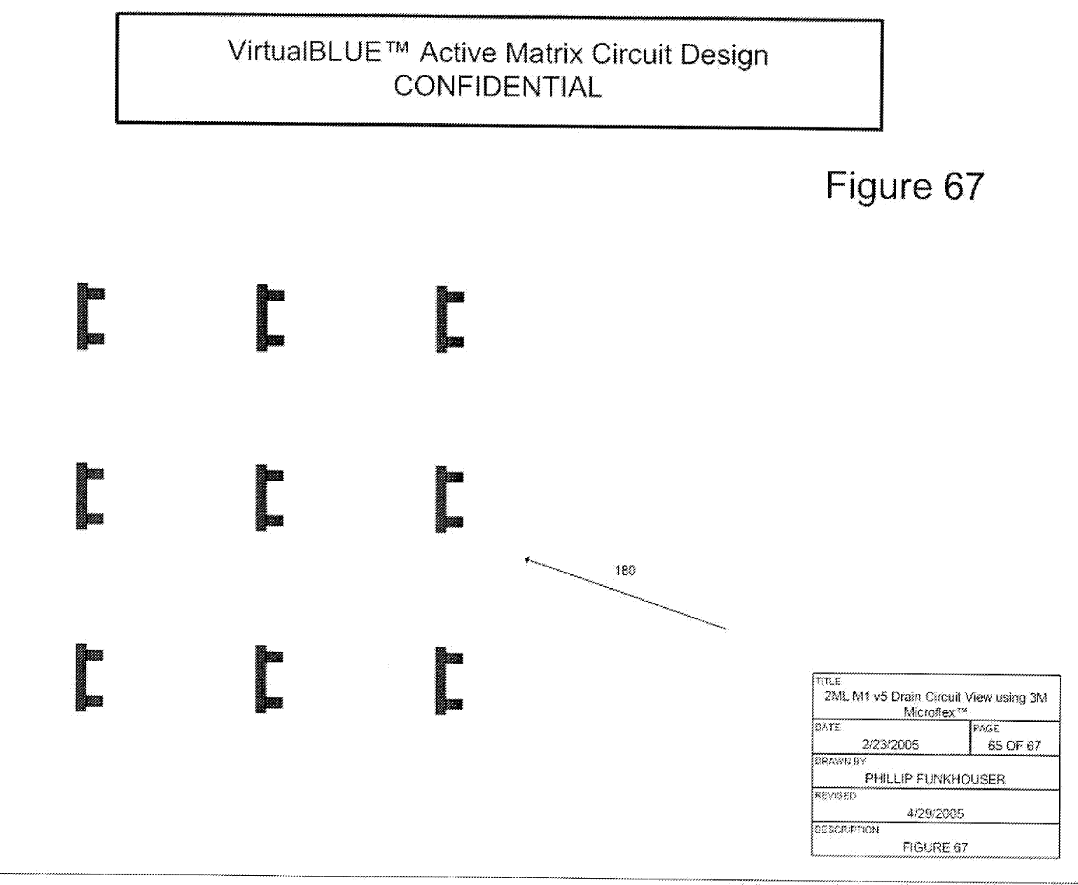

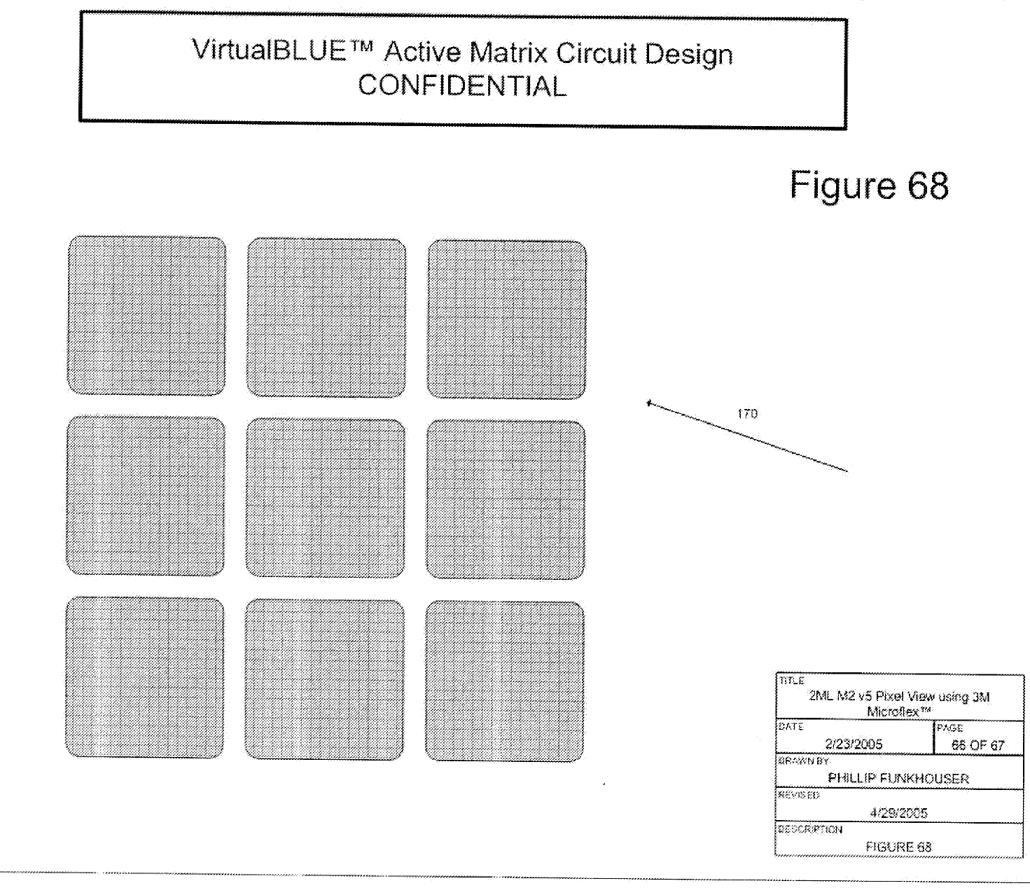

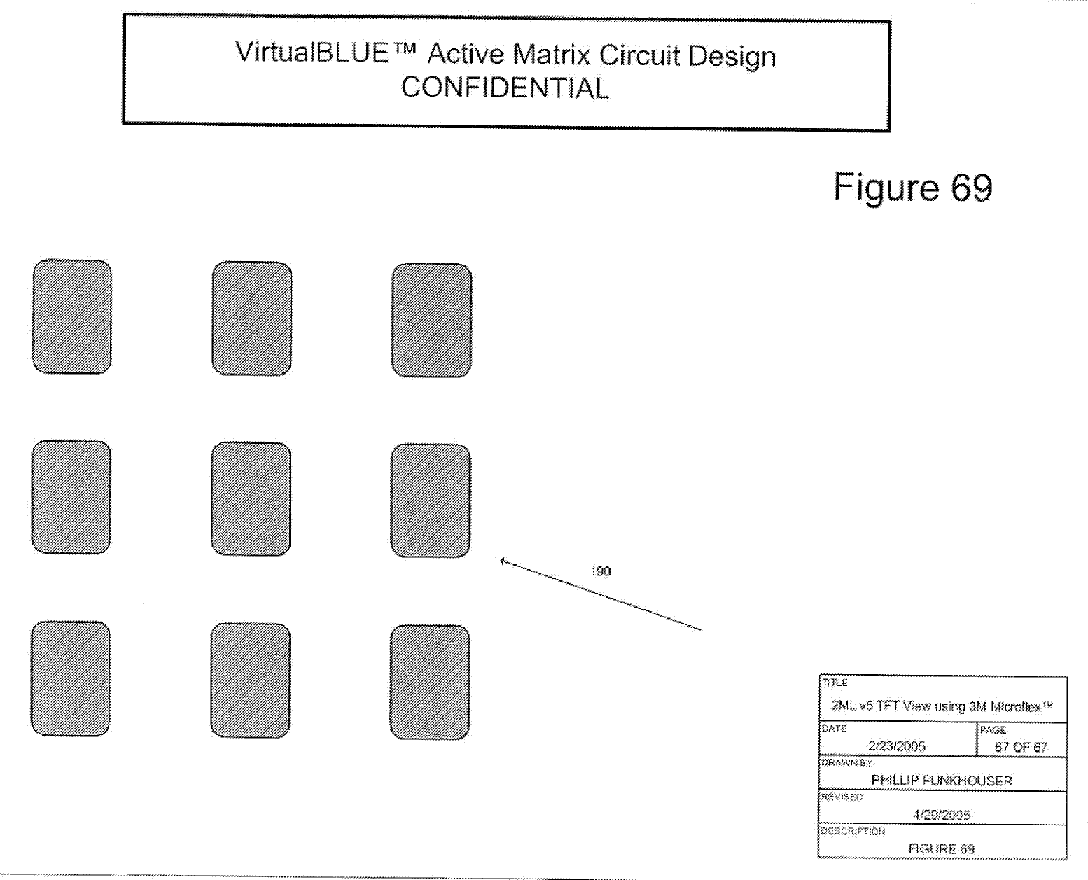

FIG. 34 illustrates a third embodiment of a flexible active matrix driver layer 475 in a row-only configuration. FIGS. 42-48 illustrate a top view of a first circuit design 155 associated with the flexible active matrix driver layer 475 of FIG. 34, FIGS. 56-62 illustrate a top view of a second circuit design 155, and FIGS. 63-69 illustrate a top view of a third circuit design 155 associated with the flexible active matrix driver layer 475 of FIG. 34.

Referring now to FIGS. 33-69 generally, the circuit assembly 155 is placed on the flexible substrate 150. In this embodiment, however, pixel electrode 170 is located on the opposed surface of flexible substrate 150 with respect to the circuit assembly 155. The circuit assembly 155 includes gate line 165, dielectric 175, drain 180, source line 185, and semiconductor 190. The flexible substrate 150 is perforated, drilled, milled, or otherwise formed in known manner to create via 160, which allow electrical current to travel from the drain 180 to the pixel electrode 170.

Referring specifically to FIGS. 15, 21, 27, 42, 49, 56 and 63, it will be apparent to one skilled in the art that various patterns may be are used to maximize the circuit area of the gate lines 165, drains 180, and source lines 185 with respect to the covering semiconductor 190.

Referring specifically to FIGS. 21, 27, 49 and 56, it will be apparent to one skilled in the art that triangular pads may be used to maximize further the circuit area patterns of the gate lines 165, drains 180, source lines 185 with respect to the covering semiconductor 190.

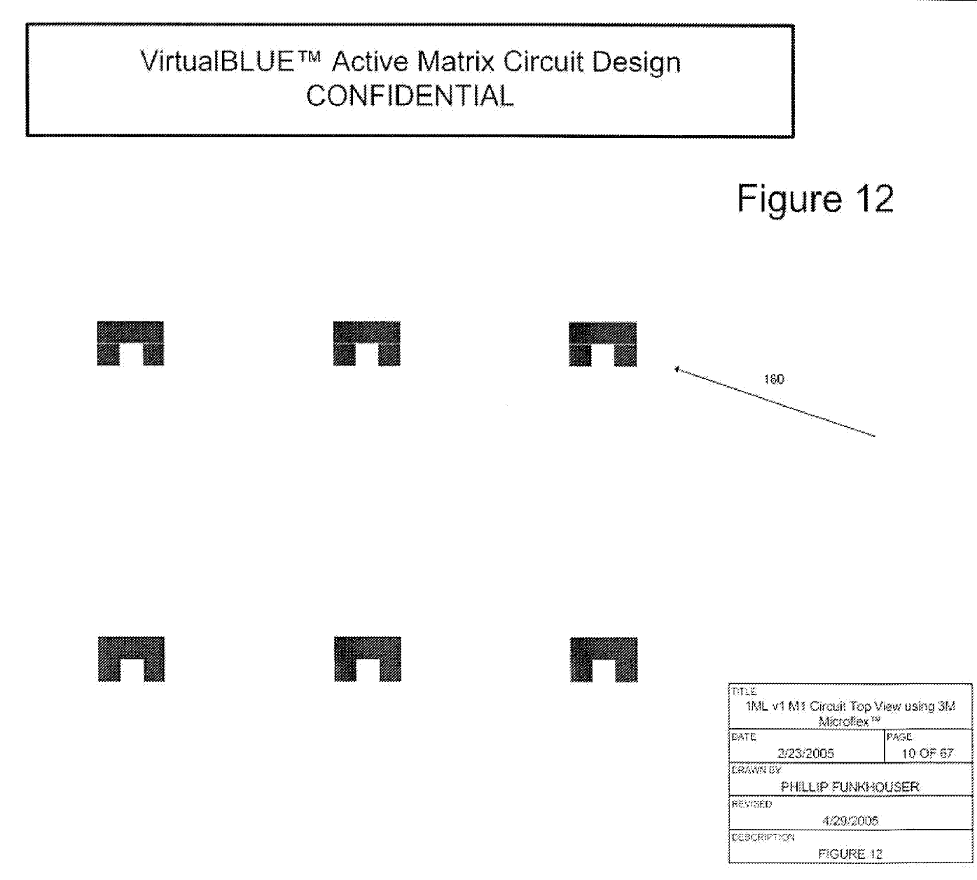

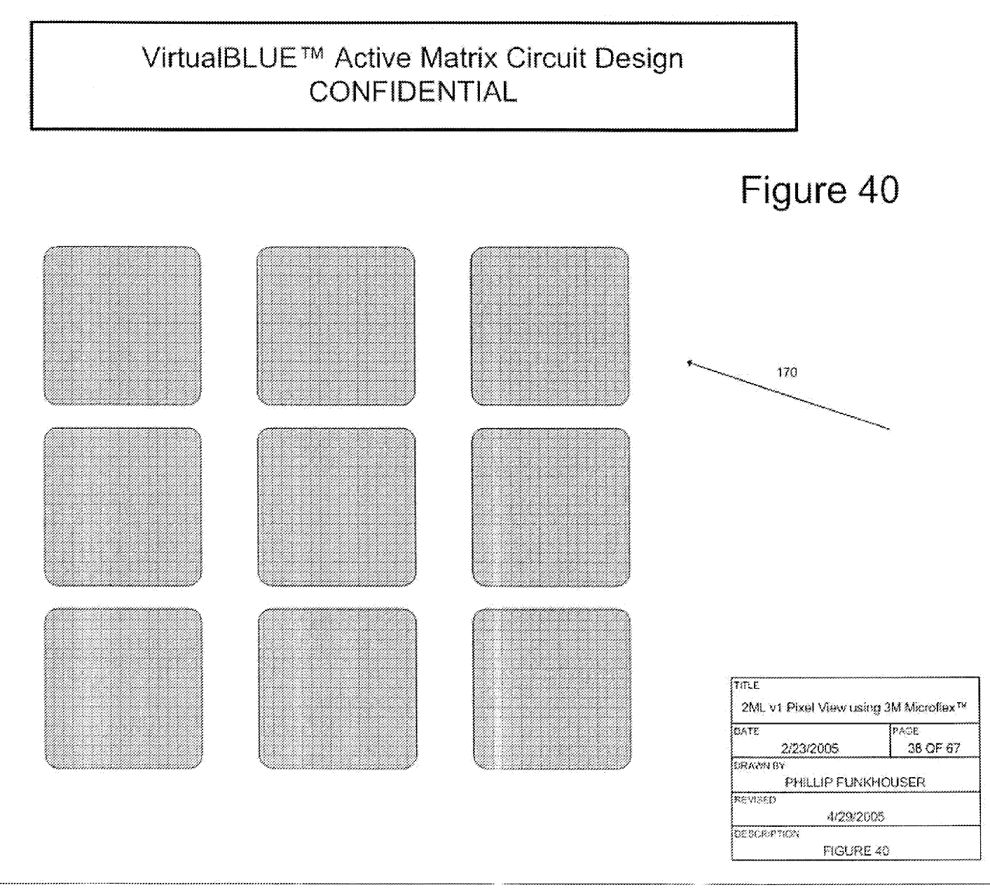

As seen in FIGS. 3-6, 43, 50, 57 and 64, via 160 are used to connect the drain 180 (as shown in FIGS. 12, 18, 24, 30, 39, 46, 53, 60 and 67) with the corresponding pixel electrode 170 (as shown in FIGS. 40, 47, 54, 61 and 68), which are located on opposite sides or surfaces of the backplane substrate 150.

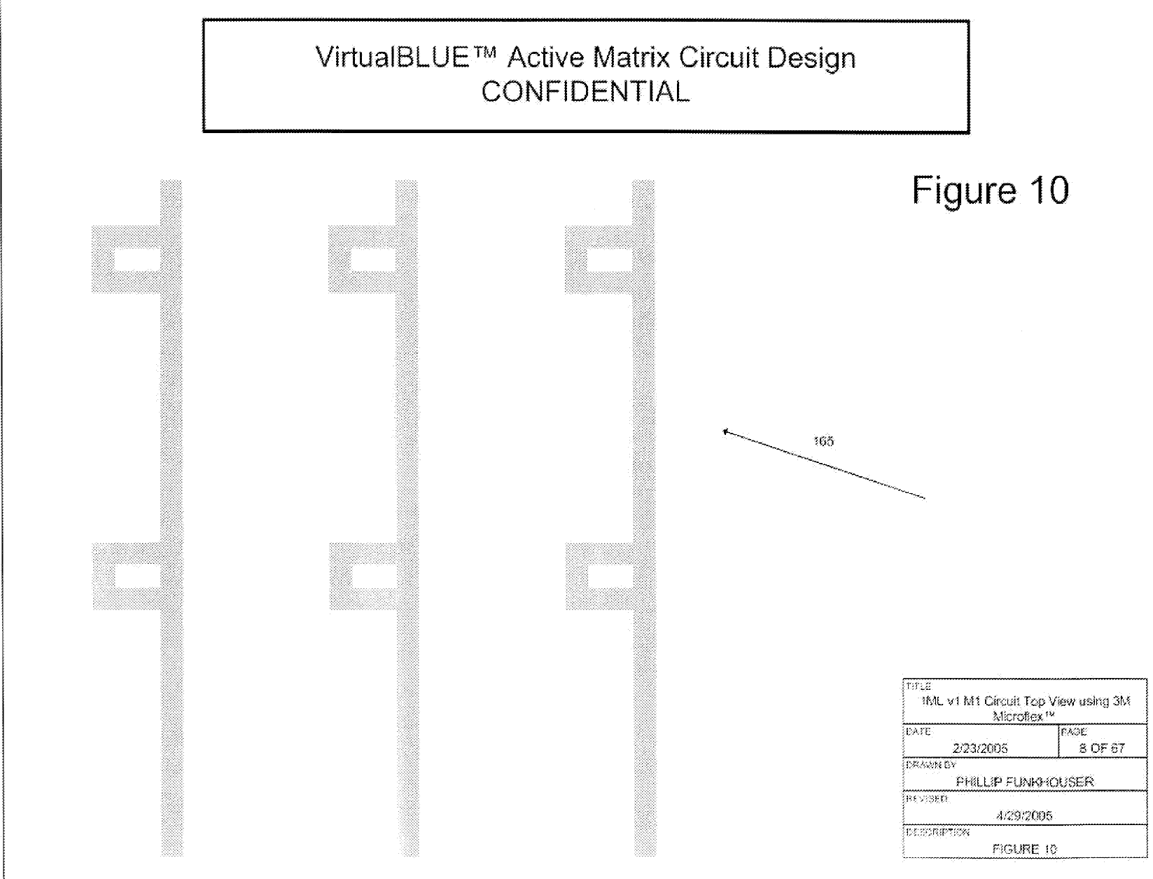

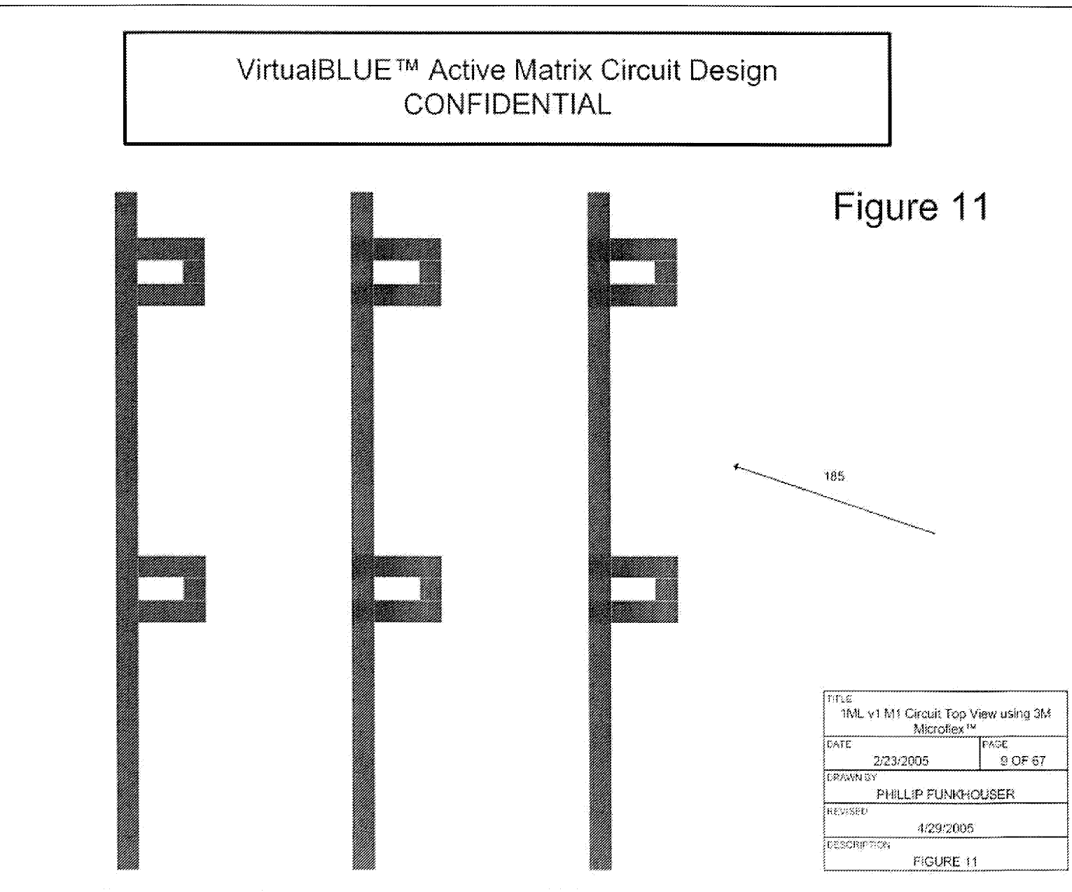

As seen in FIGS. 10, 16, 22, 28, 37, 44, 51, 58 and 65, in several embodiments, gate lines 165 are run parallel to corresponding source lines 185, which are shown in FIGS. 11, 17, 23, 29, 38, 45, 52, 59 and 66.

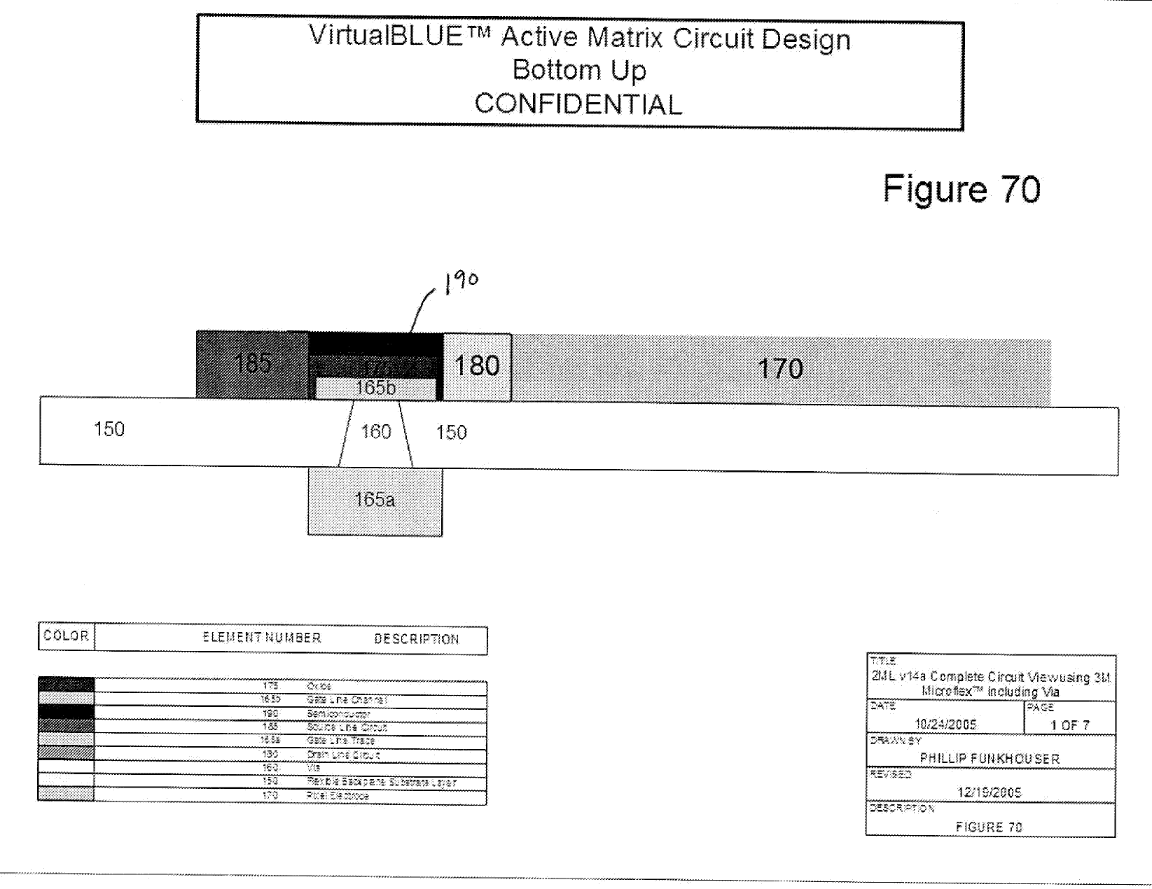

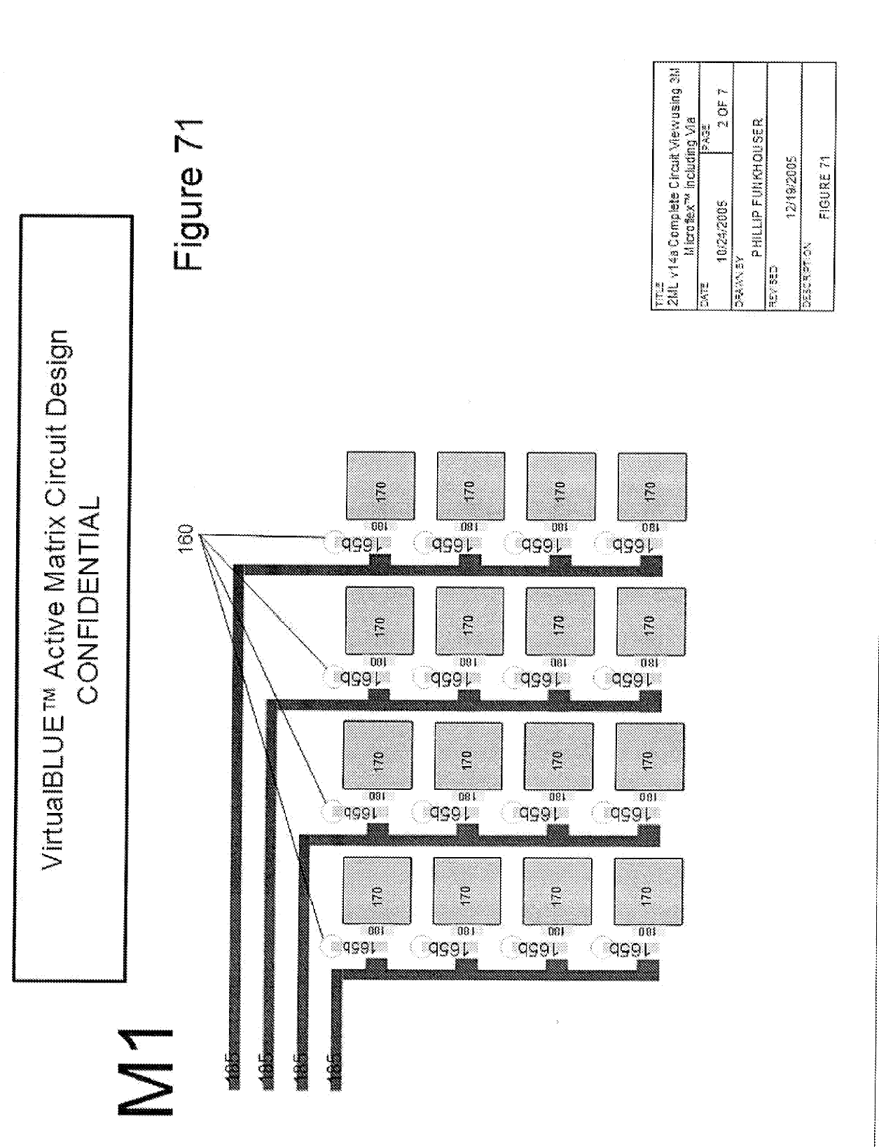

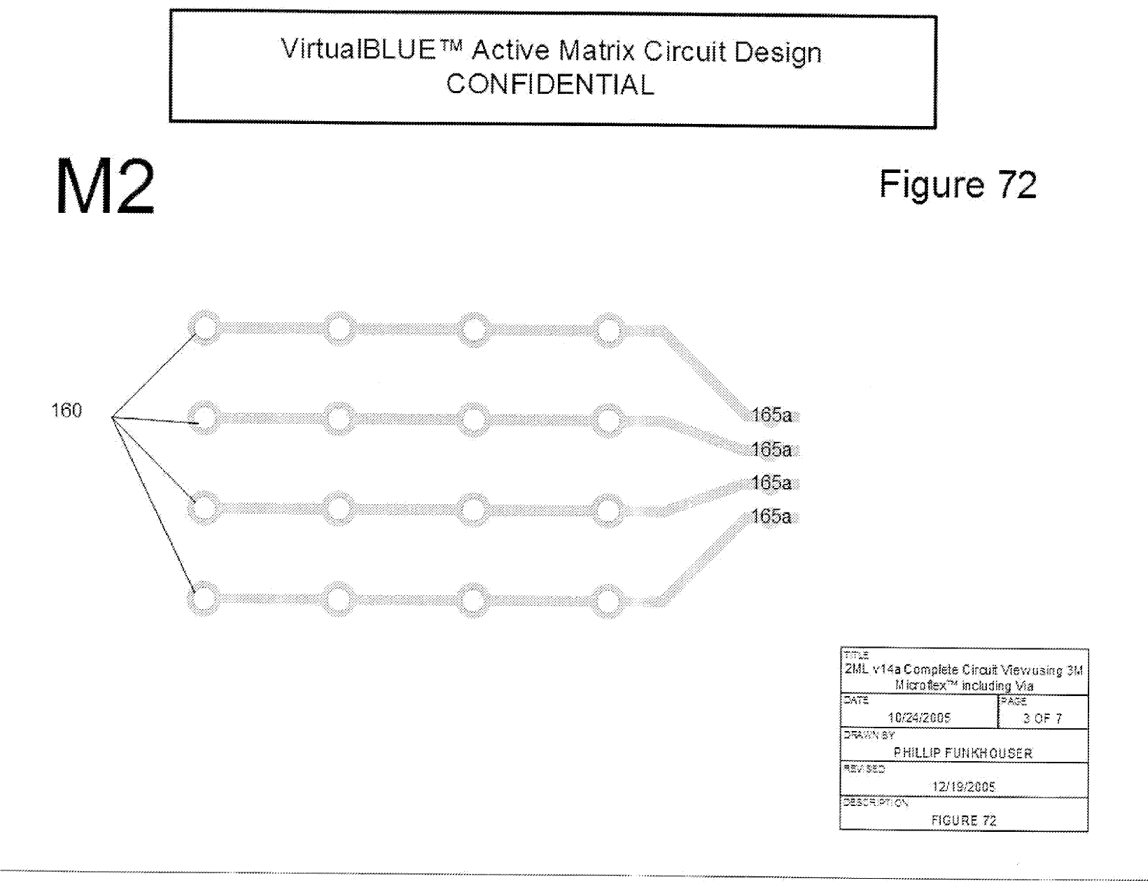

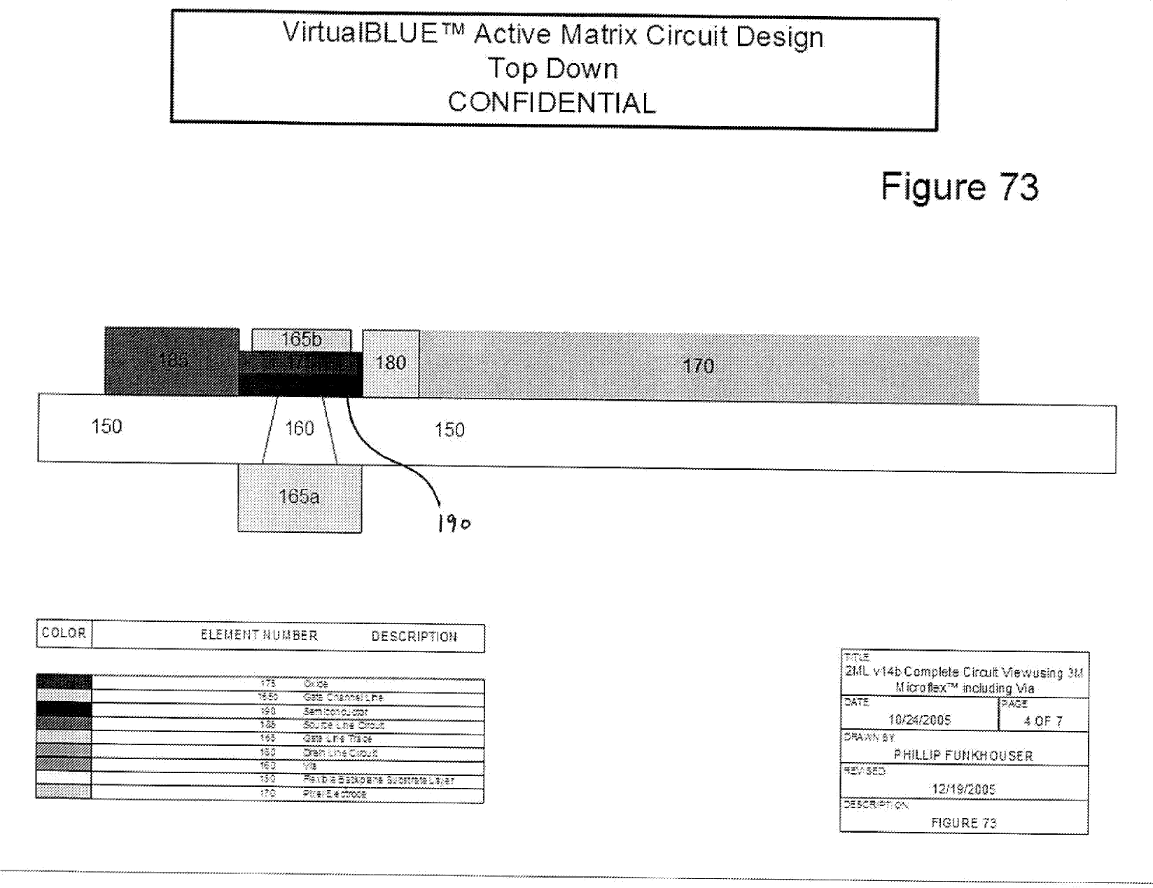

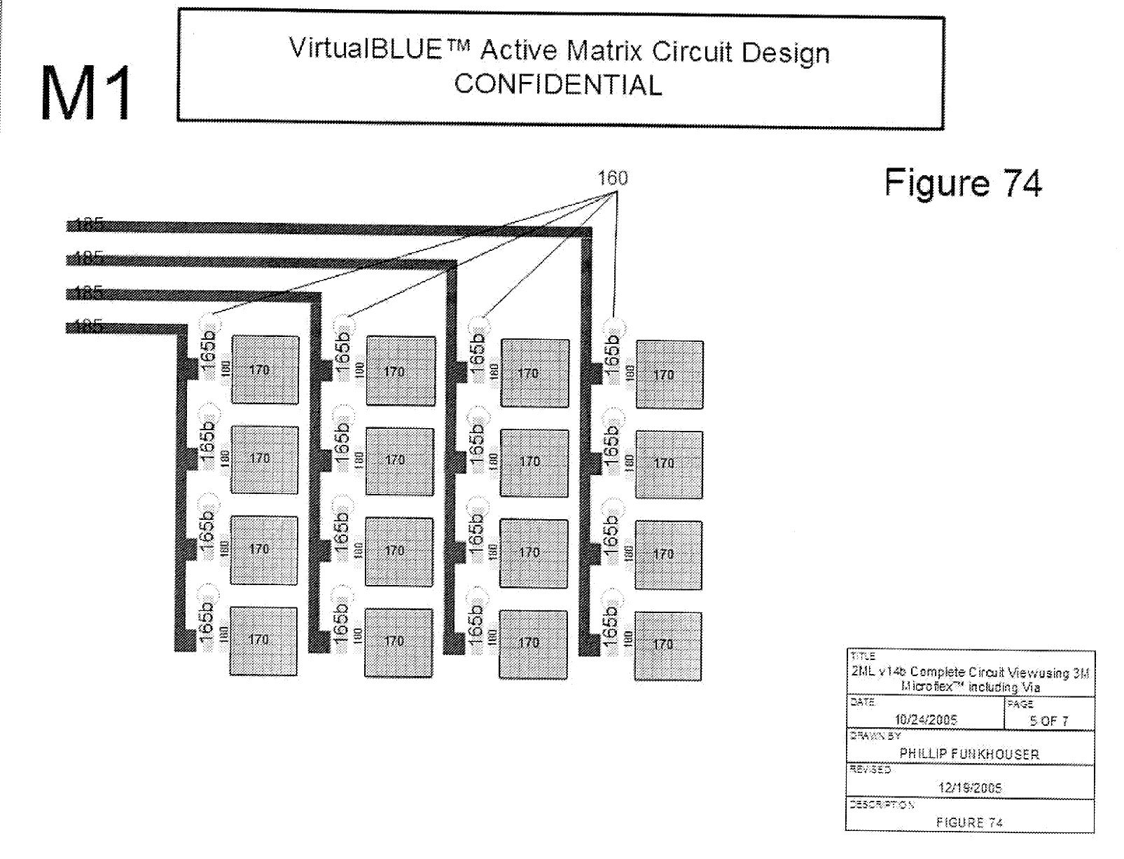

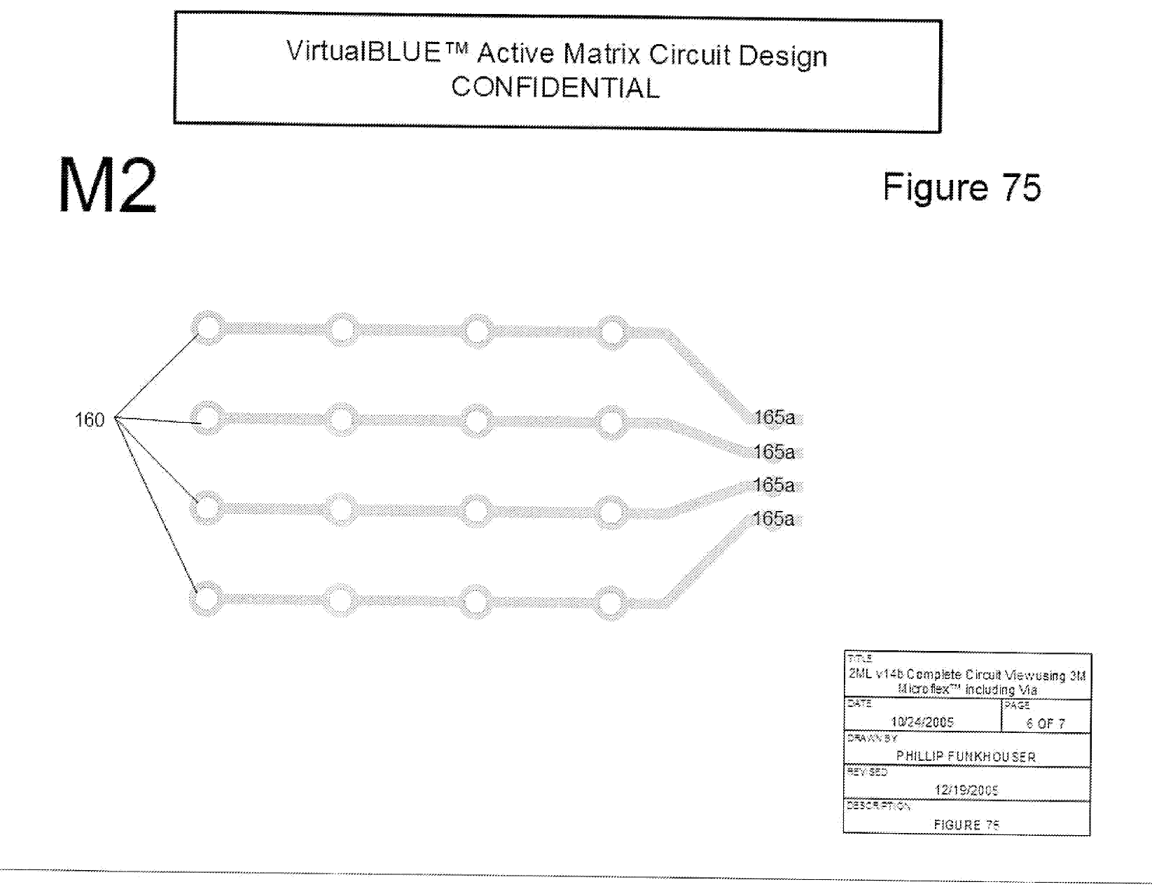

FIGS. 70-75 illustrate fourth and fifth embodiments of a flexible active matrix driver layer 475 in a row and column configuration. As shown, via 160 are used to connect each channel gate 165b with the gate line 165a, which is located on the oppositely disposed surface of the backplane substrate 150. The source line 185 is run in a perpendicular orientation to the gate line 165a. This orientation is commonly referred to as a row and column design. The drain 180 connects to pixel electrode 170.

Having described the primary components of the flexible display assembly 400, the operation of the flexible display assembly 400 will now be described:

The display control section 200 operates the flexible digital display assembly 400. The display control section 200 comprises the display driver 220, the gate line controller 222 and the source line controller 223.

The display driver 220 signals the gate line controller 222 and the source line controller 223 to provide current to selected gate lines and source lines, respectively, which selectively switches on selected pixel switches on the flexible digital display assembly 400 and is responsible for sizing the drawing and documents appropriately based on the size of the flexible digital display assembly 400 used.

The gate lines 165 and source lines 185 never overlap or contact each other. The gate lines 165 and source lines 185 transfer electricity through the semiconductor 190 to the drain 180 which charge the pixel electrodes 170. In two layer embodiments of the display assembly 400, pixel electrode 170 connects to drain 180, located on the oppositely disposed surface of the backplane substrate 150, through via 160.

The display driver 220 signals the gate line controller 222, which in turn sends a signal to the selected gate line(s) 165; at the same time, a corresponding signal is sent from the display driver 220 to the source line controller 223, which in turn sends a signal to the selected source line(s) 185. When the two corresponding signals meet at an intersection along a gate line 165 and source line 185 pair, they energize an individual semiconductor 190. The energized semiconductor 190 then carries the signal to the drain 180, which energizes the corresponding pixel electrode 170.

Many simultaneous signals sent and sequenced from the display driver 220 can travel along different gate line 165 and sources line 185 pairs with necessary speed ad within an appropriate time to address at each of the individual pixel electrodes 170 of the active matrix circuit assembly 155, which in turn are used to create image and/or text on the display layer frontplane 460 or 440.

In one embodiment, the active matrix circuit assembly 155 comprises a display assembly, which includes a display layer and a matrix driver layer 475 adjacent the display layer. The matrix driver layer 475 includes a substrate layer 150, and a plurality of pixel electrodes 170, gate lines 165, source lines 185, and pixel switches are disposed on the substrate layer 150. Each pixel switch is associated with one respective pixel electrode 170, and each pixel switch includes a gate electrically connected to the gate line 165, a source connected to the source line 185, a drain 180, a dielectric 175 disposed between and electrically insulating the gate, the source, and the drain 180, and a semiconductor 190 disposed between the gate and the drain 180. The active matrix circuit assembly also includes a display control 200, including a gate line controller 222 in electrical communication with the plurality of gate lines 165, a source line controller 223 in electrical communication with the plurality of source lines 185, and a display driver 220 that electrically communicates with the gate line controller 222 and the source line controller 223 for providing current selectively to the gate lines 165 and source lines 185, wherein when one of the pixel switches is activated, the corresponding pixel electrode 170 is energized.

In some embodiments, the display layer of the active matrix circuit assembly 155 is a flexible active matrix RGB color display 440. In other embodiments, the display layer is a flexible microcapsule display layer 460.

In one embodiment, the pixel electrodes 170 and the pixel switches of the active matrix circuit assembly 155 are located on a common surface of the substrate layer 150. In another embodiment, the pixel electrodes 170 and the pixel switches are located on opposite surfaces of the substrate layer 150. When the pixel electrodes 170 and the pixel switches are located on opposite surfaces of the substrate layer 150, each pixel switch is electrically connected to its corresponding pixel electrode 170 using a via 160 defined through the substrate layer 150.

In some embodiments, the gate lines 165 of the active matrix circuit assembly 155 are parallel to the source line 185 on the substrate layer 150. In other embodiments, the gate lines 165 are perpendicular to the source lines 185 on the substrate layer 150, and the gate lines 165 and the source lines 185 are disposed on opposed surfaces of the substrate layer 150. In certain embodiments of the active matrix circuit assembly 155, each gate is connected to the gate lines 165 through via 160 defined through the substrate layer 150.

The display assembly of the active matrix circuit assembly 155 can further comprise an upper protective layer 415 overlying the display layer and a lower protective layer 420 underlying the display layer. In other embodiments, the display assembly is flexible. Still in other embodiments, the substrate layer 150 is flexible.

In one embodiment of the present invention, the matrix display driver 475 comprises a substrate 150, a gate line 165 arranged linearly along one surface of the substrate 150, and a source line 185 arranged perpendicularly to the gate line 165 and disposed on the opposed surface of the substrate 150. The relative overlap of the gate line 165 and source line 185 define a display switch. On the opposed surface of the substrate layer 150, the display switch further includes a pixel electrode 170, a drain 180 electrically connected to the pixel electrode 170, a semiconductor 190 disposed between the source line 185 and the drain 180, and a channel gate 165b. The channel gate is electrically connected to the gate line 165 by a via 160 defined through the substrate 150, and the channel gate is electrically insulated from the semiconductor 190 by a dielectric 175. In this embodiment, the display switch is actuated, current flows to the drain 180, and the pixel electrode 170 is energized.

The substrate 150 of the matrix display driver 475 is flexible in certain embodiments. In another embodiment, the channel gate 165b is stacked on top of the dielectric 175 and the semiconductor 190 over the via 160. In yet another embodiment, the channel gate 165b is spaced apart from the source line 185 and the drain 180. The semiconductor 190 can also be stacked on top of the dielectric 175 and the channel gate 165b over the via 160. In another embodiment of the matrix display driver 475, the channel gate 165b is separated from the source line 185 and the drain 180 by the dielectric 175.

What is claimed is:

1 An active matrix circuit assembly comprising:
a. a display assembly, including;
i. a display layer; and
ii. a matrix driver layer adjacent the display layer, the matrix driver layer including a substrate layer and, disposed on the substrate layer, a plurality of pixel electrodes, gate lines, source lines, and pixel switches, each pixel switch associated with a respective one of the pixel electrodes, each pixel switch including a gate electrically connected to the gate line, a source connected to the source line, a drain, a dielectric disposed between and electrically insulating the gate, the source, and the drain, and a semiconductor disposed between the gate and the drain; and
b. a display control, including:
i. a gate line controller in electrical communication with the plurality of gate lines;
ii. a source line controller in electrical communication with the plurality of source lines; and
iii. a display driver that electrically communicates with the gate line controller and the source line controller for providing current selectively to the gate lines and source lines, wherein when one of the pixel switches is activated, the corresponding pixel electrode is energized.

2. The active matrix circuit assembly of claim 1 wherein the pixel electrodes and the pixel switches are located on a common surface of the substrate layer.

3. The active matrix circuit assembly of claim 1 wherein the pixel electrodes and the pixel switches are located on opposed surfaces of the substrate layer.

4. The active matrix circuit assembly of claim 3 wherein each pixel switch is electrically connected to its corresponding pixel electrode using a via defined through the substrate layer.

5. The active matrix circuit assembly of claim 1 wherein the gate lines are parallel to the source line on the substrate layer.

6. The active matrix circuit assembly of claim 1 wherein the gate lines are perpendicular to the source lines on the substrate layer and wherein the gate lines and the source lines are disposed on opposed surfaces of the substrate layer.

7. The active matrix circuit assembly of claim 6 wherein each gate is connected to the gate lines through via defined through the substrate layer.

8. The active matrix circuit assembly of claim 1 wherein the display layer is a flexible active matrix RGB color display or a flexible microcapsule display layer.

9. The active matrix circuit assembly of claim 1 wherein the display assembly further comprises an upper protective layer overlying the display layer and a lower protective layer underlying the display layer.

10. The active matrix circuit assembly of claim 1 wherein the display assembly is flexible.

11. The active matrix circuit assembly of claim 1 wherein the substrate layer is flexible.

12. A matrix display driver comprising:
a. a substrate;
b. a gate line arranged linearly along one surface of the substrate;
c. a source line arranged perpendicularly to the gate line, said source line disposed on the opposed surface of the substrate, the relative overlap of the gate line and source line defining a display switch;
d. said display switch further including, on the opposed surface of the substrate layer, a pixel electrode, a drain electrically connected to said pixel electrode, a semiconductor disposed between the source line and the drain, and a channel gate, the channel gate electrically connected to the gate line by a via defined through the substrate, and the channel gate electrically insulated from the semiconductor by a dielectric;
wherein, when the display switch is actuated, current flows to the drain and the pixel electrode is energized.

13. The matrix display driver of claim 12 wherein the channel gate is stacked on top of the dielectric and the semiconductor over the via.

14. The matrix display driver of claim 13 wherein the channel gate is spaced apart from the source line and the drain.

15. The matrix display driver of claim 12 wherein the semiconductor is stacked on top of dielectric and the channel gate over the via.

16. The matrix display driver of claim 13 wherein the channel gate is separated from the source line and the drain by the dielectric.

17. The matrix display driver of claim 12 wherein the substrate is flexible.
